(19) United States
(12) Patent Application Publication
(10) Pub. No.: US 2026/0004030 A1
(43) Pub. Date: Jan. 1, 2026

(54) Artificial Intelligence (AI) Assisted Integration of New Digital Model Types and Tools into Integrated Digital Model Platform

(71) Applicant: Istari Digital, Inc., Charleston, SC (US)

(72) Inventors: William Roper, JR., Charleston, SC (US); Christopher Lee Benson, Arlington, VA (US); Sriram Krishnan, Cambridge, MA (US); Vadim Kendyukhov, Krakow (PL); Najem Aldeen Abu Rmaileh, Amman (JO); Malik Suliman Ghanim Al-Ghanim, Amman (JO)

(21) Appl. No.: 19/321,364

(22) Filed: Sep. 8, 2025

Related U.S. Application Data
(63) Continuation of application No. PCT/US24/35885, filed on Jun. 27, 2024.
(60) Provisional application No. 63/511,583, filed on Jun. 30, 2023.

(51) Int. Cl. G06F 30/27; G06F 30/12

(52) U.S. Cl. CPC G06F 30/27; G06F 30/12

(57) ABSTRACT

Methods and systems for generating a digital model splicer are provided. The method comprises training a first AI model and a second AI model on an interconnected digital model platform (IDMP) platform resource-capability mapping; generating input and output schemas for a target digital model tool using the first AI model, wherein the first AI model is prompted based on an identifier for the target digital tool; generating a plurality of function scripts executable by the IDMP using a second AI model, wherein the second AI model is prompted based on the input and output schemas, and wherein at least one function script calls Application Programming Interface (API) or Software Development Kit (SDK) functions associated with the target digital tool, using the input and output schemas; and storing the input and output schemas and the plurality of function scripts as the digital model splicer for the target digital tool.

### REFERENCE TO RELATED APPLICATIONS

If an Application Data Sheet (“ADS”) or PCT Request Form (“Request”) has been filed on the filing date of this application, it is incorporated by reference herein. Any applications claimed on the ADS or Request for priority under 35 U.S.C. §§ 119, 120, 121, or 365 (c), and any and all parent, grandparent, great-grandparent, etc. applications of such applications, are also incorporated by reference, including any priority claims made in those applications and any material incorporated by reference, to the extent such subject matter is not inconsistent herewith.

Furthermore, this application is related to the U.S. patent applications listed below, which are incorporated by reference in their entireties herein, as if fully set forth herein:
PCT patent application No. PCT/US24/19297 (Docket No. IST-01.002PCT), filed on Mar. 10, 2024, entitled “Software-Code-Defined Digital Threads in Digital Engineering Systems with Artificial Intelligence (AI) Assistance,” describes AI-assisted digital threads for digital engineering platforms.
PCT patent application No. PCT/US24/18278 (Docket No. IST-02.001PCT), filed on Mar. 3, 2024, entitled “Secure and Scalable Model Splicing of Digital Engineering Models for Software-Code-Defined Digital Threads,” describes model splicing for digital engineering platforms.
PCT patent application No. PCT/US24/14030 (Docket No. IST-01.001PCT), filed on Feb. 1, 2024, entitled “Artificial Intelligence (AI) Assisted Digital Documentation for Digital Engineering,” describes AI-assisted documentation for digital engineering platforms.
U.S. provisional patent application No. 63/442,659 (Docket No. IST-01.001P), filed on Feb. 1, 2023, entitled “AI-Assisted Digital Documentation for Digital Engineering with Supporting Systems and Methods,” describes AI-assistance tools for digital engineering (DE), including modeling and simulation applications, and the certification of digitally engineered products.
U.S. provisional patent application No. 63/451,545 (Docket No. IST-01.002P), filed on Mar. 10, 2023, entitled “Digital Threads in Digital Engineering Systems, and Supporting AI-Assisted Digital Thread Generation,” describes model splicer and digital threading technology.
U.S. provisional patent application No. 63/451,577 (Docket No. IST-02.001P1), filed on Mar. 11, 2023, entitled “Model Splicer and Microservice Architecture for Digital Engineering,” describes model splicer technology.
U.S. provisional patent application No. 63/462,988 (Docket No. IST-02.001P2), filed on Apr. 29, 2023, also entitled “Model Splicer and Microservice Architecture for Digital Engineering,” describes model splicer technology.
U.S. provisional patent application No. 63/511,583 (Docket No. IST-02.002P), filed on Jun. 30, 2023, entitled “AI-Assisted Model Splicer Generation for Digital Engineering,” describes model splicer technology with AI-assistance.
U.S. provisional patent application No. 63/516,624 (Docket No. IST-02.003P), filed on Jul. 31, 2023, entitled “Document and Model Splicing for Digital Engineering,” describes document splicer technology.
U.S. provisional patent application No. 63/520,643 (Docket No. IST-02.004P), filed on Aug. 20, 2023, entitled “Artificial Intelligence (AI)-Assisted Automation of Testing in a Software Environment,” describes software testing with AI-assistance.
U.S. provisional patent application No. 63/590,420 (Docket No. IST-02.005P), filed on Oct. 14, 2023, entitled “Commenting and Collaboration Capability within Digital Engineering Platform,” describes collaborative capabilities.
U.S. provisional patent application No. 63/586,384 (Docket No. IST-02.006P), filed on Sep. 28, 2023, entitled “Artificial Intelligence (AI)-Assisted Streamlined Model Splice Generation, Unit Testing, and Documentation,” describes streamlined model splicing, testing and documentation with AI-assistance.
U.S. provisional patent application No. 63/470,870 (Docket No. IST-03.001P), filed on Jun. 3, 2023, entitled “Digital Twin and Physical Twin Management with Integrated External Feedback within a Digital Engineering Platform,” describes digital and physical twin management and the integration of external feedback within a DE platform.
U.S. provisional patent application No. 63/515,071 (Docket No. IST-03.002P), filed on Jul. 21, 2023, entitled “Generative Artificial Intelligence (AI) for Digital Engineering,” describes an AI-enabled digital engineering task fulfillment process within a DE software platform.
U.S. provisional patent application No. 63/517,136 (Docket No. IST-03.003P), filed on Aug. 2, 2023, entitled “Machine Learning Engine for Workflow Enhancement in Digital Engineering,” describes a machine learning engine for model splicing and DE script generation.
U.S. provisional patent application No. 63/516,891 (Docket No. IST-03.004P), filed on Aug. 1, 2023, entitled “Multimodal User Interfaces for Digital Engineering,” describes multimodal user interfaces for DE systems.
U.S. provisional patent application No. 63/580,384 (Docket No. IST-03.006P), filed on Sep. 3, 2023, entitled “Multimodal Digital Engineering Document Interfaces for Certification and Security Reviews,” describes multimodal user interfaces for certification and security reviews.
U.S. provisional patent application No. 63/613,556 (Docket No. IST-03.008P), filed on Dec. 21, 2023, entitled “Alternative Tool Selection and Optimization in an Integrated Digital Engineering Platform,” describes tool selection and optimization.
U.S. provisional patent application No. 63/584,165 (Docket No. IST-03.010P), filed on Sep. 20, 2023, entitled “Methods and Systems for Improving Workflows in Digital Engineering,” describes workflow optimization in a DE platform.
U.S. provisional patent application No. 63/590,456 (Docket No. IST-04.001P), filed on Oct. 15, 2023, entitled “Data Sovereignty Assurance for Artificial Intelligence (AI) Models,” relates to data sovereignty assurance during AI model training and evaluation.
U.S. provisional patent application No. 63/606,030 (Docket No. IST-04.001P2), filed on Dec. 4, 2023, also entitled “Data Sovereignty Assurance for Artificial Intelligence (AI) Models,” further details data sovereignty assurances during AI model training and evaluation.
U.S. provisional patent application No. 63/419,051, filed on Oct. 25, 2022, entitled “Interconnected Digital Engineering and Certification Ecosystem.”
U.S. non-provisional patent application Ser. No. 17/973,142 (Docket No. 54332-0057001) filed on Oct. 25, 2022, entitled “Interconnected Digital Engineering and Certification Ecosystem.”
U.S. non-provisional patent application Ser. No. 18/383,635 (Docket No. 54332-0059001), filed on Oct. 25, 2023, entitled “Interconnected Digital Engineering and Certification Ecosystem.”
U.S. provisional patent application No. 63/489,401, filed on Mar. 9, 2023, entitled “Security Architecture for Interconnected Digital Engineering and Certification Ecosystem.”

### NOTICE OF COPYRIGHTS AND TRADEDRESS

A portion of the disclosure of this patent document contains material which is subject to copyright protection. This patent document may show and/or describe matter which is or may become tradedress of the owner. The copyright and tradedress owner has no objection to the facsimile reproduction by anyone of the patent disclosure as it appears in the U.S. Patent and Trademark Office files or records, but otherwise reserves all copyright and tradedress rights whatsoever.

ISTARI DIGITAL is a trademark name carrying embodiments of the present invention, and hence, the aforementioned trademark name may be interchangeably used in the specification and drawings to refer to the products/process offered by embodiments of the present invention. The terms ISTARI and ISTARI DIGITAL may be used in this specification to describe the present invention, as well as the company providing said invention.

### FIELD OF THE INVENTION

This disclosure relates to tools for digital engineering, including modeling and simulation applications, and the certification of digitally engineered products. Specifically, this disclosure relates to the application of artificial intelligence (AI) in the communication, integration, and collaboration among multidisciplinary digital engineering models at large scale.

### BACKGROUND OF THE INVENTION

The statements in the background of the invention are provided to assist with understanding the invention and its applications and uses, and may not constitute prior art.

Digital engineering (DE) is an integrated digital approach to systems engineering, using authoritative sources of system data and models as a continuum across disciplines to support lifecycle activities from conception through disposal. Disparate engineering tools from multiple disciplines are necessary to enable DE, from design to validation, verification, manufacturing, to certification of complex systems, yet these DE tools and the models they generate are siloed in different engineering software platforms. Robust and efficient integration of data and models from the siloed tools is one of the largest expenses in DE and requires massive teams of highly-specialized engineers and software developers, while cross-platform collaboration is often impeded by the mismatch of software skill sets among highly expensive subject matter experts (SMEs), given the sheer number of different DE model types in use today. Furthermore, large-scale multidisciplinary integration into digital threads and digital twins for system-level assessment is far from maturing to efficiently model intricate interactions in large complex systems.

Recent developments in artificial intelligence (AI) and machine learning (ML) have opened new doors for process automation, generative design, and data analytics in DE. Latest advances in natural language processing, transformer-based Large Language Models (LLMs) further show strong promises for essential DE tasks such as text generation for documentation and code generation for software development, yet the applicability of such LLMs in DE is so far unproven, given the complexity and multidisciplinary nature of DE, and with issues such as AI hallucinations and uncertain data security and privacy protection both during LLM training and deployment.

Therefore, in view of the aforementioned difficulties, there is an unsolved need to provide an engineering collaboration system and platform that integrates a plethora of DE tools to enable streamlined design, manufacturing, assembly, validation, verification, and certification of complex systems. Accordingly, it would be an advancement in the state of the art to enable AI-assistance in the integration of multidisciplinary engineering models from disparate, disconnected tools, together with human-readable documentation, in a unified, scalable, and collaborative DE platform.

It is against this background that various embodiments of the present invention were developed.

### BRIEF SUMMARY OF THE INVENTION

This summary of the invention provides a broad overview of the invention, its application, and uses, and is not intended to limit the scope of the present invention, which will be apparent from the detailed description when read in conjunction with the drawings.

Broadly, the present invention relates to methods and systems for AI-assisted model splicer generation and update for any given DE tool, DE model type, or combinations thereof. More specifically, embodiments of the present invention are directed to training machine learning (ML) and/or artificial intelligence (AI) models on resource-capability mappings provided by an interconnected digital model platform (IDMP), identifying data schemas for DE models newly incorporated into the IDMP, and generating function scripts that interface with DE tool Application Programming Interfaces (APIs) or with the IDMP platform API. Such function scripts may be created when a new DE tool is introduced to the IDMP ecosystem, or when an existing DE tool is updated with a new version within the IDMP.

Methods and systems thus described herein are further directed to AI-assisted cross-tool scripting of DE model operations encompassing disparate DE tools, Normative program code interfaces to both DE models and DE tools may be universally customized and automated within the unified IDMP for the creation and manipulation of complex systems comprising digital models, digital threads, and digital twins.

A vast array of DE model types and DE tools exist today, exemplified by the presence of over 50 vendors providing computer-aided design (CAD) tools that support in excess of 20 distinct CAD file formats. Through the process of continuous learning and adaptation to common IDMP schemas and IDMP resource-capability mappings universally applicable within the IDMP, the disclosed embodiments facilitate the seamless integration of novel models and tools into the IDMP, thus enabling the expansion of the IDMP across the vast number of tools and model types, with limited intervention from subject matter experts (SMEs). The effortless, AI-assisted integration of new DE tools and components into the IDMP enhances the platform's capabilities and performance while minimizing disruptions and delays, potentially leading to dramatic reductions in cost and time throughout all phases of any digitally-engineered product's lifecycle.

In various embodiments, the ML and AI engines or modules thus disclosed may be trained and/or fine-tuned on existing resource-capability mappings, datasets of user inputs and feedback, and exemplary schemas and function scripts. Fine-tuning may be further customized with enterprise documents and data when appropriate, to capture specific language and data dependencies within client databases. Fine-tuning and deployment of the AI-assisted process steps may occur in secure customer environments to ensure zero-trust principles are followed.

Accordingly, various methods, processes, and non-transitory storage media storing program code for AI-assisted generation and update of digital model splicers are within the scope of the present invention. “Model splicer generation” creates input and output schema for model splices, as well as a library or pipeline of scripts that can be selectively integrated into any particular model splice. A “model splicer” for a given digital model type, when applied to a specific digital model file of the digital model type, extracts model data from the model file, instantiates API endpoints according to input/output schemas, and encapsulates a set of selected scripts that allow access and modification of the model data.

Accordingly, various methods, processes, systems, and non-transitory storage medium storing program code for executing processes for AI-assisted integration of new digital model types and tools into an IDMP are provided.

In one aspect, one embodiment of the present invention is a non-transitory physical storage medium storing program code. The program code is executable by a hardware processor. The hardware processor when executing the program code causes the hardware processor to execute a computer-implemented process for artificial intelligence (AI)-assisted generation of a digital model splicer on an interconnected digital model platform (IDMP). The program code may comprise code to train a first AI model and a second AI model on an IDMP platform resource-capability mapping. The program code may comprise code to generate input and output schemas for a target digital model tool using the first AI model, wherein the first AI model is prompted based on an identifier for the target digital tool. The program code may comprise code to generate a plurality of function scripts executable by the IDMP using the second AI model, wherein the second AI model is prompted based on the input and output schemas, and wherein at least one function script calls Application Programming Interface (API) or Software Development Kit (SDK) functions associated with the target digital tool, using the input and output schemas. The program code may further comprise code to store the input and output schemas and the plurality of function scripts as the digital model splicer for the target digital tool.

In some embodiments, the non-transitory physical storage medium further comprises program code to align the input and output schemas to a standardized IDMP data schema, wherein at least one variable within the input and output schemas is of a standard IDMP variable type.

In some embodiments, the first AI model is prompted further based on input and output schema examples for a template digital tool associated with a template digital model type.

In some embodiments, the IDMP platform has an IDMP platform API, wherein the IDMP platform API is universal across at least two different digital tools for a common digital model type category, and wherein the IDMP platform resource-capability mapping comprises the IDMP platform API.

In some embodiments, the non-transitory physical storage medium further comprises program code to receive a user intent input, wherein the second AI model is a recommender engine, wherein the second

AI model is prompted further based on the user intent input, and wherein the plurality of function scripts accomplish the user intent input.

In some embodiments, the first AI model is prompted further based on a target digital model type associated with the target digital tool.

In some embodiments, a category of the target digital model type is previously integrated into the IDMP and described in the resource-capability mapping, and the input and output schemas overlap with an existing input and output schema for an existing digital tool with the target digital model type category.

In some embodiments, the non-transitory physical storage medium further comprises program code to extract tool API information from API documentations of the target digital tool, wherein the second AI model is prompted further based on the tool API information.

In some embodiments, the non-transitory physical storage medium further comprises program code to fine-tune the first AI model and the second AI model on API documentations of the target digital tool.

In some embodiments, the non-transitory physical storage medium further comprises program code to generate a design mockup for the digital model splicer, wherein the second AI model is prompted further based on a portion of the design mockup.

In some embodiments, the program code to generate the design mockup comprises program code to receive a digital task involving the digital model type; upload the input and output schemas into a design mockup tool; generate, using the design mockup tool, a base design mockup of the digital model splicer, with a standardized data schema; for each variable in the standardized schema, search for example text or image in a database to update the base design mockup; generate the design mockup by adding the example texts or images to the base design mockup, based on the input and output schema and the digital task; receive user feedback on the design mockup; and finalize the design mockup based on the user feedback.

In some embodiments, the first AI model or the second AI model is a generative AI model.

In some embodiments, the first AI model or the second AI model is a transformer-based Large Language Model (LLM) or a Small Language Model (SLM)

In some embodiments, the second AI model is pre-trained on existing script functions from the IDMP.

In some embodiments, the first AI model or the second AI model is prompted further based on human user input.

In some embodiments, the first AI model or the second AI model is prompted further based on a digital task.

In some embodiments, at least one function script calls API functions associated with a digital tool different from the target digital tool.

In a second aspect, a computer-implemented method is provided. The method comprises training a first AI model and a second AI model on an IDMP platform resource-capability mapping; generating input and output schemas for a target digital model tool using the first AI model, wherein the first AI model is prompted based on an identifier for the target digital tool; generating a plurality of function scripts executable by the IDMP using the second AI model, wherein the second AI model is prompted based on the input and output schemas, and wherein at least one function script calls Application Programming Interface (API) or Software Development Kit (SDK) functions associated with the target digital tool, using the input and output schemas; and storing the input and output schemas and the plurality of function scripts as the digital model splicer for the target digital tool.

Embodiments as set out for the first aspect apply equally to the second aspect.

In a third aspect, a system for is provided. The system comprises at least one hardware processor, and at least one non-transitory physical storage medium storing program code. The program code is executable by the at least one hardware processor. The at least one hardware processor when executing the program code causes the at least one hardware processor to execute a computer-implemented process for artificial intelligence (AI)-assisted generation of the digital model splicer on the IDMP. The program code comprising code to train a first AI model and a second AI model on an IDMP platform resource-capability mapping; generate input and output schemas for a target digital model tool using the first AI model, wherein the first AI model is prompted based on an identifier for the target digital tool; generate a plurality of function scripts executable by the IDMP using the second AI model, wherein the second AI model is prompted based on the input and output schemas, and wherein at least one function script calls Application Programming Interface (API) or Software Development Kit (SDK) functions associated with the target digital tool, using the input and output schemas; and store the input and output schemas and the plurality of function scripts as the digital model splicer for the target digital tool.

Embodiments as set out for the first aspect apply equally to the third aspect.

In yet another aspect or embodiment of the present invention, a computer program product for AI-assisted generation of a digital model splicer on an IDMP is provided. The computer program may be used for and may include a computer-readable storage medium having program instructions, or program code, embodied therewith, the program instructions executable by a processor to cause the processor to perform the aforementioned steps.

In another aspect or embodiment of the present invention, a system for AI-assisted generation of a digital model splicer on an IDMP is provided, the system including a memory that stores computer-executable components, and a hardware processor, operably coupled to the memory, and that executes the computer-executable components stored in the memory, where the computer-executable components may include components communicatively coupled with the processor that execute the aforementioned steps.

In yet another aspect or embodiment of the present invention, a system for AI-assisted generation of a digital model splicer on an IDMP is provided, the system including a user device having a processor, a display, a first memory; a server including a second memory and a data repository; a communications link between said user device and said server; and a plurality of computer codes embodied on said first and second memory of said user device and said server, said plurality of computer codes which when executed causes said server and said user device to execute a process including the steps described herein.

In another aspect or embodiment of the present invention, a computerized server AI-assisted generation of a digital model splicer on an IDMP is provided, including at least one processor, memory, and a plurality of computer codes embodied on said memory, said plurality of computer codes which when executed causes said processor to execute a process including the steps described herein. Other aspects and embodiments of the present invention include the methods, processes, and algorithms including the steps described herein, and also include the processes and modes of operation of the systems and servers described herein.

In yet another aspect or embodiment of the present invention, an edge computerized system for AI-assisted generation of a digital model splicer on an IDMP is provided, the edge computerized system running on a physical system or physical twin (PTw) with either access to, or dedicated, processing, memory, computer code stored on a non-transitory computer-readable storage medium of the physical system or PTw, and a plurality of sensor data being measured on said physical system or PTw, the computer code causing the processor to perform the aforementioned steps.

Features which are described in the context of separate aspects and/or embodiments of the invention may be used together and/or be interchangeable wherever possible. Similarly, where features are, for brevity, described in the context of a single embodiment, those features may also be provided separately or in any suitable sub-combination. Features described in connection with the non-transitory physical storage medium may have corresponding features definable and/or combinable with respect to a digital documentation system and/or method and/or system, or vice versa, and these embodiments are specifically envisaged.

Yet other aspects and embodiments of the present invention will become apparent from the detailed description of the invention when read in conjunction with the attached drawings.

### BRIEF DESCRIPTION OF THE DRAWINGS

The accompanying drawings, which are incorporated in and constitute part of this specification, illustrate embodiments of the invention and together with the description, serve to explain the principles of the disclosed embodiments. For clarity, simplicity, and flexibility, not all elements, components, or specifications are defined in all drawings. Not all drawings corresponding to specific steps or embodiments of the present invention are drawn to scale. Emphasis is instead placed on illustration of the nature, function, and product of the manufacturing method and devices described herein.

Embodiments of the present invention described herein are exemplary, and not restrictive. Embodiments will now be described, by way of examples, with reference to the accompanying drawings, in which:

FIG. 1 shows an exemplary interconnected digital engineering (IDEP) platform architecture, in accordance with some embodiments of the present invention.

FIG. 2 shows an exemplary implementation of the IDEP as an interconnected digital engineering (DE) and certification ecosystem, and exemplary digitally certified products, in accordance with some embodiments of the present invention.

FIG. 3 shows another exemplary implementation of the IDEP illustrating its offered services and features, in accordance with some embodiments of the present invention.

FIG. 4 shows potential scenarios for instantiating an IDEP in connection to a customer's physical system and IT environment, in accordance with some embodiments of the present invention.

FIG. 5 shows exemplary multimodal interface designs for integration of feedback in am IDEP, in accordance with some embodiments of the present invention.

FIG. 6 is a schematic diagram comparing exemplary digital threads that connect DE models, in accordance with some embodiments of the present invention.

FIG. 7 is a schematic showing an exemplary DE model splicing setup, in accordance with some embodiments of the present invention.

FIG. 8 is a schematic showing digital threading of DE models via model splicing, in accordance with some embodiments of the present invention.

FIG. 9 is a schematic illustrating the linking of DE model splices in a splice plane and comparing digital threading with and without model splicing, in accordance with some embodiments of the present invention.

FIG. 10 shows an exemplary directed acyclic graph (DAG) representation of pipelined DE tasks related to digital threads, in accordance with some embodiments of the present invention.

FIG. 11 shows an exemplary use case of AI assistance in model splicing an input Model-Based Systems Engineering (MBSE) model file and scalable sharing of the model, in accordance with some embodiments of the present invention.

FIG. 12 is an exemplary architecture diagram for implementing a DE model splicer, in accordance with some embodiments of the present invention.

FIG. 13 is an exemplary flowchart showing a process for AI-assisted model splicer generation, in accordance with some embodiments of the present invention.

FIG. 14 is a schematic showing an exemplary implementation of AI-assisted model splicer generation or update, in accordance with some embodiments of the present invention.

FIG. 15 a schematic showing an exemplary AI-assisted model input/output schema generation module in an IDMP, and a corresponding AI-assisted model splicer design mockup generation module, in accordance with some embodiments of the present invention.

FIG. 16 shows an exemplary open-source LLM implementation of AI-assisted function script generation in a model splicer generation engine, in accordance with some embodiments of the present invention.

FIG. 17 shows a screen capture illustrating an exemplary AI-assisted process for creating a OPENFOAM model splicer design mockup, in accordance with some embodiments of the present invention.

FIG. 18 shows screen captures illustrating an exemplary AI-assisted process for obtaining exemplary digital artifacts, in accordance with some embodiments of the present invention.

FIG. 19 is a full model splicer design mockup derived from FIGS. 17 and 18, in accordance with some embodiments of the present invention.

FIG. 20 shows an illustrative EXCEL model splicer design mockup, in accordance with some embodiments of the present invention.

FIG. 21 shows an illustrative API tab for the model splicer design mockup in FIG. 20, in accordance with some embodiments of the present invention.

FIG. 22 shows an exemplary process for model splicer generation via Large Language Models (LLMs) directly, with prompt-response fine-tuning, in accordance with some embodiments of the present invention.

FIG. 23 shows another exemplary process for model splicer generation via an LLM with customization, in accordance with some embodiments of the present invention.

FIG. 24 shows an exemplary architecture for fine-tuning an LLM using DE data, in accordance with some embodiments of the present invention.

FIG. 25 describes neural network operation fundamentals, in accordance with some embodiments of the present invention.

FIG. 26 shows an overview of an IDMP neural network training process, in accordance with some embodiments of the present invention.

FIG. 27 is an illustrative flow diagram showing the different phases and datasets involved in training an IDMP machine learning model, in accordance with some embodiments of the present invention.

FIG. 28 provides illustrative schematics of a server (management computing entity) and a client (user computing entity) used for model splicer generation and update within an IDMP, in accordance with some embodiments of the present invention.

### DETAILED DESCRIPTION OF THE INVENTION

In the following description, for purposes of explanation, numerous specific details are set forth in order to provide a thorough understanding of the invention. It will be apparent, however, to one skilled in the art that the invention can be practiced without these specific details. In other instances, structures, devices, activities, methods, and processes are shown using schematics, use cases, and/or diagrams in order to avoid obscuring the invention. Although the following description contains many specifics for the purposes of illustration, anyone skilled in the art will appreciate that many variations and/or alterations to suggested details are within the scope of the present invention. Similarly, although many of the features of the present invention are described in terms of each other, or in conjunction with each other, one skilled in the art will appreciate that many of these features can be provided independently of other features. Accordingly, this description of the invention is set forth without any loss of generality to, and without imposing limitations upon, the invention.

Broadly, the present invention relates to methods and systems for AI-assisted model splicer generation and update for any given DE tool, DE model type, or combinations thereof. More specifically, embodiments of the present invention are directed to training machine learning (ML) and/or artificial intelligence (AI) models on resource-capability mappings provided by an interconnected digital model platform (IDMP), identifying data schemas for DE models newly incorporated into the IDMP, and generating function scripts that interface with DE tool Application Programming Interfaces (APIs) or with the IDMP platform API. Such function scripts may be created when a new DE tool is introduced to the IDMP ecosystem, or when an existing DE tool is updated with a new version within the IDMP.

With reference to the figures, embodiments of the present invention are now described in detail. First, general IDMP and model splicer generation-specific terminologies are introduced. Next, the IDMP is explained in detail. Finally, the AI-assisted system, which may be considered a subsystem of the IDMP, is described in detail.

### Terminology

Some illustrative terminologies used with the IDEP are provided below to assist in understanding the present invention, but these are not to be read as restricting the scope of the present invention. The terms may be used in the form of nouns, verbs, or adjectives, within the scope of the definition.
Digital engineering (DE): According to the Defense Acquisition University (DAU) and the Department of Defense (DOD) Digital Engineering Strategy published in 2018, digital engineering is “an integrated digital approach to systems engineering, using authoritative sources of systems' data and models as a continuum across disciplines to support lifecycle activities from concept through disposal.” Digital engineering incorporates digital technological innovations into an integrated, model-based approach that empowers a paradigm shift from the traditional design-build-test methodology of systems engineering to a new model-analyze-build methodology, thus enabling systems design, prototyping, and testing all in a virtual environment.
DE data: Digital engineering (DE) data comprises project management, program management, product management, design review, and/or engineering data.
DE data field: A data field for DE data, for example, in a DE document template.
Phases: The stages within a DE product lifecycle, including but not limited to, stakeholder analysis, concept studies, requirements definition, preliminary design and technology review, system modeling, final design, implementation, system assembly and integration, prototyping, verification and validation on system, sub-system, and component levels, and operations and maintenance.
DE model, also referred to as a “digital model”: A computer-generated model that represents characteristics or behaviors of a complex product or system. A DE model can be created or modified using a DE tool, and a DE model may be represented by one or more DE model files. A DE model file is the computer model file created or modified using the DE tool. In the present disclosure, the terms “digital model”, “DE model” and “DE model file” may be used interchangeably, as the context requires. A DE model within the IDEP as disclosed herein refers to any digital file uploaded onto the platform, including documents that are appropriately interpreted, as defined below. For example, a computer-aided design (CAD) file, a Systems Modeling Language (SysML) file, a Systems Requirements Document (SDR) text file, and a Neural Network Model JSON file may each be considered a DE model, in various embodiments of the present invention. A DE model may be machine-readable only, may be human-readable as well but written in programming codes, or may be human-readable and written in natural language-based texts. For example, a word-processing document comprising a technical specification of a product, or a spreadsheet file comprising technical data about a product, may also be considered a DE model.
Digital Model: A computer-generated model that represents characteristics or behaviors of a complex product, system, or process. Digital models include DE models but are not limited to the field of digital engineering. For example, digital models include medical model files used to build digital twins of patients (e.g., digital patients), such as clinical documentation, laboratory results, physiological test results, psychological test results, patient communications and reports, patient medical data, health records, remote monitoring data, and the like. Digital models also include the financial models used to build digital twins of financial assets, such as enterprise data, business financial data, process data (e.g., manufacturing, logistics, sales, supply chain), research results, etc. Other examples of digital models are also within the scope of the present invention, for example, scientific models, geophysical models, climate models, biological models, biochemical models, chemical models, drug models, petrochemical models, oceanographic models, business process models, management science models, economic models, econometric models, sociological models, population dynamics models, socioeconomic models, planetary science models, mining models, mineral models, metallurgical models, supply chain logistics models, manufacturing models, and so on. Digital models include one or more digital artifacts, where each digital artifact is accessible with a security network. A model file can be created or modified using a software tool. A model file within the Interconnected Digital Model Platform (IDMP) as disclosed herein refers to any digital file uploaded onto the platform. All the terms and concepts defined above and included herein, including model splicing, model splices, and software-defined digital threads, apply in the context of the digital model and within the context of the IDMP.
Interconnected Digital Engineering Platform (IDEP), also referred to as a “Digital Engineering and Certification Ecosystem”: According to the DAU, a “DE ecosystem” is the “interconnected infrastructure, environment, and methodology (process, methods, and tools) used to store, access, analyze, and visualize evolving systems' data and models to address the needs of the stakeholders.” Embodiments of the IDEP as disclosed herein comprise software platforms running on hardware to realize the aforementioned capabilities under zero-trust principles. A DE and certification ecosystem performs verification and validation tasks, defined next. An IDEP is a type of Integrated Digital Model Platform (IDMP), defined below. In general, any reference to an IDEP in the specification and drawings can be considered equivalent to a reference to an IDMP, and vice versa.
Interconnected Digital Model Platform (IDMP): Embodiments of the IDMP as disclosed herein include interconnected infrastructure, environment, and methodology (process, methods, and tools) used to store, access, analyze, visualize, and modify data and digital models associated with a product or system. In some embodiments, IDMPs include software platforms running on hardware to realize the aforementioned capabilities under zero-trust principles. Specifically, an embodiment of the IDMP is a software platform that interconnects a plurality of spliced model files through one or more software-defined digital threads.
Verification: According to the DAU, verification “confirms that a system element meets design-to or build-to specifications. Through the system's life cycle, design solutions at all levels of the physical architecture are verified through a cost-effective combination of analysis, examination, demonstration, and testing.” Verification refers to evaluating whether a product, service, or system meets specified requirements and is fit for its intended purpose, checking externally against customer or stakeholder needs. For example, in the aerospace industry, a verification process may include testing an aircraft component to ensure it can withstand the forces and conditions it will encounter during flight.
Validation: According to the DAU, validation is “1) the review and approval of capability requirement documents by a designated validation authority. 2) The process by which the contractor (or as otherwise directed by the DoD component procuring activity) tests a publication/technical manual for technical accuracy and adequacy. 3) The process of evaluating a system or software component during, or at the end of, the development process to determine whether it satisfies specified requirements.” Thus, validation refers to evaluating whether the overall performance of a product, service, or system is suitable for its intended use, including its compliance with regulatory requirements, and its ability to meet the needs of its intended users, checking internally against specifications and regulations. For example, for an industrial product manufacturing, a validation process may include consumer surveys that inform product design, modeling and simulations for validating the design, prototype testing for failure limits and feedback surveys from buyers.
Common Verification & Validation (V&V) products: Regulatory and certification standards, compliances, calculations, and tests (e.g., for the development, testing, and certification of products and/or solutions) are referred to herein as “common V&V products.”
DE tool: A tool or DE tool is a DE application software (e.g., a CAD software), computer program, and/or script that creates or manipulates a DE model during at least one stage or phase of a product lifecycle. A DE tool may comprise multiple functions or methods.
Application Programming Interface (API): A software interface that provides programmatic access to services by a software program, thus allowing application software to exchange data and communicate with each other using standardized requests and responses. It allows different programs to work together without revealing the internal details of how each works. A DE tool is typically provided with an API library for code-interface access.
Script: A sequence of instructions that is interpreted and run within or carried out by another program, without compilation into a binary file to be run by itself through a computer processor without the support of other programs.
API scripts: Scripts that implement particular functions available via the IDEP as disclosed herein. An API script may be an API function script encapsulated in a model splice, or an “orchestration script” or “platform script” that orchestrates a workflow through a digital thread built upon interconnected model splices.
Platform API or ISTARI API: A library of API scripts available on the IDEP as disclosed herein.
API function scripts, “splice functions,” “splice methods,” “ISTARI functions,” or “function nodes”: A type of API scripts. When executed, an API function script inputs into or outputs from a DE model or DE model splice. An “input” function, input method, or “input node” allows updates or modifications to an input DE model. An “output” function, output method, or “output node” allows data extraction or derivation from an input DE model via its model splice. An API function script may invoke native API function calls of native DE tools, where the terms “native” and “primal” may refer to existing DE model files, functions, and API libraries associated with specific third-party DE tools, including both proprietary and open-source ones.
Endpoints: an endpoint in the context of software and networking is a specific digital location or destination where different software systems communicate with each other. It enables external systems to access the features or data of an application, operating system, or other services. An API endpoint is the point of interaction where APIs receive requests and return data in response. A software development kit (SDK) endpoint or SDK-defined endpoint similarly provides a service handle for use with an SDK. References to API endpoints in the present disclosure are equally applicable to SDK endpoints.
Artifact: According to the DAU, a digital artifact is “an artifact produced within, or generated from, a DE ecosystem” to “provide data for alternative views to visualize, communicate, and deliver data, information, and knowledge to stakeholders.” In the present disclosure, a “digital artifact” or “artifact” is an execution result from an output API function script within a model splice. Multiple artifacts may be generated from a single DE model or DE model splice.
Model splice: Within the present disclosure, a “model splice”, “model wrapper”, or “model graft” of a given DE model file comprises locators to or copies of (1) DE model data or digital artifacts extracted or derived from the DE model file, including model metadata, and (2) splice functions (e.g., API function scripts) that can be applied to the DE model data. The splice functions provide unified and standardized input and output API endpoints for accessing and manipulating the DE model data. The DE model data are model-type-specific, and a model splice is associated with model-type-specific input and output schemas. One or more different model splices may be generated from the same input DE model file(s), based on the particular user application under consideration, and depending on data access restrictions. In some contexts, the shorter terms “splice”, “wrapper”, and/or “graft” are used to refer to spliced, wrapped, and/or grafted DE models.
Model representation: Within the present disclosure, “model representation” of a given DE model includes any embodiment of the engineering model in the form of DE model file(s), model splices, or collections of digital artifacts derived from the DE model. In some embodiments, a DE model representation comprises model-type-specific locators to DE model data and metadata, potentially including standardized input and output API endpoints for accessing and manipulating the DE model data. Discussions related to the usage of model splices in the present disclosure are applicable to any other forms of model representation as well.
Model splicing or DE model splicing: A process for generating a model splice from a DE model file. DE model splicing encompasses human-readable document model splicing, where the DE model being spliced is a human-readable text-based document.
Model splicer: Program code or script (uncompiled) that performs model splicing of DE models. A DE model splicer for a given DE model type, when applied to a specific DE model file of the DE model type, retrieves, extracts, or derives DE model data associated with the DE model file, generates and/or encapsulates splice functions and instantiates API endpoints according to input/output schemas.
Model splice linking: Generally refers to jointly accessing two or more DE model splices via API endpoints or splice functions. For example, data may be retrieved from one splice to update another splice (e.g., an input splice function of a first model splice calls upon an output splice function of a second model splice); data may be retrieved from both splices to generate a new output (e.g., output splice functions from both model splices are called upon); data from a third splice may be used to update both a first and a second splice (e.g., input splice functions from both model splices are called upon). In the present disclosure, “model linking” and “model splice linking” may be used interchangeably, as linked model splices map to correspondingly linked DE models.
Digital thread, Software-defined digital thread, Software-code-defined digital thread, or Software digital thread: According to the DAU, a digital thread is “an extensive, configurable and component enterprise-level analytical framework that seamlessly expedites the controlled interplay of authoritative technical data, software, information, and knowledge in the enterprise data-information-knowledge systems, based on the digital system model template, to inform decision makers throughout a system's lifecycle by providing the capability to access, integrate, and transform disparate data into actionable information.” Within the IDEP as disclosed herein, a digital thread is a platform script that calls upon the platform API to facilitate, manage, or orchestrate a workflow through linked model splices to provide the aforementioned capabilities. That is, a digital thread within the IDEP is a computer-executable script that connects data from one or more DE models, data sources, or physical artifacts to accomplish a specific mission or business objective, and may be termed a “software-defined digital thread” or “software digital thread” that implements a communication framework or data-driven architecture that connects traditionally siloed DE models to enable seamless information flow among the DE models via model splices. In various embodiments, a digital thread associated with a digital twin is configured to execute a scripted workflow associated with the digital twin.
Tool linking: Similar to model splice linking, tool linking generally refers to jointly accessing two or more DE tools via model splices, where model splice functions that encapsulate disparate DE tool functions are called upon jointly to perform a DE task.
Zero-trust security: An information security principle based on the assumption of no implicit trust between any elements, agents, or users. Zero trust may be carried out by implementing systematic mutual authentication and least privileged access, typically through strict access control, algorithmic impartiality, and data isolation. Within the IDEP as disclosed herein, least privileged access through strict access control and data isolation may be implemented via model splicing and the IDEP system architecture.
Zero-knowledge approach: A zero-knowledge approach in data operations refers to a method where computational processes and data analyses are conducted such that the underlying data remains completely confidential and undisclosed to the parties performing the operations. This technique enables the validation, aggregation, and processing of data without exposing the actual data content, thereby preserving privacy and confidentiality.
Hyperscale capabilities: The ability of a system architecture to scale adequately when faced with massive demand.
IDEP enclave or DE platform enclave: A central command hub responsible for the management and functioning of DE platform operations. An enclave is an independent set of cloud resources that are partitioned to be accessed by a single customer (i.e., single-tenant) or market (i.e., multi-tenant) that does not take dependencies on resources in other enclaves.
IDEP exclave or DE platform exclave: A secondary hub situated within a customer environment to assist with customer DE tasks and operations. An exclave is a set of cloud resources outside enclaves managed by the IDEP, to perform work for individual customers. Examples of exclaves include virtual machines (VMs) and/or servers that the IDEP maintains to run DE tools for customers who may need such services.
Digital twin: According to the DAU, a digital twin is “a virtual replica of a physical entity that is synchronized across time. Digital twins exist to replicate configuration, performance, or history of a system. Two primary sub-categories of digital twin are digital instance and digital prototype.” A digital instance is “a virtual replica of the physical configuration of an existing entity; a digital instance typically exists to replicate each individual configuration of a product as-built or as-maintained.” A digital prototype is “an integrated multi-physical, multiscale, probabilistic model of a system design; a digital prototype may use sensor information and input data to simulate the performance of its corresponding physical twin; a digital prototype may exist prior to realization of its physical counterpart.” Thus, a digital twin is a real-time virtual replica of a physical object or system, with bi-directional information flow between the virtual and physical domains.
Authoritative twin: A reference design configuration at a given stage of a product life cycle. At the design stage, an authoritative twin is the twin configuration that represents the best design target. At the operational stage, an authoritative twin is the twin configuration that best responds to the actual conditions on the ground or “ground-truths”.
Admins or Administrators: Project managers or other authorized users. Admins may create templates in the documentation system and have high-level permissions to manage settings in the IDEP.
Requesters: Users who use the platform for the implementation of the modeling and simulations towards certification and other purposes, and who may generate documentation in the digital documentation system, but do not have admin privileges to alter the required templates, document formats, or other system settings.
Reviewers/Approvers: Users who review and/or approve templates, documents, or other system data.
Contributors: Users who provide comments or otherwise contribute to the IDEP.
Resource-capability mapping: A framework for identifying and linking available resources with the capabilities they enable or support. An exemplary resource-capability mapping is the IDMP API, where the resource refers to third-party tools and functions integrated into and accessible via the IDMP, and where the exemplary capability refers to IDMP functions written in scripts for completing certain tasks using the available resource. Such resource-capability mappings may be used to identify how tool-specific resources such as tool functions, access and control capabilities, human-machine interfaces, processes, and objects can be allocated, invoked, and utilized efficiently and effectively to achieve specific IDMP platform functions or tasks. Resource capability mapping also assists with zero-knowledge implementations where the capability details are available to a user while the specific digital tool resource or its functions are only mapped within the customer environment.
AI Agent or Tool Agent: a software entity or module that takes instructions from the enclave and acts on behalf of a user or another program to perform specific tasks or operations related to an AI model or a DE tool. An AI agent or a tool agent may be designed as part of the IDMP but deployed by a customer within a secured customer environment to interface in-between the IDMP, AI models, and/or proprietary tools the customer is licensed for. Inside the customer environment, modular agents interact directly with the domain-specific tools and models to allow for bi-directional data flow across distributed tools.

### An Interconnected Digital Engineering Platform (IDEP) Architecture

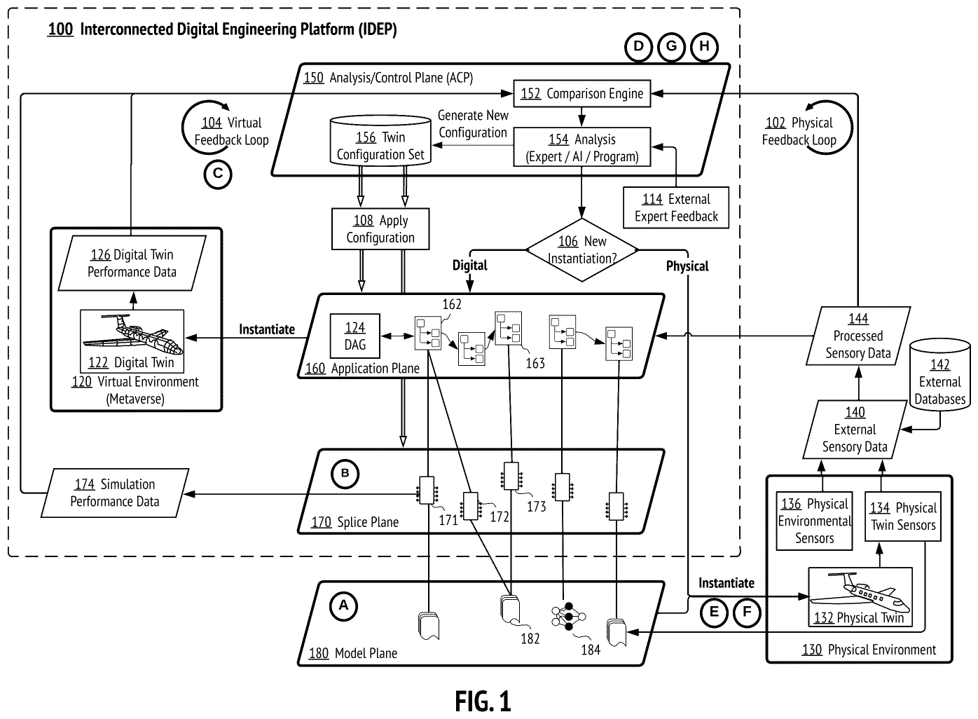

FIG. 1 shows an exemplary interconnected digital engineering platform (IDEP) architecture, in accordance with some embodiments of the present invention. IDEP 100 streamlines the process of product development from conception to production, by using a virtual representation or digital twin (DTw) 122 of the product to optimize and refine features before building a physical prototype or physical twin (PTw) 132, and to iteratively update DTw 122 until DTw 122 and PTw 132 are in sync to meet the product's desired performance goals.

Specifically, a product (e.g., airplane, spacecraft, exploration rover, missile system, automobile, rail system, marine vehicle, remotely operated underwater vehicle, robot, drone, medical device, biomedical device, pharmaceutical compound, drug, power generation system, smart grid metering and management system, microprocessor, integrated circuit, building, bridge, tunnel, chemical plants, oil and gas pipeline, refinery, etc.) manufacturer may use IDEP platform 100 to develop a new product. The engineering team from the manufacturer may create or instantiate digital twin (DTw) 122 of the product in a virtual environment 120, encompassing detailed computer-aided design (CAD) models and finite element analysis (FEA) or computational fluid dynamics (CFD) simulations of component systems such as fuselage, wings, engines, propellers, tail assembly, and aerodynamics. DTw 122 represents the product's design and performance characteristics virtually, allowing the team to optimize and refine features before building a physical prototype 132 in a physical environment 130. In some embodiments, PTw 132 may be an existing entity, while DTw 122 is a digital instance that replicates individual configurations of PTw 132, as-built or as-maintained. In the present disclosure, for illustrative purposes only, DTw 122 and PTw 132 are discussed in the context of building a new product, but it would be understood by persons of ordinary skill in the art that the instantiation of DTw 122 and PTw 132 may take place in any order, based on the particular use case under consideration.

Digital models (e.g., CAD models, FEA models, CFD models) used for creating DTw 122 are shown within a model plane 180 in FIG. 1. Also shown in model plane 180 is a neural network (NN) model 184, which may provide machine-learning based predictive modeling and simulation for a DE process. A DE model such as 182 may be spliced into one or more model splices, such as 172 and 173 within a splice plane 170. Individual DTws such as 122 are instantiated from splice plane 170 via an application plane 160. A model splice such as 172 may be linked to another model splice such as 171 by a platform script or application 162 on application plane 160 into a digital thread. Multiple digital threads such as 162 and 163 may be further linked across different stages or phases of a product life cycle, from concept, design, testing, to production. Digital threads further enable seamless data exchange and collaboration between departments and stakeholders, ensuring optimized and validated designs.

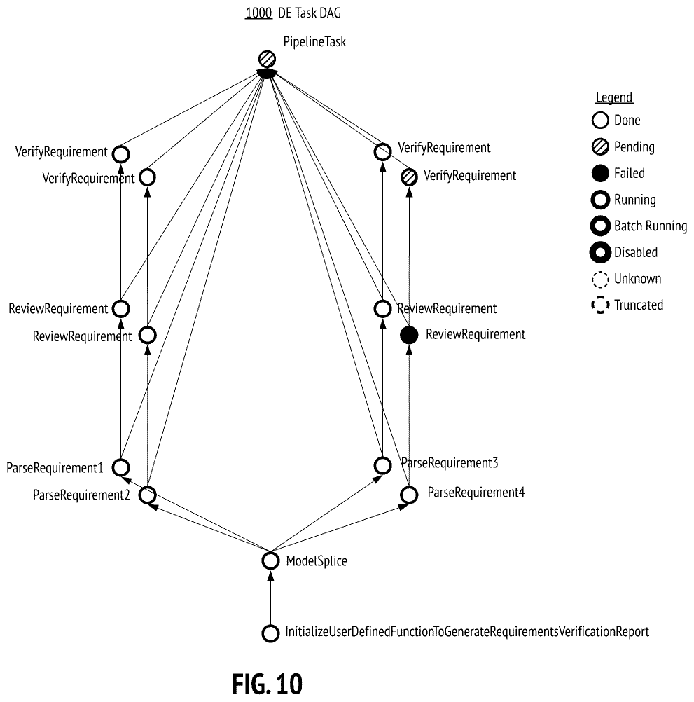

As model splicing provides input and output splice functions that can access and modify DE model data, design updates and DE tasks associated with the digital threads may be represented by scripted, interconnected, and pipelined tasks arranged in Directed Acyclic Graphs (DAGs) such as 124. A DE task DAG example is discussed in further detail with reference to FIG. 10.

To enhance the design, external sensory data 140 may be collected, processed, and integrated into application plane 160. This process involves linking data from different sources, such as physical sensors 134 on prototype 132, physical environmental sensors 136, and other external data streams such as simulation data from model plane 180. API endpoints provide access to digital artifacts from various environments (e.g., physical twin (PTw) sensor 134 data) and integrate them into the spliced plane 170 for the DTw 122. Model splices on the splice plane 170 enable autonomous data linkages and digital thread generation, ensuring DTw 122 accurately represents the product's real-world performance and characteristics.

To validate DTw 122's accuracy, the engineering team may build or instantiate PTw 132 based on the same twin configuration (i.e., digital design). Physical prototype 132 may be equipped with numerous sensors 134, such as accelerometers and temperature sensors, to gather real-time performance data. This data may be compared with the DTw's simulations to confirm the product's performance and verify its design.

Processed sensory data 144 may be used to estimate parameters difficult to measure directly, such as aerodynamic forces or tire contact patch forces. Such processed sensory data provide additional data for DTw 122, further refining its accuracy and reliability. Processed sensory data 144 may be generated from physical environment sensors 136 with physical environment 130, and may be retrieved from other external databases 142, as discussed below.

During development, feedback from customers and market research may be collected to identify potential improvements or adjustments to the product's design. At an analysis & control plane (ACP) 150, subject matter experts (SMEs) may analyze processed sensory data 144 and external expert feedback 114, to make informed decisions on necessary design changes. Such an analysis 154 may be enhanced or entirely enabled by algorithms (i.e., static program code) or artificial intelligence (AI) modules. Linking of digital threads such as 162, physical sensors 134 and 136, processed sensory data 144, and expert feedback data 114 occurs at ACP 150, where sensor and performance data is compared, analyzed, leading to modifications of the underlying model files through digital threads.

In particular, sensory data 144 from physical environment 130 and performance data 126 from virtual environment 120 may be fed into a comparison engine 152. Comparison engine 152 may comprise tools that enable platform users to compare various design iterations with each other and with design requirements, identify performance lapses and trends, and run verification and validation (V&V) tools.

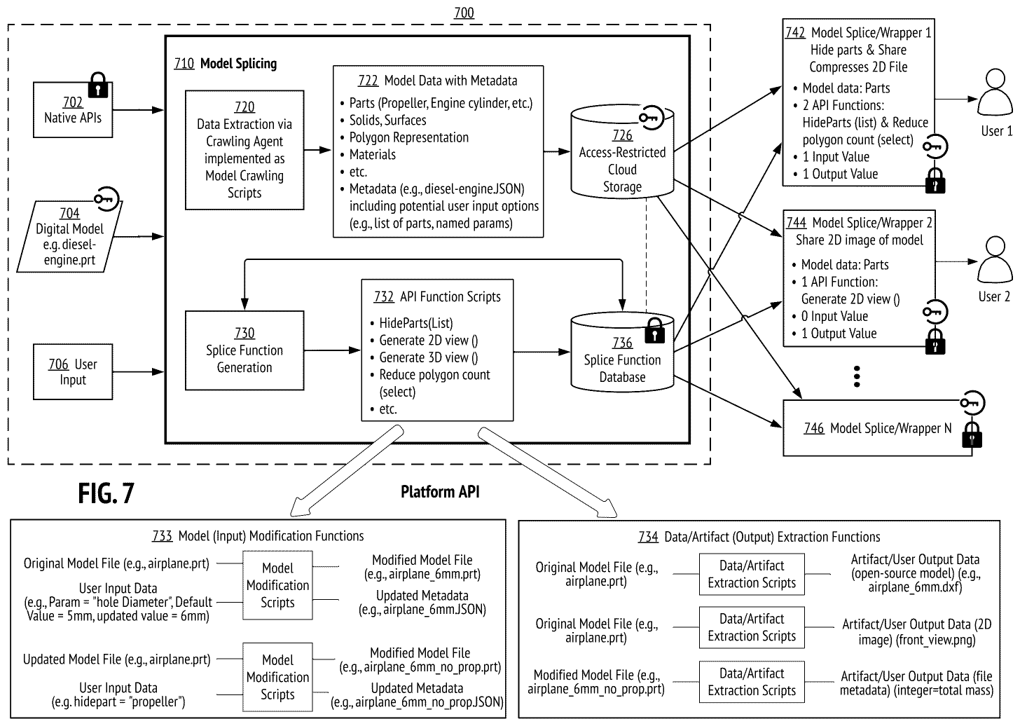

Model splicing is discussed in further detail with reference to FIGS. 7 to 9, and 11 to 33. Model splicing enables the scripting of any DE operation involving DE model files in model plane 180, where each DE model is associated with disparate and siloed DE tools. Codification of DE models and DE operations with a unified corpus of scripts enable IDEP 100 to become an aggregator where a large space of DE activities associated with a given product (e.g., airplane, spacecraft, exploration rover, missile system, automobile, rail system, marine vehicle, remotely operated underwater vehicle, robot, drone, medical device, biomedical device, pharmaceutical compound, drug, power generation system, smart grid metering and management system, microprocessor, integrated circuit, building, bridge, tunnel, chemical plants, oil and gas pipeline, refinery, etc.) may be threaded through program code. Thus, model splicing enables the linking and manipulation of all model files (e.g., 182, 184) associated with a given product within the same interconnected DE platform or DE ecosystem 100. As a consequence, the generation and training of AI modules for the purpose of manipulating DE models (e.g., 182), digital threads (e.g., 162), and digital twins (e.g., 122) become possible over the programmable and unified IDEP 100.

### Virtual and Physical Feedback Loops

FIG. 1 uses letter labels “A” to “H” to denote different stages of a product's lifecycle. At each stage, IDEP 100 enables feedback loops whereby data emanating from a PTw or a DTw is analyzed at ACP 150, leading to the generation of a new twin configuration based on design modifications. The new twin configuration may be stored in a twin configuration set and applied through the application and splice planes, yielding modified model files that are registered on the digital thread.

A virtual feedback loop 104 starts with a decision 106 to instantiate new DTw 122. A DAG of hierarchical tasks 124 allows the automated instantiation of DTw 122 within virtual environment 120, based on a twin configuration applied at a process step 108 from a twin configuration set 156. DTw 122 and/or components thereof are then tested in virtual environment 120, leading to the generation of DTw performance data 126. Concurrently, DTw 122 and/or components thereof may be tested and simulated in model plane 180 using DE software tools, giving rise to test and simulation performance data 174. Performance data 126 and 174 may be combined, compared via engine 152, and analyzed at ACP 150, potentially leading to the generation and storage of a new twin configuration. The eventual decision to instantiate a DTw from the new twin configuration completes virtual feedback loop 104.

A physical feedback loop 102 starts with a decision 106 to instantiate a new PTw 132. PTw 132 may be instantiated in a physical environment 130 from the model files of model plane 180 that are associated with an applied twin configuration from the twin configuration set 156. PTw 132 and/or components thereof are then tested in physical environment 132, leading to the generation of sensory data from PTw sensors 134 and environmental sensors 136 located in physical environment 130. This sensory data may be combined with data from external databases to yield processed sensory data 144.

Data from PTw sensors 134 may be directly added to the model files in model plane 180 by the DE software tools used in the design process of PTw 132. Alternatively, PTw sensor data may be added to digital thread 162 associated with PTw 132 directly via application plane 160. In addition, processed sensory data 144 may be integrated into IDEP 100 directly via application plane 160. For example, processed sensory data 144 may be sent to ACP 150 for analysis, potentially leading to the generation and storage of a new twin configuration. The eventual decision to instantiate a PTw from the new twin configuration completes physical feedback loop 102.

At each stage A to H of the product life cycle, the system may label one twin configuration as a current design reference, herein described as an “authoritative twin” or “authoritative reference”. The authoritative twin represents the design configuration that best responds to actual conditions (i.e., the ground truth). U.S. provisional patent application No. 63/470,870 (Docket No. IST-03.001P) provides a more complete description of authoritative twins and their determination, and is incorporated by reference in its entirety herein.

With faster feedback loops from sensor data and expert recommendations, the system updates DTw 122 to reflect latest design changes. This update process may involve engineering teams analyzing feedback 154 and executing the changes through IDEP 100, or automated changes enabled by IDEP 100 where updates to DTw 122 are generated through programmed algorithms or AI modules. This iterative updating process continues until DTw 122 and PTw 132 are in sync and the product's performance meets desired goals. While IDEP 100 may not itself designate the authoritative reference between a DTw or a PTw, the platform provides configurable mechanisms such as policies, algorithms, voting schema, and statistical support, whereby agents may designate a new DTw as the authoritative DTw, or equivalently in what instances the PTw is the authoritative source of truth.

When significant design improvements are made, a new PTw prototype may be built based on the updated DTw. This new prototype undergoes further testing and validation, ensuring the product's performance and design align with project objectives.

Once DTw 122 and PTw 132 have been validated and optimized, the product is ready for production. A digital thread connecting all stages of development can be queried via splice plane 170 to generate documentation as needed to meet validation and verification requirements. The use of model splicing, along with the feedback architecture shown in FIG. 1, improves the efficiency of the overall product innovation process.

### Interconnected DE Platform and Product Lifecycle

In FIG. 1, letter labels “A” to “H” indicate the following major steps of a product lifecycle, according to some embodiments of the current invention:
A. Digital models reside within customer environments: a product may be originally represented by model files that are accessible via software tools located within customer environments. Model plane 180 encompasses all model files (e.g., 182) associated with the product.
B. Preparatory steps for design in the digital realm: splice plane 170 encompasses model splices (e.g., 172) generated from DE model file through model splicing. Model splicing enables the integration and sharing of DE model files within a single platform, as described in detail with reference to FIGS. 7 to 9, and 11 to 33
C. Link threads as needed among model splices: to implement a product, model splices are linked through scripts within application plane 160. A digital twin (DTw) 122 englobing as-designed product features may be generated from application plane 160 for running in virtual environment 120. The complete twin configuration of a generated DTw is saved in twin configuration set 156 located at the analysis & control plane (ACP) 150. Features or parts of DTw 122 may be simulated in model plane 180, with performance data 174 accessed through splice plane 170. In one embodiment, features or parts of PTw 132 or DTw 122 configuration may be simulated outside the platform, where performance data is received by the ACP 150 for processing, in a similar way as performance data 126 received from DTw 122.
D. Finalize “As-designed”: performance data 126 from DTw 122 or simulation performance data 174 attained through model plane 180 and accessed through model splicing may be collected and sent to ACP 150 for analysis. Performance data from different iterations of DTw 122 may be compared via engine 152 to design requirements. Analysis of the differences may lead to the generation of new twin configurations that are stored at twin configuration set 156. Each twin configuration in twin configuration set 156 may be applied at application plane 160 and splice plane 170 via process step 108 to instantiate a corresponding DTw. Multiple DTws may be generated and tested, consecutively or simultaneously, against the design requirements, through comparison engine 152 and analysis module 154. Verification and validation tools may be run on the various DTw iterations.
E. Finalize “As-manufactured”: once a DTw 122 satisfies the design requirements, a corresponding PTw 132 prototype may be instantiated from the spliced model files (e.g., 172). Sensor data originating from the PTw 134 or from within the physical environment 136 may be collected, combined with other external data 142 (e.g., sensor data from other physical environments). The resulting processed sensory data 144 may be sent to the analysis & control plane 150 to be compared with performance data 126 from DTws and simulations (e.g., 174), leading to further DTw 122 and PTw 132 iterations populating the twin configuration set 156. Processed sensory data 144 may also be mapped to the digital threads (e.g., 164) and model splices (e.g., 172) governing the tested PTw 132 through the application plane 160.
F. Finalize “As-assembled”: once the manufacturing process is completed for the various parts, as a DTw and as a PTw, the next step is to finalize the assembled configuration. This involves creating a digital representation of the assembly to ensure it meets the specified requirements. The digital assembly takes into account the dimensions and tolerances of the “as-manufactured” parts. To verify the feasibility of the digital assembly, tests are conducted using the measured data obtained from the physical assembly and its individual components. Measurement data from the physical component parts may serve as the authoritative reference for the digital assembly, ensuring alignment with the real-world configuration. The digital assembly is compared with the actual physical assembly requirements for validation of the assembled configuration. Subsequently, the digital assembly tests and configurations serve as an authoritative reference for instructions to guide the physical assembly process and ensure accurate replication. IDEP 100 components described above may be used in the assembly process. In its authoritative iteration, DTw 122 ultimately captures the precise details of the physical assembly, enabling comprehensive analysis and control in subsequent stages of the process.
G. Finalize “As-operated”: to assess the performance of the physical assembly or its individual component parts, multiple digital twins 122 may be generated as needed. These digital twins are created based on specific performance metrics and serve as virtual replicas of the physical system. Digital twins 122 are continuously updated and refined in real-time using the operational data (e.g., 144) collected from monitoring the performance of the physical assembly or its components. This data may include, but are not limited to, processed sensory data, performance indicators, and other relevant information. By incorporating this real-time operational data, digital twins 122 stay synchronized with the actual system and provide an accurate representation of its operational performance. Any changes or improvements observed via sensory data 144 during the real-world operation of the assembly are reflected in DE models within the digital twins and recorded in the twin configuration set 156. This ensures that the digital twins remain up-to-date and aligned with the current state of the physical system.
H. Predictive analytics/Future performance: The design process may continue iteratively in virtual environment 120 through new DTw 122 configurations as the product is operated. Multiple digital twins may be created to evaluate the future performance of the physical assembly or its component parts based on specific performance metrics. Simulations are conducted with various control policies to assess the impact on performance objectives and costs. The outcome of these simulations helps in deciding which specific control policies should be implemented (e.g., tail volume coefficients and sideslip angle for an airplane product). The digital twin DE models (e.g., 182) are continuously updated and refined using the latest sensor data, control policies, and performance metrics to enhance their predictive accuracy. This iterative process ensures that the digital twins (e.g., 122, 156) provide reliable predictions of future performance and assist in making informed decisions.

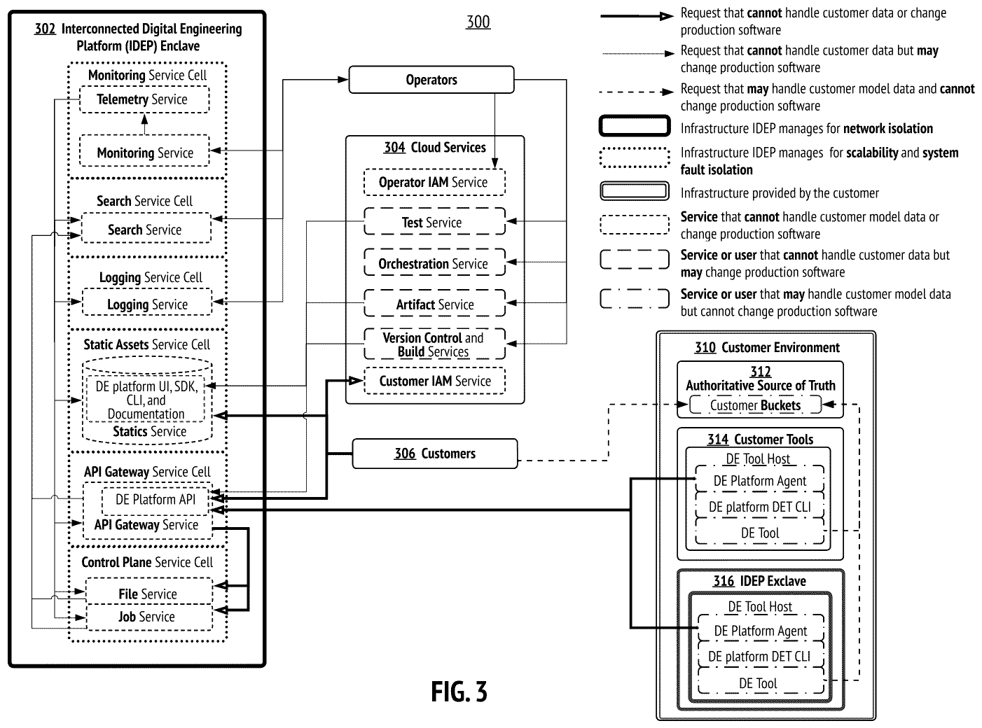

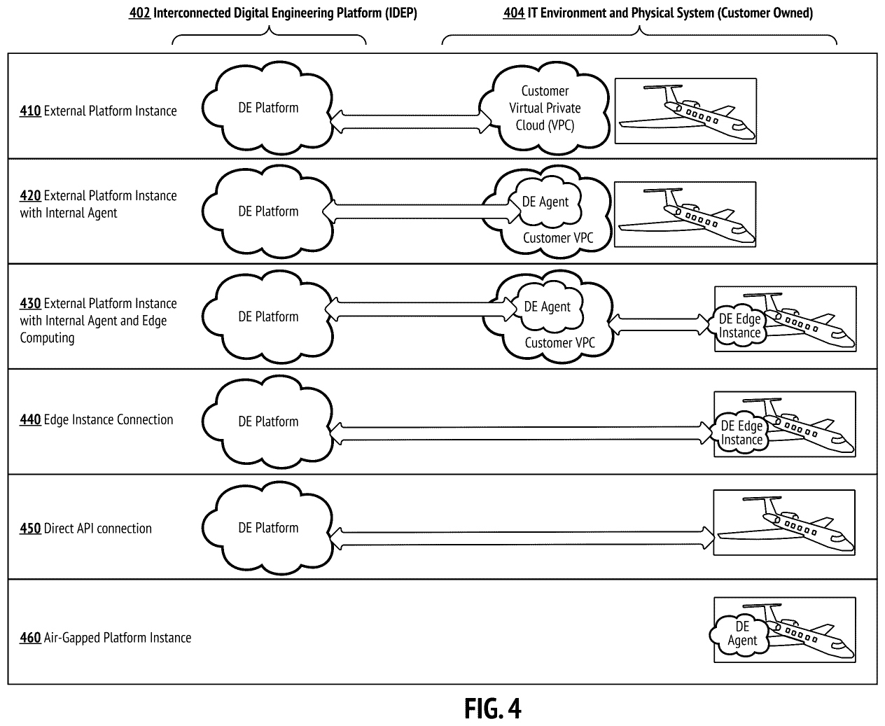

The hardware components making up IDEP 100 (e.g., servers, computing devices, storage devices, network links) may be centralized or distributed among various entities, including one or more DE service providers and DE clients, as further discussed in the context of FIGS. 3 and 4. FIG. 4 shows an illustration of various potential configurations for instancing a DE platform within a customer's physical system and information technology (IT) environment, usually a virtual private cloud (VPC) protected by a firewall.

DE Documentation with Live or Magic Documents

The methods and systems described herein enable the updating and generation of DE documents using the full functionality of the IDEP shown in FIG. 1. In FIG. 1, the IDEP virtual feedback loop 104 allows the scripting of program code within a digital thread 162 for the generation, storing, and updating of digital twins 122 and twin configurations 156. Similarly, the IDEP virtual feedback loop 104 also allows the scripting of program code within a digital thread 162 for the generation, storing, and updating of DE documents. This enables the creation and maintenance of so-called live digital engineering documents.

Live DE documents are more akin to a DTw than a conventional static document in that they are configured, through a digital thread, to be continuously updated to reflect the most current changes within a particular twin configuration. In particular, an authoritative live DE document is configured to reflect the latest authoritative twin configuration. The “printing” of a live DE document corresponds to the generation of a frozen (i.e., static) time-stamped version of a live DE document. Therefore, “printing”—for a live DE document—is equivalent to “instantiation” for a DTw.

Live DE documents may also be known as magic documents as changes implemented within a twin configuration (e.g., through a modification of a model file) may appear instantaneously within the relevant data fields and sections of the live DE document. Similarly, authoritative live DE documents may also be known as authoritative magic documents as they continuously reflect data from the authoritative twin, thus always representing the authoritative source of truth.

Given the massive quantities of data and potential modifications that are carried out during a product's lifecycle, the scripts implementing live DE documentation may be configured to allow for a predefined maximum delay between the modification of a model file and the execution of the corresponding changes within a live DE document. Moreover, for similar reasons, the scripts implementing live DE documentation may be restricted to operate over a specified subset of model files within a DTw, thus reflecting changes only to key parameters and configurations of the DTw.

In one embodiment of the present invention, an IDEP script (e.g., an IDEP application) having access to model data via one or more model splices and DE document templates to create and/or update a live DE document may dynamically update the live DE document using software-defined digital threads over an IDEP platform. In such an embodiment, the IDEP script may receive user interactions dynamically. In response to the user updating data for a model and/or a specific parameter setting, the IDEP script may dynamically propagate the user's updates into the DE document through a corresponding digital thread.

In another embodiment of the present invention, the IDEP script may instantiate a DE document with sufficient specification to generate a physical twin (PTw). In such an embodiment, the IDEP script may receive a digital twin configuration of a physical twin, generate a live DE document associated with the digital twin configuration, receive a predetermined timestamp, and generate a printed DE document (i.e., a static, time-stamped version of the live DE document at the predetermined timestamp). Such an operation may be referred to as the “printing of a digital twin”.

In yet another embodiment of the present invention, an IDEP script may instantiate (i.e., “print”) a DE document specifying an updated digital twin upon detecting the update. In such an embodiment, the IDEP script may detect a modification of a DE model or an associated digital thread. In response to detecting the modification, the IDEP script may update relevant data fields and sections of the live DE document based on the detected modification, and generate an updated printed DE document with the updated relevant data fields and sections based on the always-updated live DE document.

In various embodiments, a software-defined digital thread can be associated with a companion magic document (or “magic doc”) that encompasses live updates for one or more core parameters of the digital thread. In one embodiment, the magic doc includes key parameters describing the implementation of a user's intent. For example, in one embodiment, a companion magic doc for a given digital thread may include key data points and key orchestration script examples illustrating a user's intent (e.g., “increase a drone's wing span by 1%”). In one embodiment, a script-generating ML model receiving as input pseudocode or detailed user instructions derived from a user's intent, is trained on prior IDEP digital threads and documents. In addition to generating a digital thread (with orchestration scripts and comments), the script-generating ML model is also configured to generate a magic doc that explains how the generated digital thread addresses the user intent.

In some embodiments, receiving user interactions with a DE model, modifications to a DE model, or modifications to an associated digital thread, may be carried out through a push configuration, where a model splicer or a script of the digital thread sends any occurring relevant updates to the IDEP script immediately or within a specified maximum time delay. In other embodiments, receiving user interactions with a DE model, modifications of a DE model, or modifications of an associated digital thread, may be carried out through a pull configuration, where a model splicer or a script of the digital thread flag recent modifications until the IDEP script queries relevant DE models (via their model splices) or associated digital threads, for flagged modification. In these embodiments, the IDEP script may extract the modified information from the modified DE models (via their model splices) or the modified digital threads, in order to update a live DE document. In yet other embodiments, receiving user interactions with a DE model, modifications of a DE model, or modifications of an associated digital thread, may be carried out through a pull configuration, where the IDEP script regularly checks relevant DE models (via their model splices) or associated digital threads, for modified data fields, by comparing the data found in the live DE document with regularly extracted model and digital thread data. In these embodiments, the IDEP script may use the modified data to update the live DE document.

### Dynamic Document Updates

Some embodiments described herein center around documentation, or document preparation and update and on document management (e.g., for reviews). As discussed, some embodiments of the system allow for dynamic updates to documents, which pertain to software-defined digital threads in the IDEP platform and the accompanying documentation.

Use of an ML engine with the model data and templates to create and/or update documents almost instantaneously as a one-time action have been presented. Furthermore, the digital engineering platform interacts dynamically with the user. As the user interacts with the system and updates data for a model or a specific parameter setting, these changes may be propagated through the corresponding digital threads and to the associated documentation. The AI architectures involved include locally-instanced large language model (LLMs, for data security reasons) as well as non-LLM approaches (e.g., NLP-based), in order to create, update, or predict documentation in the form of sentences, paragraphs, and whole documents. At the same time, trying to update the entire system of digital threads for every update may be prohibitively slow and may present security risks to the system. Generating live DE documents that are updated based on a subset of a system's DE models and within a maximum time delay may therefore be more efficient.

### Interconnected Digital Engineering and Certification Ecosystem

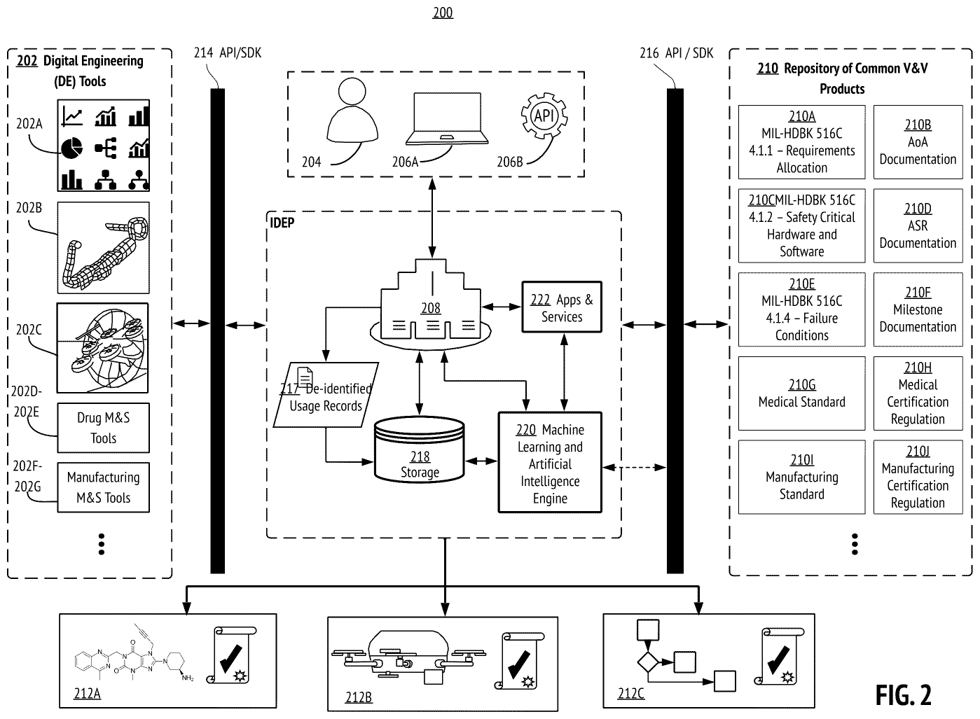

FIG. 2 shows an exemplary implementation of the IDEP as an interconnected digital engineering (DE) and certification ecosystem 200, and exemplary digitally certified products, in accordance with some embodiments of the present invention. Interconnected DE and certification ecosystem 200 may be viewed as a particular instantiation or implementation of IDEP 100 shown in FIG. 1. The IDEP may also be referred to as a “DE Metaverse.”

Interconnected DE and certification ecosystem 200 is a computer-based system that links models and simulation tools with their relevant requirements in order to meet verification, validation, and certification purposes. Verification refers to methods of evaluating whether a product, service, or system meets specified requirements and is fit for its intended purpose. For example, in the aerospace industry, a verification process may include testing an aircraft component to ensure it can withstand the forces and conditions it will encounter during flight. Verification also includes checking externally against customer or stakeholder needs. Validation refers to methods of evaluating whether the overall performance of a product, service, or system is suitable for its intended use, including its compliance with regulatory requirements and its ability to meet the needs of its intended users. Validation also includes checking internally against specifications and regulations. Interconnected DE and certification ecosystem 200 as disclosed herein is designed to connect and bridge large numbers of disparate DE tools and models from multitudes of engineering domains and fields, or from separate organizations who may want to share models with each other but have no interactions otherwise. In various embodiments, the system implements a robust, scalable, and efficient DE model collaboration platform, with extensible model splices having data structures and accompanying functions for widely distributed DE model types and DE tools, an application layer that links or connects DE models via APIs, digital threads that connect live engineering model files for collaboration and sharing, digital documentation management to assist with the preparation of engineering and certification documents appropriate for verification and validation (V&V) purposes, and AI-assistance with the functionalities of the aforementioned system components.

More specifically, FIG. 2 shows an example of an interconnected DE and certification ecosystem and examples of digitally certified products 212A, 212B, and 212C (collectively referred to as digitally certified products 212). For example, in some implementations, digitally certified product 212A may be an unmanned aerial vehicle (UAV) or other aircraft, digitally certified product 212B may be a drug or other chemical or biologic compound, and the digitally certified product 212C may be a process such as a manufacturing process. In general, the digitally certified products 212 can include any product, process, or solution that can be developed, tested, or certified (partially or entirely) using DE tools such as 202. In some implementations, digitally certified products 212 may not be limited to physical products, but can include non-physical products such as methodologies, processes and software, etc. While physical and physically-interacting systems often require multiple DE tools to assess for compliance with common V&V products simply by virtue of the need for modeling and simulation (M&S), many complex non-physical systems may also require multiple DE tools for product development, testing, and/or certification. With this in mind, various other possibilities for digitally certified products will be recognized by one of ordinary skills in the art. The inclusion of regulatory and certification standards, compliances, calculations, and tests (e.g., for the development, testing, and certification of products and/or solutions) enables users to incorporate relevant regulatory and certification standards, compliances, calculations, and test data directly into their DE workflow. Regulatory and certification standards, compliances, calculations, and tests are sometimes referred to herein as “common validation and verification (V&V) products.”

Digitally certified products 212 in FIG. 2 may be designed and/or certified using interconnected DE and certification ecosystem 200. Interconnected DE and certification ecosystem 200 may include a user device 206A, API 206B, or other similar human-to-machine, or machine-to-machine communication interfaces operated by a user. A user may be a human 204 of various skill levels, or artificial users such as algorithms, artificial intelligence, or other software that interface with ecosystem 200 through API 206B. Ecosystem 200 may further comprise a computing and control system 208 (“computing system 208” hereinafter) connected to and/or including a data storage unit 218, an artificial intelligence (AI) engine 220, and an application and service layer 222. In some embodiments, the artificial intelligence (AI) engine 220 is a machine learning (ML) engine. References to “machine learning engine 220 “or “ML engine 220” may be extended to artificial intelligence (AI) engines 220 more generally. For the purposes of clarity, any user selected from various potential human or artificial users are referred to herein simply as the user 204. In some implementations, computing system 208 may be a centralized computing system; in some implementations, computing system 208 may be a distributed computing system. In some cases, user 204 may be considered part of ecosystem 200, while in other implementations, user 204 may be considered separately from ecosystem 200. Ecosystem 200 may include one or more DE tools 202, such as data analysis tool 202A, computer-aided design (CAD) and finite element analysis (FEA) tool 202B, simulation tool 202C, drug modeling and simulation (M&S) tools 202D-202E, manufacturing M&S tools 202F-202G, etc. Ecosystem 200 may also include a repository of common V&V products 210, such as regulatory standards 210A-210F related to the development and certification of a UAV, medical standard 210G (e.g., CE marking (Europe), FCC Declaration of Conformity (USA), IECEE CB Scheme (Europe, North America, parts of Asia & Australia), CDSCO (India), FDA (USA), etc.), medical certification regulation 210H (e.g., ISO 13485, ISO 14971, ISO 9001, ISO 62304, ISO 10993, ISO 15223, ISO 11135, ISO 11137, ISO 11607, IEC 60601, etc.), manufacturing standard 210I (e.g., ISO 9001, ISO 9013, ISO 10204, EN 1090, ISO 14004, etc.), and manufacturing certification regulation 210J (e.g., General Certification of Conformity (GCC), etc.), etc.

In FIG. 2, computing system 208 is centrally disposed within the architecture and is configured to communicate with (e.g., receive data from and transmit data to) user device 206A or API 206B such as an API associated with an artificial user, DE tools 202 via an API or software development kit (SDK) 214, and repository of common V&V products 210 via an API/SDK interface 216. For example, computing system 208 may be configured to communicate with user device 206A and/or API 206B to send or receive data corresponding to a prototype of a design, information about a user (e.g., user credentials), engineering-related inputs/outputs associated with DE tools 202, digitized common V&V products, an evaluation of a product design, user instructions (e.g., search requests, data processing instructions, etc.), and more. Computing system 208 may also be configured to communicate with one or more DE tools 202 to send engineering-related inputs for executing analyses, models, simulations, tests, etc. and to receive engineering-related outputs associated with the results. Computing system 208 may also be configured to communicate with repository of common V&V products 210 to retrieve data corresponding to one or more digitized common V&V products 210 and/or upload new common V&V products, such as those received from user 204, to repository of common V&V products 210. All communications may be transmitted and corroborated securely, for example, using methods relying on zero-trust security. In some implementations, the computing system of the ecosystem may interface with regulatory and/or certification authorities (e.g., via websites operated by the authorities) to retrieve digitized common V&V products published by the regulatory authorities that may be relevant for a product that a user is designing. In some implementations, the user may upload digitized common V&V products to the ecosystem themselves.

Computing and control system 208 may process and/or store the data that it receives to perform analysis and control functionalities, and in some implementations, may access machine learning engine 220 and/or application and service layer 222, to identify useful insights based on the data, as further described herein. The central disposition of computing system 208 within the architecture of the ecosystem has many advantages including reducing the technical complexity of integrating the various DE tools; improving the product development experience of user 204; intelligently connecting common V&V products such as standards 210A-210F to DE tools 202 most useful for satisfying requirements associated with the common V&V products; and enabling the monitoring, storing, and analysis of the various data that flows between the elements of the ecosystem throughout the product development process. In some implementations, the data flowing through and potentially stored by the computing system 208 can also be auditable to prevent a security breach, to perform data quality control, etc. Similarly, any analysis and control functions performed via computing system 208 may be tracked for auditability and traceability considerations.

Referring to one particular example shown in FIG. 2, user 204 may use the DE and certification ecosystem to produce a digitally certified UAV 212B. For example, user 204 may be primarily concerned with certifying the UAV as satisfying the requirements of a particular regulatory standard 210E relating to failure conditions of the UAV (e.g., “MIL-HDBK 516C 4.1.4—Failure Conditions”). In this usage scenario, user 204 may develop a digital prototype of the UAV on user device 206A or using API 206B and may transmit prototype data (e.g., as at least one of a CAD file, a MBSE file, etc.) to computing system 208. Along with the prototype data, user 204 can transmit, via user device 206A, additional data including an indication of the common V&V product that user 204 is interested in certifying the product for (e.g., regulatory standard 210E), user credential information for accessing one or more capabilities of computing system 208, and/or instructions for running one or more digital models, tests, and/or simulations using a subset of DE tools 202.

Referring to another example shown in FIG. 2, user 204 can use the DE and certification ecosystem to produce a digitally certified drug, chemical compound, or biologic 212A. For example, user 204 may be primarily concerned with certifying drug, chemical compound, or biologic 212A as satisfying the requirements of a particular medical standard 210G and medical certification regulation 210H. In this usage scenario, user 204 can develop a digital prototype of the drug, chemical compound, or biologic on user device 206A or using API 206B and can transmit the prototype data (e.g., as a molecular modeling file) to computing system 208. Along with the prototype data, user 204 can transmit, via user device 206A, additional data including an indication of the common V&V products that user 204 is interested in certifying the product for (e.g., medical standard 210G and medical certification regulation 210H), user credential information for accessing one or more capabilities of computing system 208, and/or instructions for running one or more digital models, tests, and/or simulations using a subset of DE tools 202 (e.g., drug M&S tools 202D-202E).

Referring to yet another example shown in FIG. 2, user 204 can use the digital engineering and certification ecosystem to produce a digitally certified manufacturing process 212C. For example, user 204 may be primarily concerned with certifying manufacturing process 212C as satisfying the requirements of a particular manufacturing standard 210I and manufacturing certification regulation 210J. In this usage scenario, user 204 can develop a digital prototype of the manufacturing process on user device 206A or using API 206B and can transmit the prototype data to computing system 208. Along with the prototype data, user 204 can transmit, via the user device 206A, additional data including an indication of the common V&V products that user 204 is interested in certifying the process for (e.g., manufacturing standard 210I and manufacturing certification regulation 210J), user credential information for accessing one or more capabilities of computing system 208, and/or instructions for running one or more digital models, tests, and/or simulations using a subset of DE tools 202 (e.g., manufacturing M&S tools 202F-202G).

In any of the aforementioned examples, computing system 208 can receive the data transmitted from user device 206A and/or API 206B and can process the data to evaluate whether the common V&V product of interest (e.g., regulatory standard 210E, medical standard 210G, medical certification regulation 210H, manufacturing standard 210I, manufacturing certification regulation 210J, etc.) is satisfied by the user's digital prototype, in the context of analysis and control plane 150 shown in FIG. 1. For example, this can involve communicating with the repository of common V&V products 210 via the API/SDK 216 to retrieve the relevant common V&V product of interest and processing the regulatory and/or certification data associated with the common V&V product to identify one or more requirements for the UAV prototype; the drug, chemical compound, or biologic prototype; the manufacturing process prototype; etc. In some implementations, repository of common V&V products 210 can be hosted by a regulatory and/or certification authority (or another third party), and retrieving the regulatory and/or certification data can involve using API/SDK 216 to interface with one or more data resources maintained by the regulatory and/or certification authority (or the another third party). In some implementations, the regulatory and/or certification data can be provided directly by user 204 via user device 206A and/or API 206B (e.g., along with the prototype data).

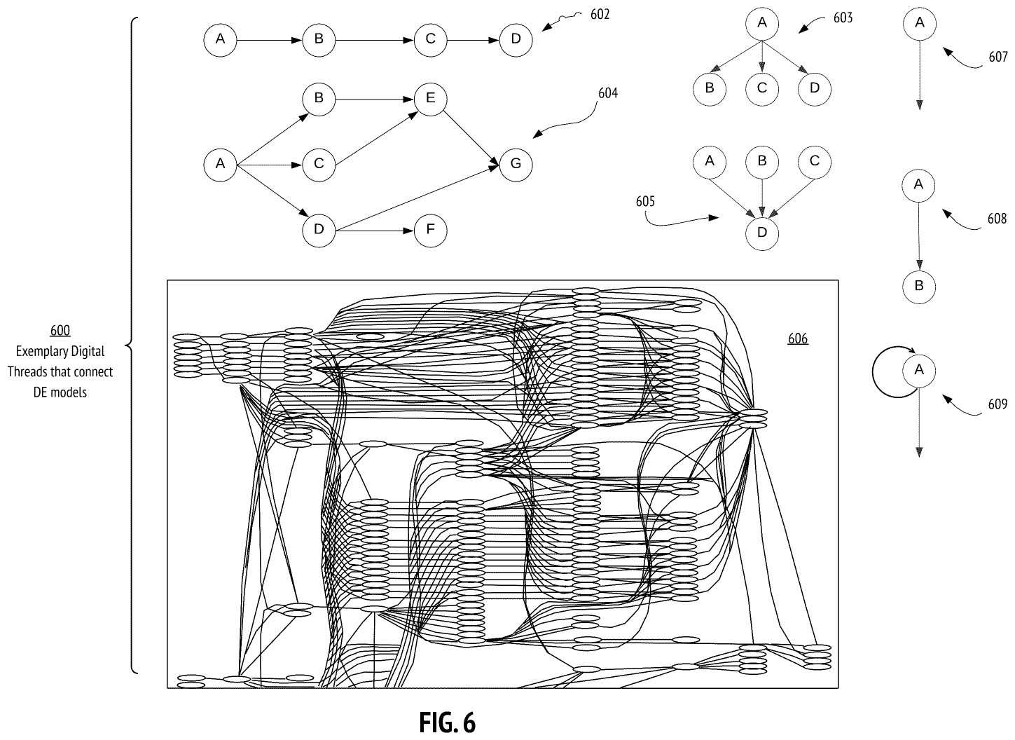

Evaluating whether the common V&V product of interest is satisfied by the user's digital prototype can also involve processing the prototype data received from user device 206A or API 206B to determine if the one or more identified requirements are actually satisfied. In some implementations, computing system 208 can include one or more plugins, local applications, etc. to process the prototype data directly at the computing system 208. For example, model splicing and digital threading applications are discussed in detail later with reference to FIGS. 6 to 9. In some implementations, the computing system can simply pre-process the received prototype data (e.g., to derive inputs for DE tools 202) and can then transmit instructions and/or input data to a subset of DE tools 202 via API/SDK 214 for further processing.

Not all DE tools 202 are necessarily required for the satisfaction of particular regulatory and/or certification standards. Therefore, in the UAV example provided in FIG. 2, computing system 208 may determine that only a data analysis tool 202A and a finite element analysis tool 202B are required to satisfy regulatory standard 210E for failure conditions. In the drug, chemical compound, or biologic example provided in FIG. 2, computing system 208 may determine that only drug M&S tools 202D-202E are required to satisfy medical standard 210G and medical certification regulation 210H. In the manufacturing process example provided in FIG. 2, computing system 208 may determine that only manufacturing M&S tools 202F-202G are required to satisfy manufacturing standard 210I and manufacturing certification regulation 210J. In other implementations, user 204 may themselves identify the particular subset of DE tools 202 that should be used to satisfy the common V&V product of interest, provided that user 204 is a qualified subject matter expert (SME). In other implementations, user 204 may input to computing system 208 some suggested DE tools 202 to satisfy a common V&V product of interest, and computing system 208 can recommend to user 204 a modified subset of DE tools 202 for final approval by user 204, provided that user 204 is a qualified SME. After a subset of DE tools 202 has been identified, computing system 208 can then transmit instructions and/or input data to the identified subset of DE tools 202 to run one or more models, tests, and/or simulations. The results (or “engineering-related data outputs” or “digital artifacts”) of these models, tests, and/or simulations can be transmitted back and received at computing system 208.

In still other implementations, user 204 may input a required DE tool such as 202F for meeting a common V&V product 210I, and the computing system 208 can determine that another DE tool such as 102G is also required to satisfy common V&V product 2101. The computing system can then transmit instructions and/or input data to both DE tools (e.g., 202F and 202G), and the outputs of these DE tools can be transmitted and received at computing system 208. In some cases, the input data submitted to one of the DE tools (e.g., 202G) can be derived (e.g., by computing system 208) from the output of another of the DE tools (e.g., 202F).

After receiving engineering-related data outputs or digital artifacts from DE tools 202, computing system 208 can then process the received engineering-related data outputs to evaluate whether or not the requirements identified in the common V&V product of interest (e.g., regulatory standard 210E, medical standard 2110G, medical certification regulation 210H, manufacturing standard 210I, manufacturing certification regulation 210J, etc.) are satisfied. For example, applications and services 222 may provide instructions for orchestrating validation or verification activities. In some implementations, computing system 208 can generate a report summarizing the results of the evaluation and can transmit the report to device 206A or API 206B for review by user 204. If all of the requirements are satisfied, then the prototype can be certified, resulting in digitally certified product 212 (e.g., digitally certified drug, chemical compound, or biologic 212A; digitally certified UAV 212B; digitally certified manufacturing process 212C, etc.). However, if some of the regulatory requirements are not satisfied, then additional steps may need to be taken by user 204 to certify the prototype of the product. In some implementations, the report that is transmitted to the user can include recommendations for these additional steps (e.g., suggesting one or more design changes, suggesting the replacement of one or more components with a previously designed solution, suggesting one or more adjustments to the inputs of the models, tests, and/or simulations, etc.). If the requirements of a common V&V product are partially met, or are beyond the collective capabilities of distributed engineering tools 202, computing systems 208 may provide user 204 with a report recommending partial certification, compliance, or fulfillment of a subset of the common V&V products (e.g., digital certification of a subsystem or a sub-process of the prototype). The process of generating recommendations for user 204 is described in further detail below.

In response to reviewing the report, user 204 can make design changes to the digital prototype locally and/or can send one or more instructions to computing system 208 via user device 206A or API 206B. These instructions can include, for example, instructions for computing system 208 to re-evaluate an updated prototype design, use one or more different DE tools 202 for the evaluation process, and/or modify the inputs to DE tools 202. Computing system 208 can, in turn, receive the user instructions, perform one or more additional data manipulations in accordance with these instructions, and provide user 204 with an updated report. Through this iterative process, user 204 can utilize the interconnected digital engineering and certification ecosystem to design and ultimately certify (e.g., by providing certification compliance information) the prototype (e.g., the UAV prototype, drug prototype, manufacturing process prototype, etc.) with respect to the common V&V product of interest. Importantly, since all of these steps occur in the digital world (e.g., with digital prototypes, digital models/tests/simulations, and digital certification), significant amount of time, cost, and materials can be saved in comparison to a process that would involve the physical prototyping, evaluation and/or certification of a similar UAV, drug, manufacturing process, etc. If the requirements associated with a common V&V product are partially met, or are beyond the collective capabilities of DE tools 202, computing system 208 may provide user 204 with a report recommending partial certification, compliance or fulfillment of a subset of the common V&V products (e.g., digital certification of a subsystem or a sub-process of the prototype).

While the examples described above focus on the use of the interconnected digital engineering and certification ecosystem by a single user, additional advantages of the ecosystem can be realized through the repeated use of the ecosystem by multiple users. As mentioned above, the central positioning of computing system 208 within the architecture of the ecosystem enables computing system 208 to monitor and store the various data flows through the ecosystem. Thus, as an increasing number of users utilize the ecosystem for digital product development, data associated with each use of the ecosystem can be stored (e.g., in storage 218), traced (e.g., with metadata), and analyzed to yield various insights, which can be used to further automate the digital product development process and to make the digital product development process easier to navigate for non-subject matter experts.

Indeed, in some implementations, user credentials for user 204 can be indicative of the skill level of user 204, and can control the amount of automated assistance the user is provided. For example, non-subject matter experts may only be allowed to utilize the ecosystem to browse pre-made designs and/or solutions, to use DE tools 202 with certain default parameters, and/or to follow a predetermined workflow with automated assistance directing user 204 through the product development process. Meanwhile, more skilled users may still be provided with automated assistance, but may be provided with more opportunities to override default or suggested workflows and settings.

In some implementations, computing system 208 can host applications and services 222 that automate or partially automate components of common V&V products; expected or common data transmissions, including components of data transmissions, from user 204; expected or common interfaces and/or data exchanges, including components of interfaces, between various DE tools 202; expected or common interfaces and/or data exchanges, including components of interfaces, with machine learning (ML) models implemented on computing system 208 (e.g., models trained and/or implemented by the ML engine 220); and expected or common interfaces and/or data exchanges between the applications and services themselves (e.g., within applications and services layer 222).

In some implementations, the data from multiple uses of the ecosystem (or a portion of said data) can be aggregated to develop a training dataset. For example, usage records 217 collected via computing system 208 may be de-identified or anonymized, before being added to the training set. Such usage records may comprise model parameters and metadata, tool configurations, common V&V product matching to specific models or tools, user interactions with the system including inputs and actions, and other user-defined or system-defined configurations or decisions in using the ecosystem for digital engineering and certification. For instance, an exemplary de-identified usage record may comprise the combination of a specific DE tool, a specific target metric, a specific quantity deviation, and a corresponding specific user update to a DE model under this configuration. Another exemplary de-identified usage record may comprise a user-identified subset of DE tools 202 that should be used to satisfy a common V&V product of interest.

This training dataset can then be used to train ML models (e.g., using ML engine 220) to learn the steps and actions for certification processes and to perform a variety of tasks including the identification of which of DE tools 202 to use to satisfy a particular common V&V product; the identification of specific models, tests, and/or simulations (including inputs to them) that should be performed using DE tools 202; the identification of the common V&V products that need to be considered for a product of a particular type; the identification of one or more recommended actions for user 204 to take in response to a failed regulatory requirement; the estimation of model/test/simulation sensitivity to particular inputs; etc. The outputs of the trained ML models can be used to implement various features of the interconnected digital engineering and certification ecosystem including automatically suggesting inputs (e.g., inputs to DE tools 202) based on previously entered inputs, forecasting time and cost requirements for developing a product, predictively estimating the results of sensitivity analyses, and even suggesting design changes, original designs or design alternatives (e.g. via assistive or generative AI) to a user's prototype to overcome one or more requirements (e.g., regulatory and/or certification requirements) associated with a common V&V product. In some implementations, with enough training data, ML engine 220 may generate new designs, models, simulations, tests, common V&V products and/or digital threads on its own based on data collected from multiple uses of the ecosystem. Furthermore, such new designs, models, simulations, tests, common V&V products and digital threads generated by ML engine 220, once approved and adjusted by a user, may be added to the training set for further fine-tuning of ML algorithms in a reinforcement learning setup.

As shall be discussed in the context of FIGS. 7 to 9 and 11 to 33, the aforementioned collection of training datasets and the training of ML and AI modules including ML engine 220 may be enabled by model splicing technologies. Model splicing, as described herein, allows the scripting of DE model operations encompassing disparate DE tools into a corpus of normative program code, and facilitates the code-defined digital threading of a large space of DE activities involving DE models across different disciplines. ML and AI techniques may be used to create scripts to carry out almost any DE task and to execute any digital thread, allowing for programmable, machine-learnable, and dynamic changes to DE model files, digital threads, and ultimately to digital or physical twins, throughout the product life cycle. For example, in the embodiment shown in FIG. 2, ML engine 220 may manage or orchestrate the interactions between spliced DE models, DE tools, and common V&V products (e.g., DE requirements), based on digital thread options specific to user's intent and input. Sample DE tasks that may be carried out by ML engine 220 include, but are not limited to, (1) aligning models/analysis to certification lifecycle requirement steps, (2) optimizing compute by determining the appropriate fidelity of each model, (3) optimizing compute resources for specific tools/models, or (4) optimizing compute resources across multiple models. ML-enabled executions of DE tasks are not limited to certification or resource optimization, but encompass the whole DE space of operations. Rather, ML engine 220 may act as an AI multiplexer for the DE platform.

In addition to storing usage data to enable the development of ML models, previous prototype designs and/or solutions (e.g., previously designed components, systems, models, simulations and/or other engineering representations thereof) can be stored within the ecosystem (e.g., in storage 218) to enable users to search for and build upon the work of others. For example, previously designed components, systems, models, simulations and/or other engineering representations thereof can be searched for by user 204 and/or suggested to user 204 by computing system 208 in order to satisfy one or more requirements associated with a common V&V product. The previously designed components, systems, models, simulations and/or other engineering representations thereof can be utilized by user 204 as is, or can be utilized as a starting point for additional modifications. This store, or repository, of previously designed components, systems, models, simulations and/or other engineering representations thereof (whether or not they were ultimately certified) can be monetized to create a marketplace of digital products, which can be utilized to save time during the digital product development process, inspire users with alternative design ideas, avoid duplicative efforts, and more. In some implementations, data corresponding to previous designs and/or solutions may only be stored if the user who developed the design and/or solution opts to share the data. In some implementations, the repository of previous designs and/or solutions can be containerized for private usage within a single company, team, organizational entity, or technical field for private usage (e.g., to avoid the unwanted disclosure of confidential information). In some implementations, user credentials associated with user 204 can be checked by computing system 208 to determine which designs and/or solutions stored in the repository can be accessed by user 204. In some implementations, usage of the previously designed components, systems, models, simulations and/or other engineering representations thereof may be available only to other users who pay a fee for a usage.

Exemplary IDEP Implementation Architecture with Services and Features

FIG. 3 shows another exemplary implementation of the IDEP illustrating its offered services and features, in accordance with some embodiments of the present invention. Specifically, an exemplary implementation architecture diagram 300 is shown in FIG. 3 to include multiple illustrative components: an IDEP enclave 302, cloud services 304, and a customer environment 310 which optionally includes an IDEP exclave 316. This exemplary architecture 300 for the IDEP is designed in accordance with zero-trust security principles and is further designed to support scalability as well as robust and resilient operations. IDEP enclave 302 and IDEP exclave 316 together instantiate IDEP 100 shown in FIG. 1, with IDEP exclave 316 implementing model splicing and splice plane 170 in some embodiments of the present invention. An enclave is an independent set of cloud resources that are partitioned to be accessed by a single customer (i.e., single-tenant) or market (i.e., multi-tenant) that does not take dependencies on resources in other enclaves. An exclave is a set of cloud resources outside enclaves managed by the IDEP, to perform work for individual customers. Examples of exclaves include virtual machines (VMs) and/or servers that the IDEP maintains to run DE tools for customers who need such services.

In particular, IDEP enclave or DE platform enclave 302 may serve as a starting point for services rendered by the IDEP, and may be visualized as a central command and control hub responsible for the management and orchestration of all platform operations. For example, enclave 302 may be implemented using computer system 208 of the interconnected DE and certification ecosystem shown in FIG. 2. DE platform enclave 302 is designed to integrate both zero-trust security models and hyperscale capabilities, resulting in a secure and scalable processing environment tailored to individual customer needs. Zero-trust security features include, but are not limited to, strict access control, algorithmic impartiality, and data isolation. Enclave 302 also supports an ML engine such as 220 for real-time analytics, auto-scaling features for workload adaptability, and API-based interoperability with third-party services. Security and resource optimization are enhanced through multi-tenancy support, role-based access control, and data encryption both at rest and in transit. DE platform enclave 302 may also include one or more of the features described below.

First, IDEP enclave 302 may be designed in accordance with zero-trust security principles. In particular, DE platform enclave 302 may employ zero-trust principles to ensure that no implicit trust is assumed between any elements, such as digital models, platform agents or individual users (e.g., users 204) or their actions, within the system. That is, no agent may be inherently trusted and the system may always authenticate or authorize for specific jobs. The model is further strengthened through strict access control mechanisms, limiting even the administrative team (e.g., a team of individuals associated with the platform provider) to predetermined, restricted access to enclave resources. To augment this robust security stance, data encryption is applied both at rest and in transit, effectively mitigating risks of unauthorized access and data breaches.

IDEP enclave 302 can also be designed to maintain isolation and independence. A key aspect of the enclave's architecture is its focus on impartiality and isolation. DE enclave 302 disallows cryptographic dependencies from external enclaves and enforces strong isolation policies. The enclave's design also allows for both single-tenant and multi-tenant configurations, further strengthening data and process isolation between customers 306 (e.g., users 204). Additionally, DE enclave 302 is designed with decoupled resource sets, minimizing interdependencies and thereby promoting system efficiency and autonomy.

IDEP enclave 302 can further be designed for scalability and adaptability, aligning well with varying operational requirements. For example, the enclave 302 can incorporate hyperscale-like properties in conjunction with zero-trust principles to enable scalable growth and to handle high-performance workloads effectively.

IDEP enclave 302 can further be designed for workflow adaptability, accommodating varying customer workflows and DE models through strict access control mechanisms. This configurability allows for a modular approach to integrate different functionalities ranging from data ingestion to algorithm execution, without compromising on the zero-trust security posture. Platform 300's adaptability makes it highly versatile for a multitude of use-cases, while ensuring consistent performance and robust security.

IDEP enclave 302 can further be designed to enable analytics for robust platform operations. At the core of the enclave's operational efficiency is a machine learning engine (e.g., machine learning engine 220) capable of performing real-time analytics. This enhances decision-making and operational efficiency across platform 300. Auto-scaling mechanisms can also be included to enable dynamic resource allocation based on workload demand, further adding to the platform's responsiveness and efficiency.

In the exemplary embodiment shown in FIG. 3, IDEP enclave 302 includes several components as described in further detail herein.

A “Monitoring Service Cell. may provide “Monitoring Service” and “Telemetry Service.” A cell may refer to a set of microservices, for example, a set of microservices executing within a kubernetes pod. These components focus on maintaining, tracking and analyzing the performance of platform 300 to ensure good service delivery, including advanced machine learning capabilities for real-time analytics. A “Search Service Cell” provides “Search Service” to aid in the efficient retrieval of information from DE platform 300, adding to its overall functionality. A “Logging Service Cell” and a “Control Plane Service Cell” provide “Logging Service,” “File Service”, and “Job Service” to record and manage operational events and information flow within platform 300, and are instrumental in the functioning of platform 300. A “Static Assets Service Cell,” provides “Statics Service”, and may house user interface, SDKs, command line interface (CLI), and documentation for platform 300. An “API Gateway Service Cell” provides “API Gateway Service,” and may provide DE platform API(s) (e.g., APIs 214, 216) and act as a mediator for requests between the client applications (e.g., DE tools 202, the repository of common V&V products 210, etc.) and the platform services. In some embodiments, the API gateway service cell may receive and respond to requests from agents such as DE platform exclave 316 to provide splice functions for model splicing purposes.

As shown in FIG. 3, the architecture of DE platform 300 may also include a cloud services 304 that provide services which cannot interact with customer data but can modify the software for the orchestration of DE platform operations. In example implementations, several cloud resources provide support and foundational services to the platform. For example, in the embodiment of the DE platform 300 shown in FIG. 3, cloud services 304 includes a “Customer Identity and Access Management (IAM) Service” that ensures secure and controlled access to platform 300. Cloud services 304 also includes a “Test Service” that tests tools to validate platform operations. Cloud services 304 may also include an “Orchestration Service” that controls and manages the lifecycle of containers on the platform 300. Cloud services 304 may also include an “Artifact Service” and “Version Control and Build Services,” which may be used to maintain the evolution of projects, codes, and instances in the system, while also managing artifacts produced during the product development process.

As shown in FIG. 3, the architecture of DE platform 300 may also include a customer environment 310 with an “Authoritative Source of Truth” 312, customer tools 314, and an optional DE platform exclave 316. Customer environment 310 is where customer data resides and is processed in a zero-trust manner by DE platform 300. As described previously, DE platform enclave 302, by focusing on both zero-trust principles and hyperscale-like properties, provides a robust and scalable environment for the secure processing of significant workloads, according to the customer's unique needs. In some examples, DE platform exclave 316 may be situated within customer environment 310 in order to assist the customer(s) 306 with their DE tasks and operations, including model splicing and digital threading.

When a customer 306 (e.g., user 204) intends to perform a DE task using DE platform 300 (e.g., IDEP 100), typical operations may include secure data ingestion and controlled data retrieval. Derivative data generated through the DE operations, such as updated digital model files or revisions to digital model parameters, may be stored only within customer environment 310, and DE platform 300 may provide tools to access the metadata of the derivative data. Here metadata refers to data that can be viewed without opening the original data, and may comprise versioning information, time stamps, access control properties, and the like. Example implementations may include secure data ingestion, which utilizes zero-trust principles to ensure customer data is securely uploaded to customer environment 310 through a pre-validated secure tunnel, such as Secure Socket Layer (SSL) tunnel. This can enable direct and secure file transfer to a designated cloud storage, such as a simple storage service (S3) bucket, within customer environment 310. Example implementations may also include controlled data retrieval, in which temporary, pre-authenticated URLs generated via secure token-based mechanisms are used for controlled data access, thereby minimizing the risk of unauthorized interactions. Example implementations may also include immutable derivative data, with transformed data generated through operations like data extraction being securely stored within customer environment 310 while adhering to zero-trust security protocols. Example implementations may also include tokenization utility, in which a specialized DE platform tool referred to as a “tokenizer” is deployed within customer environment 310 for secure management of derivative metadata, conforming to zero-trust guidelines.

Customer environment 310 may interact with other elements of secure DE platform 300 and includes multiple features that handle data storage and secure interactions with platform 300. For example, one element of the customer environment 310 is “Authoritative Source of Truth” 312, which is a principal repository for customer data, ensuring data integrity and accuracy. Nested within this are “Customer Buckets” where data is securely stored with strict access controls, limiting data access to authorized users or processes through pre-authenticated URL links. This setup ensures uncompromising data security within customer environment 310 while providing smooth interactions with other elements of DE platform 300.

Customer environment 310 may also include additional software tools such as customer tools 314 that can be utilized based on specific customer requirements. For example, a “DE Tool Host” component may handle necessary DE applications for working with customer data. It may include a DE Tools Command-Line Interface (DET CLI), enabling user-friendly command-line operation of DE tools (e.g., DE tools 102). A “DE platform Agent” ensures smooth communication and management between customer environment 310 and elements of DE platform 300. Furthermore, there can be another set of optional DE tools designed to assist customer-specific DE workflows. Native DE tools are typically access-restricted by proprietary licenses and end-user license agreements paid for by the customer. IDEP platform functions call upon native DE tools that are executed within customer environment 310, therefore closely adhering to the zero-trust principle of the system design. Exemplary DE tools include, but are not limited to, proprietary and open-source versions of model-based systems engineering (MBSE) tools, augmented reality (AR) tools, computer aided design (CAD) tools, data analytics tools, modeling and simulation (M&S) tools, product lifecycle management (PLM) tools, multi-attribute trade-space tools, simulation engines, requirements model tools, electronics model tools, test-plan model tools, cost-model tools, schedule model tools, supply-chain model tools, manufacturing model tools, cyber security model tools, or mission effects model tools.

In some cases, an optional “IDEP Exclave” 316 may be employed within customer environment 310 to assist with customer DE tasks and operations, supervise data processing, and rigorously adhering to zero-trust principles while delivering hyperscale-like platform performance. IDEP exclave 316 is maintained by the IDEP to run DE tools for customers who need such services. IDEP exclave 316 may contain a “DE Tool Host” that runs DE tools and a “DE Platform Agent” necessary for the operation. Again, native DE tools are typically access-restricted by proprietary licenses and end-user license agreements paid for by the customer. IDEP exclave 316 utilities and manages proprietary DE tools hosted with customer environment 310, for example, to implement model splicing and digital threading functionalities.

In some embodiments, the machine learning (ML) models and artificial intelligence (AI) assistance approaches as described herein adapt to suit different customer instances of the IDEP (see FIG. 4) and the availability of training data. In an example, a pre-trained ML or AI model (e.g. within the IDEP enclave 302) is deployed in instances where there are restrictions around sharing customer data. In another example, AI models are deployed in a federated manner adjacent to DE agents and DE tools in the customer environment (e.g., within IDEP exclave 316). In another example, an AI model deployed inside the customer environment is trained behind its firewalls. In yet another example, the customer may allow sharing of subsets of their metadata for a training database located within the IDEP enclave.

### IDEP Deployment Scenarios

FIG. 4 shows potential scenarios for instantiating an IDEP in connection to a customer's physical system and IT environment, in accordance with some embodiments of the present invention. Specifically, FIG. 4 illustrates various potential configurations for instancing or instantiating an IDEP (“DE platform) 402 in connection to a customer's IT environment and physical system 404. The IT environment may be located on a virtual private cloud (VPC) protected by a firewall. The physical system may refer to a physical twin as discussed with reference to FIG. 1. In some embodiments, IDEP 402 may be instanced as an enclave such as 302 shown in FIG. 3. For example, IDEP 402 may be instanced on the cloud, possibly in a software-as-a-service (SaaS) configuration. The platform instances in these embodiments include software and algorithms, and may be described as follows:
1. External Platform Instance 410: This option showcases the IDEP as a separate platform instance. The platform interacts with the physical system through the customer's virtual environment, or a Customer Virtual Private Cloud (“Customer VPC”), which is connected to the physical system.
2. External Platform Instance with Internal Agent 420: The IDEP is instantiated as a separate platform, connected to an internal agent (“DE Agent”) wholly instanced within the Customer VPC. For example, the IDEP may be instantiated as enclave 302, and the DE agent may be instantiated as exclave 316 within the Customer VPC linked to the physical system.
3. External Platform Instance with Internal Agent and Edge Computing 430: This scenario displays the IDEP as a separate instantiation, connected to an internal DE Agent wholly instanced within the Customer VPC, which is further linked to an edge instance (“DE Edge Instance”) on the physical system. The DE agent is nested within the customer environment, with a smaller edge computing instance attached to the physical system.
4. Edge Instance Connection 440: This option shows the DE platform linked directly to an DE edge instance on the physical system. The DE platform and the physical system are depicted separately, connected by an edge computing instance in the middle, indicating the flow of data.
5. Direct API Connection 450: This deployment scenario shows the DE platform connecting directly to the physical system via API calls. In this depiction, an arrow extends directly from the platform sphere to the physical system sphere, signifying a direct interaction through API.
6. Air-Gapped Platform Instance 460: This scenario illustrates the IDEP being completely instanced on an air-gapped, or isolated, physical system as a DE agent. The platform operates independently from any networks or Internet connections, providing an additional layer of security by eliminating external access points and potential threats. Interaction with the platform in this context would occur directly on the physical system, with any data exchange outside the physical system being controlled following strict security protocols to maintain the air-gapped environment.

Across these deployment scenarios, the IDEP plays an important role in bridging the gap between a digital twin (DTw) established through the IDEP and its physical counterpart. Regardless of how the IDEP is instantiated, it interacts with the physical system, directly or through the customer's virtual environment. The use of edge computing instances in some scenarios demonstrates the need for localized data processing and the trade-offs between real-time analytics and more precise insights in digital-physical system management. Furthermore, the ability of the platform to connect directly to the physical system through API calls underscores the importance of interoperability in facilitating efficient data exchange between the digital and physical worlds. In all cases, the DE platform operates with robust security measures.

In some embodiments, the IDEP deployment for the same physical system can comprise a combination of the deployment scenarios described above. For example, for the same customer, some physical systems may have direct API connections to the DE platform (scenario 5), while other physical systems may have an edge instance connection (scenario 4).

### Multimodal User Interfaces

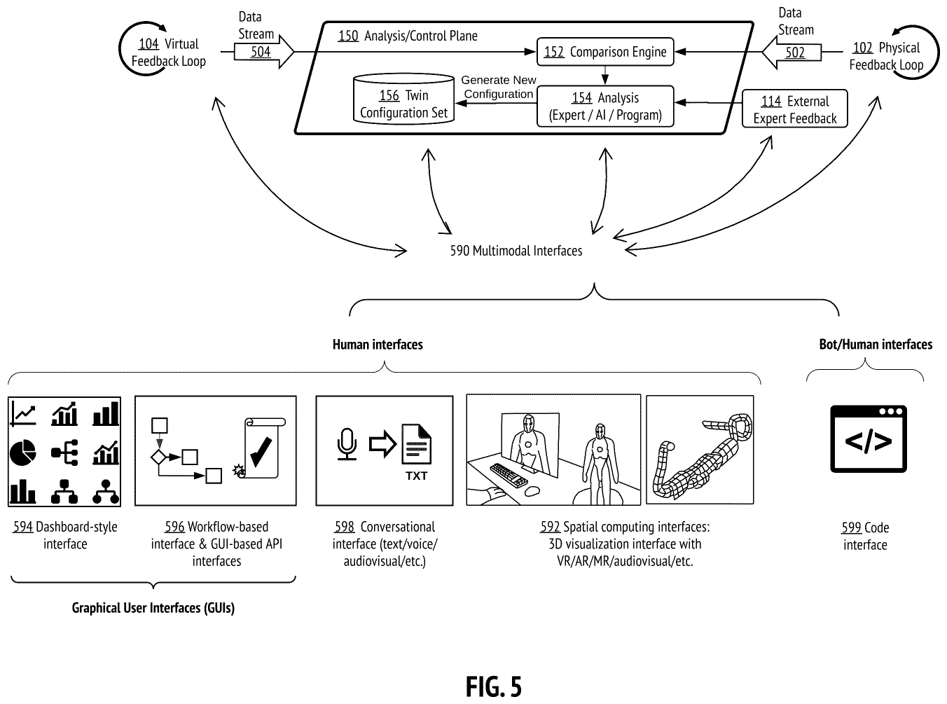

FIG. 5 illustrates the use of multimodal user interfaces 590 for the interconnected DE platform, which can handle various input and output modalities such as Virtual Reality (VR), Mixed Reality (MR), auditory, text, and code. These interfaces are designed to manage the complexity of data streams and decision-making processes, and provide decision support including option visualization, impact prediction, and specific decision invocation. Specifically, data streams 502 and 504 are processed in the Analysis & Control Plane (ACP) 150 of FIG. 1. The user interface may receive data streams from physical and virtual feedback loops 102 and 104, as well as external expert feedback 114, analysis module 154, and twin configuration set 156 of ACP 150.

The multimodal interfaces illustrated in FIG. 5 are configured to carry out all the DE tasks and actions described in the context of FIG. 1, by catering to both humans and bots/algorithms, handling the intricacies of data stream frequency and complexity, decision-making time scales, and latency impacts. In the case of human decision makers, the user interface may need to manage inputs and outputs while for algorithmic decision making, the user interface may need to present rationale and decision analysis to human users. Some examples of human interfaces include a dashboard-style interface 594, a workflow-based interface 596, conversational interfaces 598, spatial computer interfaces 592, and code interfaces 599.

Dashboard-style interface 594 offers a customizable overview of data visualizations, performance metrics, and system status indicators. It enables monitoring of relevant information, sectional review of documents, and decision-making based on dynamic data updates and external feedback. Such an interface may be accessible via web browsers and standalone applications on various devices.

Workflow-based interface 596 guides users through the decision-making process, presenting relevant data, options, and contextual information at each stage. It integrates external feedback and is designed as a progressive web app or a mobile app. In the context of alternative tool selection, workflow-based interface 596 may provide options on individual tools at each stage, or provide combinations of tool selections through various stages to achieve better accuracy or efficiency for the overall workflow.

Conversational interfaces 598 are based on the conversion of various input formats such as text, prompt, voice, audio-visual, etc. into input text, then integrating the resulting input text within the DE platform workflow. Outputs from the DE platform may undergo the reverse process. This enables interoperability with the DE platform, and specifically the manipulation of model splices. In the broad context of audio-visual inputs, the conversational interfaces may comprise data sonification, which involves using sound to represent data, information, or events, and using auditory cues or patterns to communicate important information to users, operators, or reviewers. Sonified alerts (e.g., alerts sent via sound, e.g., via a speaker) are especially useful when individuals need to process information quickly without having to visually focus on a screen. For example, sonified alerts can be used to notify security analysts of potential threats or breaches.

FIG. 5 also illustrates the use of spatial computing interfaces 592 and code interfaces 599 in the management of DTws and PTws. Spatial computing interfaces allow for more immersive and intuitive user experiences, and enable real-time synchronization between DTws and PTws. Code interfaces allow bots and digital engineers to interact with the DE platform through scripting and code. It also allows the collection of user preference, task history, and tool usage patterns for alternative tool selection purposes.

### Digital Threads and Autonomous Data Linkages

As discussed previously, a “digital thread” is intended to connect two or more digital engineering (DE) models for traceability across the systems engineering lifecycle, and collaboration and sharing among individuals performing DE tasks. In a digital thread, appropriate outputs from a preceding digital model may be provided as the inputs to a subsequent digital model, allowing for information and process flow. That is, a digital thread may be viewed as a communication framework or data-driven architecture that connects traditionally siloed elements to enable the flow of information and actions between digital models.

FIG. 6 describes the architecture and inherent complexity of digital threads, in accordance with the examples disclosed herein. Specifically, FIG. 6 is a schematic diagram comparing exemplary digital threads 600 of various complexities that manipulate and/or connect DE models, in accordance with some embodiments of the present invention. In the most basic sense, a digital thread may “thread” together DE models into a simple daisy-chain architecture 602 where modifications in any upstream DE model will affect all DE models downstream from the modified DE model. For example, a modification of any parameter or process of a DE model B will cause changes in DE model C, which in turn will cause changes in DE model D. Cause-and-effect changes will therefore cascade downstream. As another example, diagram 604 represents a more complex digital thread where a change in one DE model may affect more than one downstream model. In both 602 and 604, digital threads are represented by a directed acyclic graph (DAG).

DAGs are frequently used in many kinds of data processing and structuring tasks, such as scheduling tasks, data compression algorithms, and more. In the context of service platforms and network complexities, a DAG might be used to represent the relationships between different components or services within the platform. In digital thread 604, different models may depend on each other in different ways. Model A may affect models B, C, and D, with models B and C affecting model E, and models D and E affecting model G. Such dependencies are denoted as a DAG, where each node is associated with a component (e.g., a model), and each directed edge represents a dependency.

A major issue with dealing with interdependent DE models is that graph consistencies can be polynomial, and potentially exponential, in complexity. Hence, if a node fails (e.g., a model is unreliable), this can have a cascading effect on the rest of the digital thread, disrupting the entire design. Furthermore, adding nodes or dependencies to the graph does not yield a linear increase in complexity because of the interdependencies between models. If a new model is added that affects or depends on several existing models, the resulting increase in graph complexity is multiplicative in nature, hence potentially exponential. The multiplicative nature of digital thread consistencies is compounded by the sheer number of interconnected models, which may number in the hundreds or thousands. Diagram 606 is a partial representation of a real-world digital thread, illustrating the complexity of digital threads and its multiplicative growth.

FIG. 6 further shows special cases 603, 605, 607, 608, and 609 of exemplary simple digital threads. Diagram 607 represents a degenerate digital thread where data is shared from a single DE model. Diagram 608 represents a model-to-document digital thread where data (e.g., system attributes, performance attributes) extracted from a single DE model may be used to generate or update a text-based document (e.g., a Capability Development Document (CDD)). Diagrams 603 and 605 are generalized from 608 to represent cases where data extracted from a single model may be used to update multiple models, or vice versa. Specifically, diagram 605 may represent the dynamic updates of live or magic documents discussed in the context of FIG. 1. Here the logic to connect the DE models shown are very simple: data are extracted from multiple DE models A, B, and C to update a document model D. There are no interactions between the extracted data. Furthermore, diagram 609 shows a special case of a digital thread where data is loaded to and extracted from only a single model A. For example, as discussed in the context of FIG. 7 next, input splice functions of the model A shown in 609 may be executed to update the model, and output splice functions of model A shown in 609 may be executed to produce digital artifacts for sharing. For these special simple threads, the IDEP may provide a GUI-based interface to the user to connect the models and execute the digital threads. For complex threads such as 606, a code-based interface may be necessary.

### Model Splicing for Digital Threading and Digital Twin Generation

As disclosed herein, model splicing encapsulates and compartmentalizes digital engineering (DE) model data and model data manipulation and access functionalities. As such, model splices provide access to selective model data within a DE model file without exposing the entire DE model file, with access control to the encapsulated model data based on user access permissions. Model splicing also provides the DE model with a common, externally-accessible Application Programming Interface (API) for the programmatic execution of DE models. Model splices thus generated may be shared, executed, revised, or further spliced independently of the native DE tool and development platform used to generate the input digital model. The standardization of DE model data and the generalization of API interfaces and functions allow the access of DE model type files outside of their native software environments, and enable the linking of different DE model type files that may not previously be interoperable. Model splicing further enables the scripting and codification of DE operations encompassing disparate DE tools into a corpus of normative program code, facilitating the generation and training of artificial intelligence (AI) and machine learning (ML) models for the purpose of manipulating DE models through various DE tools across different stages of a DE process, DE workflow, or a DE life cycle.

Digital threads are created through user-directed and/or autonomous linking of model splices. A digital thread is intended to connect two or more DE models for traceability across the systems engineering life cycle, and collaboration and sharing among individuals performing DE tasks. In a digital thread, appropriate outputs from a preceding digital model are provided as inputs to a subsequent digital model, allowing for information flow. That is, a digital thread may be viewed as a communication framework or data-driven architecture that connects traditionally siloed elements to enable the flow of information between digital models. The extensibility of model splicing over many different types of DE models and DE tools enables the scaling and generalization of digital threads to represent each and every stage of the DE life cycle.

A digital twin (DTw) is a real-time virtual replica of a physical object or system, with bi-directional information flow between the virtual and physical domains, allowing for monitoring, analysis, and optimization. Model splicing allows for making individual DE model files into executable splices that can be autonomously and securely linked, thus enabling the management of a large number of DE models as a unified digital thread. Such a capability extends to link previously non-interoperable DE models to create digital threads, receive external performance and sensor data streams (e.g., data that is aggregated from DE models or linked from physical sensor data), calibrate digital twins with data streams from physical sensors outside of native DTw environments, and receive expert feedback that provides opportunity to refine simulations and model parameters.

Unlike a DTw, a virtual replica, or simulation, is a mathematical model that imitates real-world behavior to predict outcomes and test strategies. Digital twins use real-time data and have bidirectional communication, while simulations focus on analyzing scenarios and predicting results. In other words, a DTw reflects the state of a physical system in time and space. A simulation is a set of operations done on digital models that reflects the potential future states or outcomes that the digital models can progress to in the future. A simulation model is a DE model within the context of the IDEP as disclosed herein.

When testing different designs, such as variations in wing length or chord dimensions, multiple DTws (sometimes numbering in 100 s to 1,000 s) may be created, as a bridge between design specifications and real-world implementations of a system, allowing for seamless updates and tracking of variations through vast numbers of variables, as detailed in the context of FIG. 1. As an example, if three variations of a system are made, each one would have its own DTw with specific measurements. These DTws may be accessed and updated via API function scripts, which allow for easy input of new measurements from the physical parts during the manufacturing process. By autonomous linking with appropriate data, a DTw may be updated to reflect the actual measurements of the parts, maintaining traceability and ensuring accurate data representation through hundreds or thousands of models.

### Exemplary Model Splicing Setup

FIG. 7 is a schematic showing an exemplary model splicing setup, according to some embodiments of the present invention. Specifically, FIG. 7 is a schematic showing an embedded CAD model splicing example.

In the present disclosure, a “model splice”, “model wrapper”, or “model graft” of a given DE model file comprises locators to or copies of (1) DE model data or digital artifacts extracted or derived from the DE model file, including model metadata, and (2) splice functions (e.g., API function scripts) that can be applied to the DE model data. A model splice may take on the form of a digital file or a group of digital files. A locator refers to links, addresses, pointers, indexes, access keys, Uniform Resource Locators (URL) or similar references to the aforementioned DE digital artifacts and splice functions, which themselves may be stored in access-controlled databases, cloud-based storage buckets, or other types of secure storage environments. The splice functions provide unified and standardized input and output API or SDK endpoints for accessing and manipulating the DE model data. The DE model data are model-type-specific, and a model splice is associated with model-type-specific input and output schemas. One or more different model splices may be generated from the same input DE model file, based on the particular user application under consideration, and depending on data access restrictions. In some contexts, the shorter terms “splice”, “wrapper”, and/or “graft” are used to refer to spliced, wrapped, and/or grafted models.

Model splicing is the process of generating a model splice from a DE model file. Correspondingly, model splicers are program codes or uncompiled scripts that perform model splicing of DE models. A DE model splicer for a given DE model type, when applied to a specific DE model file of the DE model type, retrieves, extracts, and/or derives DE model data associated with the DE model file, generates and/or encapsulates splice functions, and instantiates API or SDK endpoints to the DE model according to input/output schemas. In some embodiments, a model splicer comprises a collection of API function scripts that can be used as templates to generate DE model splices. “Model splicer generation” refers to the process of setting up a model splicer, including establishing an all-encompassing framework or template, from which individual model splices may be deduced.

Thus, a DE model type-specific model splicer extracts or derives model data from a DE model file and/or stores such model data in a model type-specific data structure. A DE model splicer further generates or enumerates splice functions that may call upon native DE tools and API functions for application on DE model data. A DE model splice for a given user application contains or wraps DE model data and splice functions that are specific to the user application, allowing only access to and enabling modifications of limited portions of the original DE model file for collaboration and sharing with stakeholders of the given user application.

Additionally, a document splicer is a particular type of DE model splicer, specific to document models. A “document” is an electronic file that provides information as an official record. Documents include human-readable data that can be read by humans with or without specialized software, such as word processors and/or web services. Thus, a document is a special case of DE models, and may contain natural language-based text and/or graphics that are directly readable by a human without the need of additional machine compilation, rendering, visualization, or interpretation by a dedicated DE tool. A “document splice”, “document model splice” or “document wrapper” for a given user application can be generated by wrapping document data and splice functions (e.g., API function scripts) that are specific to the user application, thus revealing text at the component or part (e.g., title, table of contents, chapter, section, paragraph) level via API or SDK endpoints, and allowing access to and enabling modifications of portions of an original document or document template for collaboration and sharing with stakeholders of the given user application, while minimizing manual referencing and human errors.

In the CAD model splicing example shown in FIG. 7, a CAD model file diesel-engine.prt 704 proceeds through a model splicing process 710 that comprises a data extraction step 720 and a splice function generation step 730. This input DE model 704 is in a file format.prt native to certain DE tools. Data extraction may be performed via a DE model crawling agent implemented as model crawling scripts within a model splicer to crawl through the input DE model file and to distill model data with metadata 722. Metadata are data that can be viewed without opening the entire input DE model file, and may include entries such as file name, file size, file version, last modified date and time, and potential user input options as identified from a user input 706. Model data are extracted and/or derived from the input DE model, and may include but are not limited to, parts (e.g., propeller, engine cylinder, engine cap, engine radiator, etc.), solids, surfaces, polygon representation, and materials, etc. When a model splicer crawls through the model file, it determines how model data may be organized and accessed, as fundamentally defined by a DE tool 702 that is being used in splicing the DE model, and establishes a model data schema. This data schema describes the structure and format of the model data, some of which are translated into, or used to create input/output API endpoints with corresponding input/output schemas. In some embodiments, model data with metadata 722 may be stored in an access-restricted storage 726, such as the “customer buckets” 312 within customer environment 310 in FIG. 3, so that model splices such as 742, 744, and 746 may be generated on-demand once an input DE model 704 has been crawled through.

The model splicer further generates splice functions (e.g., API function scripts) 732 from native APIs 702 associated with the input CAD model. In the present disclosure, “native” and “primal” refer to existing DE model files, functions, and API libraries associated with specific third-party DE tools, including both proprietary and open-source ones. Native API 702 may be provided by a proprietary or open-source DE tool. For example, the model splicer may generate API function scripts that call upon native APIs of native DE tools to perform functions such as: HideParts(parts_list), Generate2DView( ), etc. These model-type-specific splice functions may be stored in a splice function database 736, again for on-demand generation of individual model splices. A catalog or specification of splice functions provided by different model splices supported by the IDEP, and orchestration scripts that link multiple model splices, constitutes a Platform API. This platform API is a common, universal, and externally-accessible platform interface that masks native API 702 of any native DE tool integrated into the IDEP, thus enabling engineers from different disciplines to interact with unfamiliar DE tools, and previously non-interoperable DE tools to interoperate freely.

Next, based on user input or desired user application 706, one or more model splices or wrappers 742, 744, and 746 may be generated, wrapping a subset or all of the model data needed for the user application with splice functions or API function scripts that can be applied to the original input model and/or wrapped model data to perform desired operations and complete user-requested tasks. In various embodiments, a model splice may take on the form of a digital file or a group of digital files, and a model splice may comprise locators to or copies of the aforementioned DE digital artifacts and splice functions, in any combination or permutation. Any number of model splices/wrappers may be generated by combining a selective portion of the model data such as 722 and the API function scripts such as 732. As the API function scripts provide unified and standardized input and output API endpoints for accessing and manipulating the DE model and DE model data, such API handles or endpoints may be used to execute the model splice and establish links with other model splices without directly calling upon native APIs. Such API endpoints may be formatted according to an input/output scheme tailored to the DE model file and/or DE tool being used, and may be accessed by orchestration scripts or platform applications that act on multiple DE models.

In some embodiments, when executed, an API function script inputs into or outputs from a DE model or DE model splice. “Input” splice functions or “input nodes” such as 733 are model modification scripts that allow updates or modifications to an input DE model. For example, a model update may comprise changes made via an input splice function to model parameters or configurations. “Output” splice functions or “output nodes” 734 are data/artifact extraction scripts that allow data extraction or derivation from a DE model via its model splice. An API function script may invoke native API function calls of native DE tools. An artifact is an execution result from an output API function script within a model splice. Multiple artifacts may be generated from a single DE model or DE model splice. Artifacts may be stored in access-restricted cloud storage 726, or other similar access-restricted customer buckets.

One advantage of model splicing is its inherent minimal privileged access control capabilities for zero-trust implementations of the IDEP as disclosed herein. In various deployment scenarios discussed with reference to FIG. 4, and within the context of IDEP implementation architecture discussed with reference to FIG. 3, original DE input model 704 and model data storage 726 may be located within customer buckets 312 in customer environment 310 of FIG. 3. Splice functions 732 stored in database 736 call upon native APIs 702. The execution or invocation of splice functions 732 may rely on job-specific authentication or authorization via proprietary licenses of DE tools (e.g., residing within customer environment 310 of FIG. 3 and/or information security clearance levels of the requesting user. Thus, model splicing unbundles monolithic access to digital model-type files as whole files and instead provides specific access to a subset of functions that allow limited, purposeful, and auditable interactions with subsets of the model-type files built from component parts or atomic units that assemble to parts.

### Digital Threading of DE Models Via Model Splicing

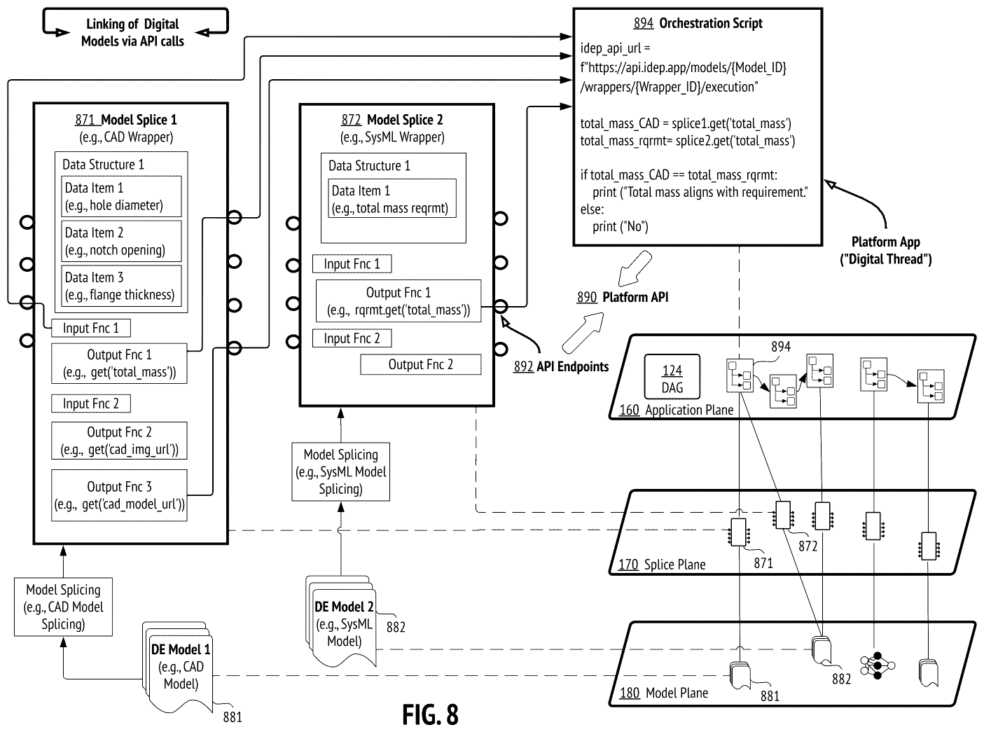

FIG. 8 is a schematic showing digital threading of DE models via model splicing, according to some embodiments of the present invention. A digital thread is intended to connect two or more DE models for traceability across the systems engineering lifecycle, and collaboration and sharing among individuals performing DE tasks.

Linking of model splices generally refers to jointly accessing two or more DE model splices via API endpoints or splice functions. For example, data may be retrieved from one splice to update another splice (e.g., an input splice function of a first model splice calls upon an output splice function of a second model splice); data may be retrieved from both splices to generate a new output (e.g., output splice functions from both model splices are called upon); data from a third splice may be used to update both a first splice and a second splice (e.g., input splice functions from both model splices are called upon). In the present disclosure, “model linking” and “model splice linking” may be used interchangeably, as linked model splices map to correspondingly linked DE models. Similarly, linking of DE tools generally refers to jointly accessing two or more DE tools via model splices, where model splice functions that encapsulate disparate DE tool functions may interoperate and call each other, or be called upon jointly by an orchestration script to perform a DE task.

Thus, model splicing allows for making individual digital model files into model splices that can be autonomously and securely linked, enabling the management of a large number of digital models as a unified digital thread written in scripts. Within the IDEP as disclosed herein, a digital thread is a platform script that calls upon the platform API to facilitate, manage, or orchestrate a workflow through linked model splices. Model splice linking provides a communication framework or data-driven architecture that connects traditionally siloed elements to enable the flow of information between digital models via corresponding model splices. The extensibility of model splicing over many different types of digital models enables the scaling and generalization of digital threads to represent each and every stage of the DE lifecycle and to instantiate and update DTws as needed.

In the particular example shown in FIG. 8, an orchestration script 894 is written in Python code and designed to interact via API endpoints such as 892 to determine if a CAD model meets a total mass requirement. API endpoint 892 is an output splice function and part of a platform API 890. Platform API 890 comprises not only splice functions but also platform scripts or orchestration scripts such as 894 itself. Orchestration script 894 is divided into three main steps:
1. Get Data From a CAD Model Splice: A POST request may be sent via the IDEP platform API to execute a computer-aided design (CAD) model splice 871. This model splice provides a uniform interface to modify and retrieve information about a CAD model 881. The parameters for the CAD model, such as hole diameter, notch opening, flange thickness, etc., may be sent in the request and set via an input splice function. The total mass of the CAD model may be derived from model parameters and retrieved via an output splice function. The response from the platform API includes the total mass of CAD model 881, and a Uniform Resource Identifier/Locator (URL) for the CAD model. The response may further comprise a URL for an image of the CAD model.
2. Get Data From a SysML Model Splice: Another POST request may be sent via the IDEP platform API to execute a Systems Modeling Language (SysML) model splice 872. SysML is a general-purpose modeling language used for systems engineering. Output function 892 of model splice 872 retrieves the total mass requirements for the system from a SysML model 882. The response from the platform API includes the total mass requirement for the system.
3. Align the Variables and Check If Requirement Met: The total mass from CAD model 881 is compared with the total mass requirement from SysML model 882. If the two values are equal, a message is printed indicating that the CAD model aligns with the requirement. Otherwise, a message is printed indicating that the CAD model does not align with the requirement.

In short, orchestration script 894, which may be implemented in application plane 160 of IDEP 100 shown in FIG. 1, links digital models 881 and 882 via model splice API calls. Orchestration script 894 is a scripted platform application that modifies a CAD model, retrieves the total mass of the modified CAD model, retrieves the total mass requirement from a SysML model, and compares the two values to check if the CAD model meets the requirement. In some embodiments, a platform application within IDEP 100 utilizes sets of functions to act upon more than one DE model.

### Model Splice Plane

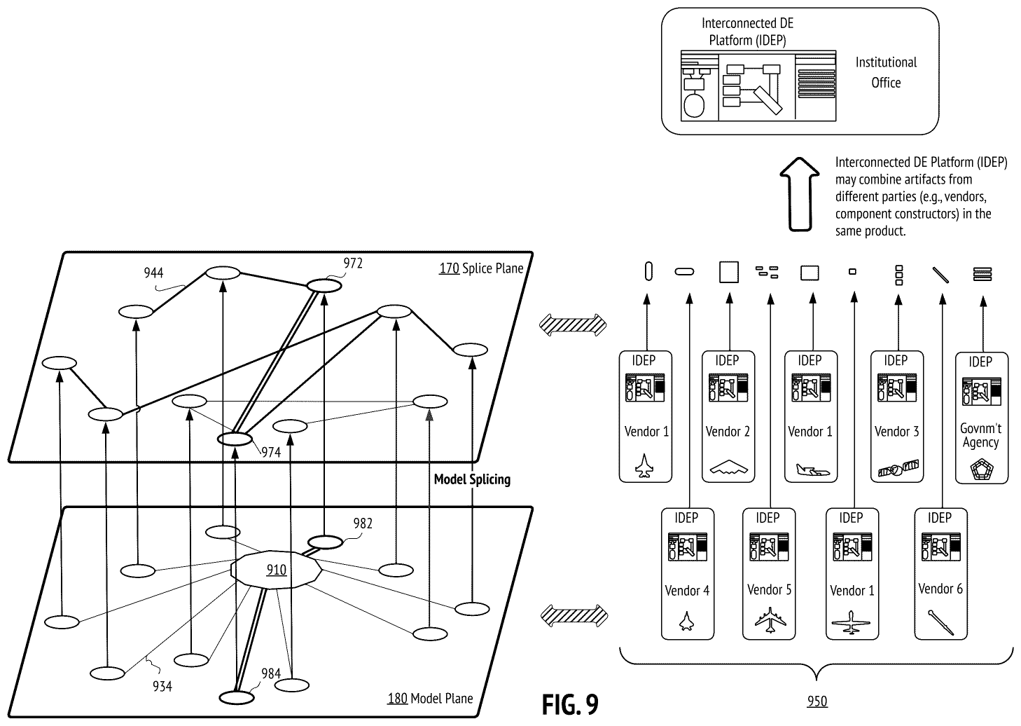

FIG. 9 is a schematic illustrating the linking of DE model splices in a splice plane and comparing digital threading with and without model splicing, according to some embodiments of the present invention. The bottom model plane 180 demonstrates current digital threading practices, where each small oval represents a DE model, and the linking between any two DE models, such as models 982 and 984, requires respective connections to a central platform 910, and potential additional linkages from every model to every other model. The central platform 910 comprises program code that is able to interpret and manipulate original DE models of distinct model types. For example, platform 910 under the control of a subject matter expert may prepare data from digital model 982 into formats that can be accessed by digital model 984 via digital model 984's native APIs, thus allowing modifications of digital model 982 to be propagated to digital model 984. Any feedback from digital model 984 to digital model 982 would require similar processing via platform 910 so that data from digital model 984 are converted into formats that can be accessed by digital model 982 via digital model 982's native APIs. This hub-and-spoke architecture 934 is not scalable to the sheer number (e.g., hundreds or thousands) of digital models involved within typical large-scale DE projects, as model updates and feedback are only possible through central platform 910.

In contrast, once the DE models are spliced, each original model is represented by a model splice comprising relevant model data, unified and standardized API endpoints for input/output, as shown in the upper splice plane 170. Splices within splice plane 170 may be connected through scripts (e.g., python scripts) that call upon API endpoints or API function scripts and may follow a DAG architecture, as described with reference to FIG. 1 and FIG. 6. Note that in FIG. 1, only the set of generated splices are shown within splice plane 170, while in FIG. 9, scripts that link model splices are also shown for illustrative purposes within the splice plane. Such scripts are referred to as orchestration scripts or platform scripts in this disclosure, as they orchestrate workflow through a digital thread built upon interconnected DE model splices. Further note that while splice plane 170 is shown in FIG. 1 as part of IDEP 100 for illustrative purposes, in some embodiments, splice plane 170 may be implemented behind a customer firewall and be part of an agent of the DE platform, as discussed in various deployment scenarios shown in FIG. 4. That is, individual API function scripts generated via model splicing by a DE platform agent may be tailored to call upon proprietary tools the customer has access to in its private environment. No centralized platform 910 with proprietary access to all native tools associated with all individual digital models shown in FIG. 9 is needed. Instead, orchestration scripts call upon universal API function scripts that may be implemented differently in different customer environments.

Hence, model splicing allows model splices such as model splice 972 from digital model 982 and model splice 974 from digital model 984 to access each other's data purposefully and directly, thus enabling the creation of a model-based “digital mesh” 944 via platform scripts and allowing autonomous linking without input from subject matter experts.

An added advantage of moving from the model plane 180 to the splice plane 170 is that the DE platform enables the creation of multiple splices per native model (e.g., see FIG. 7), each with different subsets of model data and API endpoints tailored to the splice's targeted use. For example, model splices may be used to generate multiple digital twins (DTws) that map a physical product or object design into the virtual space. Two-way data exchanges between a physical object and its digital object twin enable the testing, optimization, verification, and validation of the physical object in the virtual world, by choosing optimal digital model configuration and/or architecture combinations from parallel digital twins built upon model splices, each reacting potentially differently to the same feedback from the physical object.

Supported by model splicing, digital threading, and digital twining capabilities, the IDEP as disclosed herein connects DE models and DE tools to enable simple and secure collaboration on digital engineering data across engineering disciplines, tool vendors, networks, and model sources such as government agencies and institutions, special program offices, contractors, small businesses, Federally Funded Research and Development Centers (FFRDC), University Affiliated Research Centers (UARC), and the like. An application example 950 for the IDEP is shown on the right side of FIG. 9, illustrating how data from many different organizations may be integrated to enable cross-domain collaboration while maintaining data security, traceability, and auditability. Here DE models from multiple vendors or component constructors are spliced or wrapped by IDEP agents, and data artifacts are extracted with data protection. Turning DE models into data artifacts enables cross-domain data transfer and allows for the protection of critical information, so that model owners retain complete control over their DE models using their existing security and IT stack, continue to use DE tools that best fit their purposes, and also preserve the same modeling schema/ontology/profile that best fit their purposes. The IDEP turns DE models into micro-services to provide minimally privileged data bits that traverse to relevant stakeholders without the DE models ever leaving their home servers or being duplicated or surrogate. The IDEP also provides simple data access and digital threading options via secure web applications or secure APIs.

### DAG Representation of Threaded Tasks

Model splicing provides a unified interface among DE models, allowing model and system updates to be represented by interconnected and pipelined DE tasks. FIG. 10 shows an exemplary directed acyclic graph (DAG) representation 1000 of pipelined DE tasks related to digital threads, in accordance with some embodiments of the present invention. In diagram 1000, tasks performed through a digital thread orchestration script (e.g., 894) are structured as nodes within a DAG. Actions are therefore interconnected and carried out in a pipeline linking the DE model splices with a range of corresponding parameter values. Therefore, a digital thread can be created by establishing, via interpretable DE platform scripts, the right connections between any model splices for their corresponding models at the relevant endpoints.

Referring to FIGS. 1 and 8, DAGs of threaded tasks are built from digital threads and are part of the DE platform's application plane 160. Different DAGs may target different DE actions. For example, in FIG. 1, building or updating a DTw 122 in the virtual environment 120 has its own DAG 124. Model splicing turns DE models into data structures that can be accessed via API, thus enabling the use of software development tools, from simple python scripts to complex DAGs, in order to execute DE actions. A digital thread of model splices eliminates the scalability issue of digital thread management, and speeds up the digital design process, including design updates based on external feedback.

Following the above description of the basic elements and core aspects of the IDEP as disclosed herein, the AI-assisted model splicer generation system that enhances the IDEP's functionality with respect to model splicing is described in detail next.

### Overview of Artificial Intelligence (AI)-Assisted Model Splicer Generation

Broadly, the present invention relates to methods and systems for AI-assisted model splicer generation and update for any given DE tool, DE model type, or combinations thereof. More specifically, embodiments of the present invention are directed to training machine learning (ML) and/or artificial intelligence (AI) models on resource-capability mappings of an interconnected digital model platform (IDMP), identifying data schemas for digital tools and/or models newly incorporated into the IDMP, and generating function scripts that interface with digital tool Application Programming Interfaces (APIs) or with the IDMP platform API. Such function scripts may be created when a new digital tool or digital model is introduced to the IDMP ecosystem, or when an existing digital tool is updated with a new version within the IDMP.

Exemplary embodiments of the present invention are described in detail below in the context of digital engineering (DE). Such examples are non-limiting in scope, as an Interconnect Digital Engineering Platform (IDEP) is a type of IDMP. Any reference to an IDEP in the specification and drawings can be considered equivalent to a reference to an IDMP, and vice versa. Similarly, any reference to a DE model can be considered equivalent to a reference to a digital model; any reference to a DE tool can be considered equivalent to a reference to a digital tool.

Methods and systems thus described herein are further directed to AI-assisted cross-tool scripting of DE model operations encompassing disparate DE tools, Normative program code interfaces to both DE models and DE tools may be universally customized and automated within the unified IDMP for the creation and manipulation of complex systems comprising digital models, digital threads, and digital twins.

The current landscape of DE is characterized by a diverse and extensive array of model types and tools, for example with more than 50 vendors offering computer-aided design (CAD) tools that support over 20 different CAD file formats. The disclosed embodiments of the present disclosure harness the power of AI to enable the seamless integration of these varied models and tools into an IDMP. By leveraging continuous learning and adaptation to common IDMP schemas and universal resource-capability mappings, this AI-assisted DE tool and DE model integration process requires limited input from subject matter experts (SMEs), thereby enhancing the IDMP's capabilities and performance, while minimizing disruptions and accelerating workflows, potentially resulting in substantial cost and time savings throughout the lifecycle of digitally-engineered products.

The disclosed machine learning (ML) and AI engines or modules may be trained and fine-tuned using existing resource-capability mappings, datasets of user inputs and feedback, and exemplary schemas, function scripts, workflows, and tasks. Any fine-tuning process may be further tailored using enterprise-specific documents and data to capture the nuances of specific language and data dependencies within client databases. To maintain the integrity and security of the data, the fine-tuning and deployment of these AI-assisted processes may be performed within secure customer environments, adhering to zero-trust principles.

A DE model type-specific model splicer, when splicing an input DE model, stores model data extracted from a DE model file in a model type-specific data structure. A model splicer further generates splice functions or API function scripts that can be applied to the model data. A “model splice” or “wrapper” for a given user application can be generated by wrapping model data and splice functions that are specific to the user application, thus allowing only access to and enabling modifications of limited portions of the original engineering model file for collaboration and sharing with stakeholders of the given user application. The terms “model splice,” “model wrapper,” “splice node,” “splicer node,” and “wrapper node” are used interchangeably herein to represent a model splicing result. On the other hand, the term “model splicer” refers to a software module or datastore that can be used to generate model splices or model wrappers. “Model splicer generation” refers to the process of setting up a model splicer, or establishing an all-encompassing framework, template, or collection of input/output schemas and scripts, from which individual model splices can be deduced. That is, model splicer generation creates input and output schemas for model splices, as well as a library or pipeline of scripts that can be selectively integrated into any particular model splice. A model splicer update process similarly updates splice function scripts based on changes or updates to the underlying DE tool or DE model type involved.

The creation of model type-specific and tool-specific model splicers requires thorough knowledge of the user application and user demand, deep subject matter expertise in the particularities of the model data and associated API libraries, as well as advanced software engineering capabilities to develop splice function scripts or orchestration scripts. The AI-assisted approach to model splicer generation utilizes one or more ML and AI models and algorithms to assist in creating model splicers for new DE tools and/or new DE model types, based on tool APIs as well as IDMP resource-capability mappings that encompass existing model splicers and splicer functions created by subject matter experts (SME) and software engineers (SWE).

One feature of AI-assisted model splicer generation is the generalization of individual modular model splicers into a software engine that is universal, scalable, and adaptable to ever evolving advancements in DE. ISTARI's AI-supported IDMP is capable of standardizing data schemas and modular model interfaces across various DE tools to enable seamless integration of new tools, thus maximizing efficiency and adaptability, minimizing manual errors, and avoiding inconsistencies. This transformation simplifies the management of digital models, digital threads, and digital twins, overcoming the limitations of SMEs and SWEs in creating individual model splicers for the multitude of DE model types and DE tools in existence.

In various embodiments of the present invention, AI-assistance may be provided by one or more individual software modules to perform one or more of the following functions. “AI-assistance” broadly refers to the use of any ML and/or AI algorithms, models, techniques, modules, and engines to assist in the analysis of DE model data, linking of DE models, and completion of DE tasks. The following list is non-exhaustive and non-limiting in nature.
Generating input and output schemas for a given DE model type, DE tool, use case, workflow, task, or any combinations thereof
Generating textual or visual illustrations for a model splicer mockup
Reviewing End User License Agreements or other business and legal documents to identify customer constraints.
Reviewing DE model type and/or tool-specific documentations such as API libraries, API documentations, or API descriptions
Generating splice functions, API scripts, or function wrappers
Generating cross-tool orchestration or coordination scripts for use in digital threading and digital twinning
Enabling user-prompted customization and execution of the above functions. For example, generating user-defined splice functions, API function wrappers, API scripts, or orchestration scripts
Generating digital threads (e.g., in the DAG architecture) that link DE model splices, using associated API and orchestration scripts created by the above functions
Suggesting DE models for linking with an existing DE model, into a digital thread

Both non-generative AI models (also known as discriminative or analytical AI) and generative AI models are within the scope of the present invention. Some illustrative examples are classifiers, recommenders, generative adversarial networks (GANs), and transformer-based Large Language Models (LLMs) such as Generative Pre-Trained (GPT) language models. In this disclosure, LLMs are considered as an illustrative example of generative AI models for implementing AI-assisted model splicer generation, but are not intended to be limiting. Similarly, while there has been a recent explosion in LLM implementations and applications including BERT, ChatGPT (GPT-4), Claude, LaMDA, and LlaMA, with either proprietary or public licenses, discussion of any specific non-generative or generative AI models in the present disclosure is for illustrative purposes only and is not intended to limit the scope of the invention.

### AI Assistance Example: AI-Assisted MBSE Model Splicing

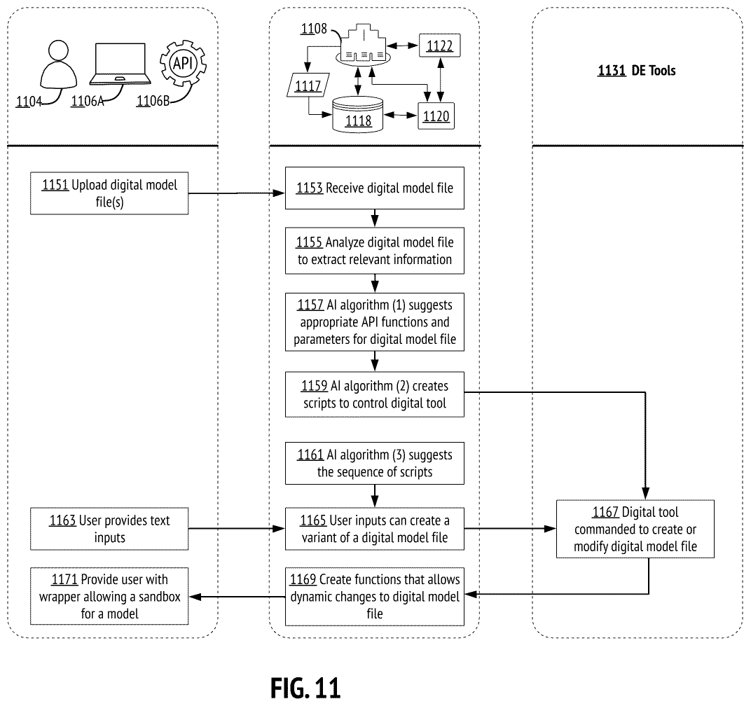

Before discussing AI-assisted model splicer generation, FIG. 11 shows an exemplary use case of AI assistance in model splicing an input Model-Based Systems Engineering (MBSE) model file and scalable sharing of the model, in accordance with some embodiments of the present invention. Recall that model splicing is the processing of an input model file by a model splicer, and model splicer generation refers to the process of setting up a model splicer, or establishing an all-encompassing framework or template, in the form of a collection of generated scripts from which individual model splices can be deduced. In other words, model splicing, or the generation of individual model splice functions may be considered as a special case of model splicer generation. Different users with different application use cases may create or customize, with or without AI-assistance, input/output schemas and individual splice functions for a DE model type and/or DE tool, and these input/output schemas and splice functions may be collected by the IDMP as part of a model-specific or tool specific model splicer, for splicing future input DE models.

In FIG. 11, A user uploads a file (e.g., MBSE) to the IDMP, which then analyzes the file to extract relevant information. One or more AI algorithms are deployed to analyze the input data file to extract relevant information, to suggest appropriate API functions and parameters for the file, to create splice function scripts to control DE tools, and to suggest sequences of scripts. User inputs may be incorporated to create a variant of the input file. The DE tool may be commanded to create or modify DE files, which enables the system to create functions that allow dynamic changes to the files. Finally, the system may provide the user with a wrapper, allowing a sandbox for a model.

As described earlier with reference to FIG. 2, an interconnected DE and certification ecosystemor an IDEP may include a user device1106A, API1106B, or other similar human-to-machine, or machine-to-machine communication interfaces operated by a user 1104. The ecosystem may further comprise a computing and control system1108 (“computing system1108” hereinafter) connected to and/or including a data storage unit1118, a machine learning (ML) and artificial intelligence (AI) engine 1120 (“AI engine” hereinafter), and an application and service layer1122. In some implementations, the data from multiple uses of the ecosystem (or a portion of said data) can be aggregated to develop a training dataset. For example, usage records 1117 collected via computing system 1118 may be de-identified or anonymized, before being added to the training set. In some embodiments, a typical workflow may take in as input various DE tools 1131 and information from a repository of common V&V products (not shown).

In a first sequence of steps, user 1104 uploads, at a step 1151, an MBSE file onto the IDEP, which receives, at a step 1153, the MBSE file. The ML engine on the digital engineering platform then analyzes, at a step 1155, the MBSE file to extract relevant information. AI engine 1120 that implements one or more ML or AI algorithms then suggests, at a step 1157, appropriate API functions of a DE tool applicable on the MBSE file and parameters for the MBSE file. Next, AI engine 1120 creates, at a step 1159, scripts to control the DE tool. Then, the system commands, at a step 1167, the appropriate DE tool to create or modify the MBSE file.

In an alternative sequence, AI engine 1120 suggests, at a step 1161, the sequence of the scripts, and the user 1104 provides text inputs at a step 1163. The user inputs can help create, at a step 1165, a variant of the MBSE file. The sequence then proceeds to step 1167 as described earlier.

After step 1167, AI engine 1120 creates, at a step 1169, functions that allow dynamic changes to the MBSE file. Finally, the system outputs, at a step 1171, a model splice or a wrapper allowing a sandbox for a model.

The AI-assistance algorithms (1), (2), and (3) shown in FIG. 11 may be created in AI engine 1120 by utilizing a combination of supervised and unsupervised learning techniques. Once an AI model is trained, it can then be applied to the MBSE file to suggest appropriate functions and parameters, create scripts to control the DE tool, or suggest the sequence of scripts for optimal results. Additionally, AI engine 1120 may also be trained on new data, improving its performance over time.

An implementation example for the AI-assistance algorithms is through the use of fine-tuned language models. In this scenario, AI engine 1120 may be trained on a dataset of user inputs and example scripts based on MBSE files. The fine-tuned language model is then able to understand the specific language and context of the MBSE files, making it better suited to suggest appropriate functions and parameters, create scripts to control the DE tool, and suggest the sequence of scripts for optimal results. Additionally, as new data is added, AI engine 1120 may continually improve its performance over time. This approach allows for greater customization and flexibility, as the AI engine can be tailored to the specific needs and requirements of the user.

In some embodiments, external feedback (e.g., from a subject matter expert) can occur in locations of the process. For example, when an AI algorithm suggests API functions and/or parameters, an external expert user can provide feedback to accept the suggestions or to suggest revisions. In another example, when another AI algorithm suggests scripts to run one or more DE tools for the input MBSE file, an external expert user can accept the scripts or suggest revisions if needed. In a third example, when another AI algorithm suggests the linking of scripts in sequence, the external expert user can provide feedback to accept the proposed sequence or suggest revisions in sequence. Such expert user actions, system actions, and user inputs may all be logged for training AI systems capable of API script and splice function generation, AI-assisted generation of model splicers, and/or autonomous model splice linking.

### An Exemplary Model Splicer Implementation

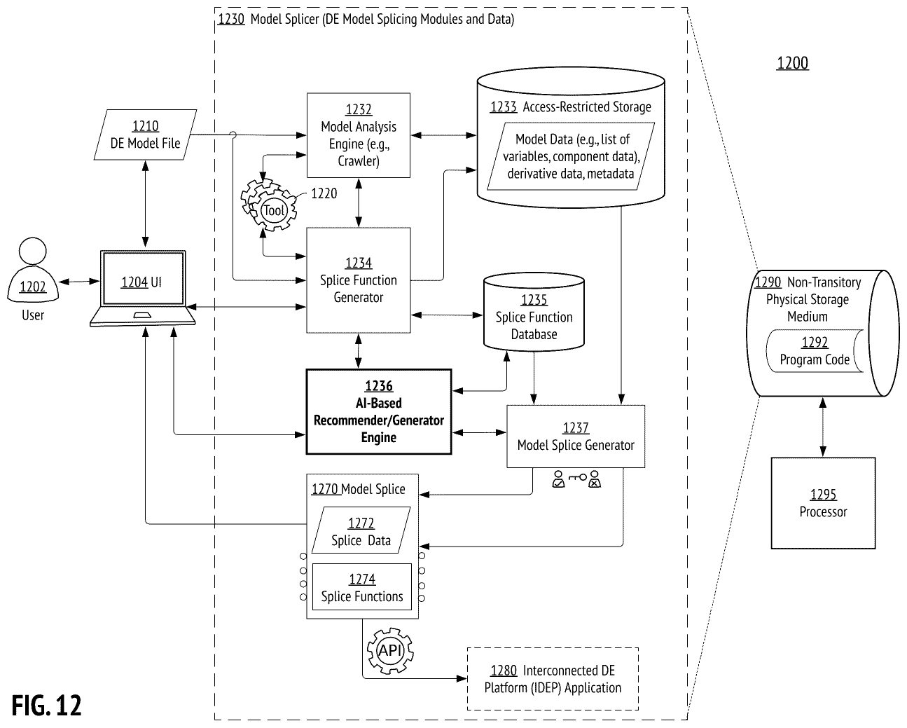

FIG. 12 shows an exemplary architecture diagram 1200 for implementing a DE model splicer, in accordance with some embodiments of the present invention. In this illustrative example, a non-transitory physical storage medium 1290 is provided to store program code 1292, the program code executable by a hardware processor 1295 to cause the hardware processor to execute computer-implemented processes, including model splicing or generating a sharable model splice 1270 from an input DE model file 1210 of a DE model.

In some embodiments, program code 1292 comprises code to receive DE model file 1210 of the DE model having a DE model type, in a source file format (e.g., in a native DE file format). In some embodiments, DE model file 1210 may be received from a user 1202 through a user interface (UI) 1204. User 1202 may be a human or a computing entity, and UI 1204 may be a graphical UI (GUI), a code interface such as an API/SDK interface, or a multimodal interface as discussed with reference to FIG. 5. For example, user 1202 may represent an artificial intelligence (AI) module that intends to link a generated model splice 1270 to another existing model splice to perform a DE task as part of a digital thread. In some embodiments, user 1202 may provide additional inputs for model splicing. Exemplary user input include, but are not limited to, requests for specific digital artifacts, splice function selections, intents for model splice usage, access restriction requirements on the generated model splice, authentication and/or authorization credentials, specific DE tools to be used for crawling through the input DE model file and/or for generating the model splice functions, request for proprietary or open-source DE tools, proprietary licenses or access codes for using proprietary DE tools during model splicing, and the like. In some embodiments, DE model file 1210 may be received directly from a data source, for example, retrieved from an internal database or a cloud-based storage service. In some embodiments, DE model file 1210 may comprise physical artifacts collected from physical twins and organized in a pre-defined source file format.

A model analysis engine 1232 analyzes input DE model file 1210 to extract model data that are in turn stored in a data storage area 1233, which may be access-restricted, cloud-based, or may be located in customer buckets within customer environments for a zero-trust implementation. In some embodiments, model analysis engine 1232 may comprise a crawler script that calls upon native functions of native DE tools 1220 associated with input file 1210 to parse the input DE model in detail to determine the model type, extract component data, identify metadata associated with the model file and/or component data, and generate a list of variables. In some embodiments, model analysis engine 1232 may generate derivative data from the extracted model data, with or without the assistance of a splice function generator 1234 and/or AI-assistance. When a derivative datum is generated and stored in storage1233, associated metadata may be stored as well, for example to identify a time of the derivation, code used for the derivation, user authorizing the derivation, and/or a version of the input model file at the time of the derivation. Such metadata may be crucial in applications that require near-instantaneous auditability and clear traceability to original sources of truth.

Splice function generator 1234 generates one or more external, commonly-accessible splice functions that enable external access to one or more digital artifacts derived from the model data stored in the model data storage area. In the present disclosure, digital artifacts are functional outputs. Any model data, derivative data, metadata, or combinations and functions thereof may be viewed as a digital artifact, accessed or generated via model splice output functions. Both model analysis engine 1232 and splice function generator 1234 may call upon native functions of native DE tools 1220 associated with the input DE model's model type or as requested by the user. For example, splice function generator 1234 may generate API function scripts that call upon native DE tool functions to derive the digital artifacts, or to provide functionalities based on user input. The user may specify which DE tool to use or is preferred. In some embodiments, splice function generator 1234 may interact with user 1202 through UI 1204 to receive user-defined splice functions, to receive user selection from a list of existing splice functions previously defined by other users or previously generated and stored in splice function database 1235, and/to receive user approval or revision to proposed splice functions. In some embodiment, the user may match between the model data and existing splice functions in splice function database 1235 to identify a selected number of splice functions that may be included in model splice 1270.

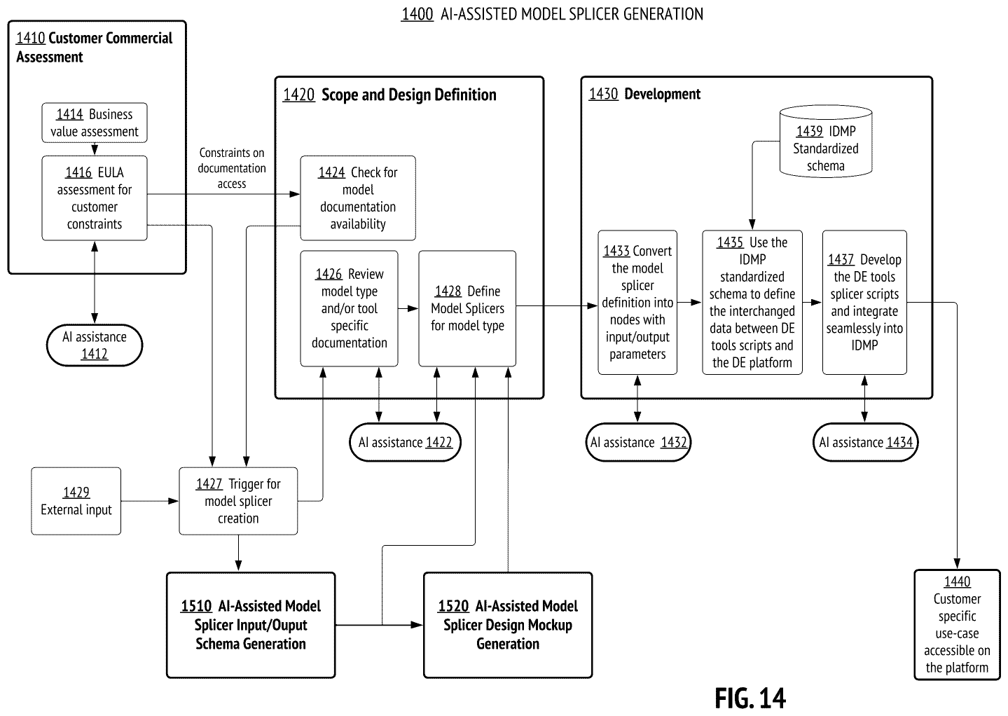

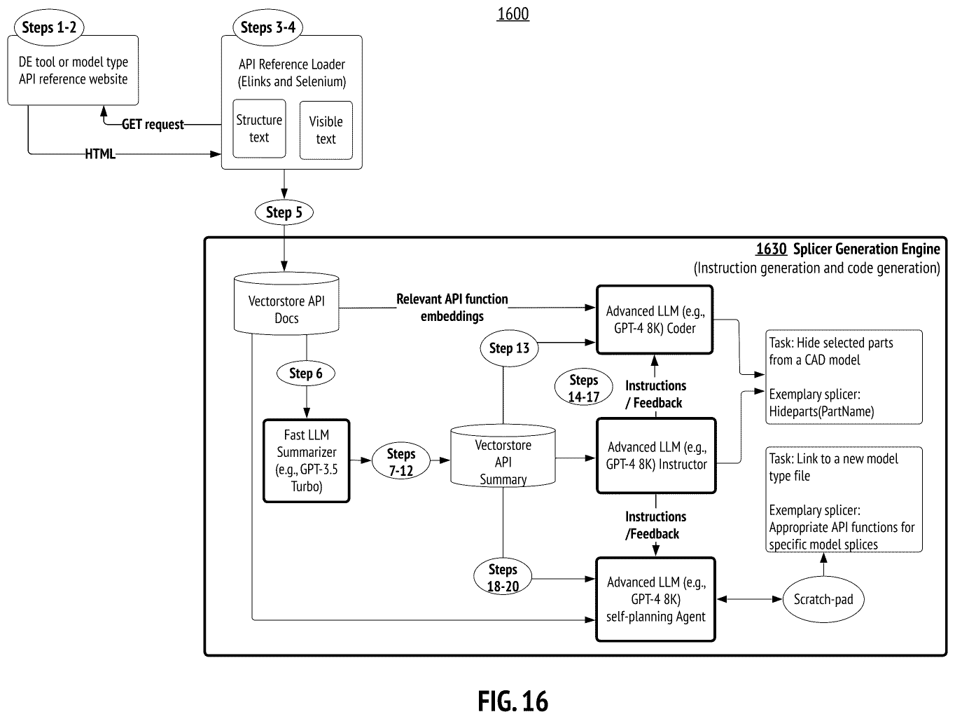

In some embodiments of a model splicer, an AI-based recommender/generator engine 1236 may assist splice function generation. For example, AI engine 1236 may have been trained on existing splice functions associated with existing model splices for the same DE model types, DE tools, analogous DE model types, analogous DE tools, analogous DE models, and/or analogous DE tools, and may have been further fine-tuned based on user inputs and actions. In some embodiments, AI engine 1236 may comprise multiple AI algorithms to analyze DE tool APIs, determine analogous DE model types or tools, and generate splice functions. In various embodiments, AI engine 1236 may comprise non-generative or generative AI algorithms. Such an AI engine may be implemented equivalently as model splicer development module 1430 discussed in the context of FIG. 14, or splicer generation engine 1630 discussed in the context of FIG. 16.

In some embodiments, AI engine 1236 may utilize a large language model (LLM) to write function scripts that call upon APIs of native DE tools 1220. In some embodiments AI engine 1236 may utilize a large language model (LLM) installed as an agent within the customer environment, accessing customer-specific knowledge base. In some embodiments, AI engine 1236 may retrieve a list of splice functions from splice function database 1235, based on user input and other data inferred from the input DE model, such as file format, DE model type, intended purposes/use/audience, etc. In some embodiments, AI engine 1236 may autonomously match model type with existing splice functions to recommend a list of potential splice functions for the user to select from. In the present disclosure, analogous DE models or DE model types refer to DE models that are similar in some aspects, such as structure or behavior, but are not identical. Analogous DE models may be identified by analyzing the characteristics of different DE models and determining shared common features, attributes, or components that are relevant for model splicing. Analogous DE models may be used as reference, baseline, or starting point for model splicing, leveraging the similarities to improve efficiency and to capitalize on validated splice functions. Analogous models are particularly useful when they follow the same standard guidelines or reuse the same components or modules. For example, different variants of an aircraft may share a common propeller design but have different avionics. Splice functions generated for one variant of the aircraft may be used as training data for AI engine 1236, for generating splice functions of other variants of the aircraft. Similarly, analogous DE tools refer to DE tools that are similar in some aspects. For example, open-source and proprietary CAD tools are considered analogous as they both can be used to operate on CAD mode files, although their functionalities and schemas are not necessarily identical.

The splice functions thus generated provide addressable API or SDK endpoints that are accessible by third-party applications and users. Such API or SDK endpoints enable access to the digital artifacts without access to the entirety of the DE model file and without requiring direct engagement by the third-party applications and users with native DE tools 1220 associated with the DE model type or the native DE file format. That is, splice functions mask native DE tool functions and DE tools. A user of a generated model splice is no longer required to have deep knowledge of the associated native DE tool. Furthermore, different users may access the same API or SDK endpoints that deploy different underlying native DE tools during model splicing. For example, a first user having a first input CAD model file and access to a proprietary CAD tool, and a second user having a second input CAD model file and access to an open-source CAD tool, can both obtain CAD model splice having the same splice functions that are implemented with the proprietary CAD tool and the open-source CAD tool respectively.

A model splicer generator 1237 bundles splice data 1272 and splice functions 1274 into shareable model splice 1270, in the form of locators (e.g., links, addresses, pointers, indexes, URLs, etc.) and/or copies of data/code. Splice data 1272 may be a selective portion of the digital artifacts obtained from input DE model file 1210. This selective portion may be selected based on data access permissions, such as a user input on the access level or security clearance level of another user that the generated model splice will be shared with, or on a need-to-know basis, such as metadata indicating the DE task which the model splice has been generated for. Splice functions 1274 may be selected from those stored in splice function database 1235. Sharable model splice 1270 is accessible via the API or SDK endpoints by third-party applications and users. These API or SDK endpoints provide a unified programming interface to all sharable model splices generated from various DE models having the same DE model type (e.g. CAD models of a same native file format, or CAD models of several native or neutral file formats). These endpoints may be utilized by applications 1280 within the IDEP to perform specific DE tasks, optimally under endpoint-specific, zero-trust access control. Thus, model splicing may be perceived as an use case-specific or application-specific process, as the data and functions of the model splice may be chosen or determined based on the intended use of the model splice.

In various embodiments, generated model splice 1270 may be shared with another user, who may in turn execute it to access and/or modify the digital artifacts and/or the input DE model. As discussed in the context of FIG. 7, in some embodiments, splice functions may be classified into input functions or model modification functions, and output functions or data/artifact extraction functions. Inputs into a model splice for execution may be input parameters for such input splice function and output splice functions. Outputs of model splice execution are digital artifacts and/or modified DE models that can be shared, viewed, further modified, linked into digital threads, and used for complete DE tasks.

While model analysis engine 1232, splice function generator 1234, model splice generator 1237 and AI engine 1236 are shown as separate modules within FIG. 12, in various embodiments of the present invention, these modules may be integrated in any combination to facilitate seamless data exchange and functional collaboration to optimize the overall performance of the DE model splicing process. In some embodiments, parts of model splicer 1230 may be implemented within a customer environment behind a customer firewall and be managed by an IDEP agent, so that customer data within storage 1233 is fully protected under a zero trust setting. Splice function database 1235, which could be independent from specific model data, may be provided by the IDEP and accessed via the IDEP agent.

The discussion of the model splicing process and the model splicer in the context of FIGS. 11 and 12 so far has focused on model splicing a single, given DE model type with functions from an associated DE tool. In some embodiments, model splicer 1230 may first identify a model type of the input model file (e.g., using model analysis engine 1231), identify one or more DE tools applicable to the input model file, then splice accordingly. For frequently used DE model types, splice functions for one or more DE tools may be written and tested by SMEs manually, and stored in splice function database 1235 for use to generate use case-specific model splices. As there is an extensively large number of DE model types and DE tools currently employed in various interdisciplinary and multidisciplinary engineering fields, it would be advantageous to scale model splicer 1230 from a few widely used DE model types and DE tools to a large number of model types and tools. Furthermore, as model splicing is use case-specific, two different input DE model files of the same DE model type and intended for the same purpose may lead to similar model splices having different model data but identical splice functions.

In some exemplary implementations of the model splicing process, one or more of the following steps may be performed by the system shown in FIG. 12. First, model analysis engine 1232 may perform preprocessing steps before an input DE model file is received or uploaded. Specifically, model analysis engine 1232 may interpret file structure and schema for a library of model-type files, and build a library of typical use cases for model splices based on customer interviews and user inputs. Machine learning (ML) or AI-based algorithms may assist in scaling the model splicer, where exemplary splice functions and file structure details may be used to create archetype for potential splice functions for specific DE model-type files and DE tools. Here the term “model-type” file refers to a DE model file of a specific DE model type.

In some embodiments, when a model-type file is received or uploaded, the model splicer may translate user instructions for typical use cases into specific functions that link appropriately with the model-type file. The model splicer may provide a selection of splices for common uses (e.g., query the model or perform specific actions on model data). The user may provide specific queries or desired actions to the system, for example to select from a list of model splices, or optionally input text prompt to an AI-assistance module to obtain a selection of model splices. Furthermore, in some implementations, endpoint calls to a model splice and its outputs may be tracked or audited as part of security implementation. Endpoint metadata tracking or auditing may also serve as training data set for user workflows that can be implemented in an automated or AI-assisted manner.

In other words, for a given DE model file, a model splicer generates model type-specific data files or structures and accompanying splice functions or native API function wrappers, which is a “second set of API functions” in addition to native APIs of the DE model. The model type-specific data files or database entries store all or a subset of model data extracted from the original DE model, while the splice functions allow access to and modification of the model type-specific data structures and/or extracted model data, metadata, and derived digital artifacts, allowing easy collaboration and sharing via an optional, dedicated, secure web-app portal. In an exemplary use case for model splices, a generated DE model splice or wrapper is analogous to an interactive portable document format (PDF) document with macro-functions embedded for annotation and collaboration. For example, an airplane manufacturer may share a redacted 3D view of an airplane's new wing design with an Air Force officer without giving the officer too much information or needing to share the original model file, which may be overly-complicated or unnecessary for the intended audience. Such a redacted 3D view may be generated using splice functions applied to data spliced from the original wing design model file.

In some embodiments, a model splice makes available a subset of the model through a subset of API endpoints or a GUI/web-app. The API endpoints may be accessed directly via code, while the GUI/web-app may offer not only handles to the API endpoints, but also interfaces for user interaction with model splices. In some instances, one of the API endpoints may still point to the location of the whole model. In some instances, a model splice may be used to share a sub-model built from extracted model data. In other instances, where the splice only provides a limited set of API endpoints, the pointer to the whole model may be needed for context. For example, a model splice that is generated from a CAD model with hidden sub-assemblies may internally connect with the whole extracted model in order to know the assembly structure.

The aforementioned splice functions allow users to share, modify, and redact the model with limited exposure to the complete model which could contain proprietary technical information. This means the model owner may retain control over who has access to which parts of the model, while still allowing others to work with the model collaboratively. Furthermore, the splice may webify the model and abstract its native API, exposing only those aspects of the model the owner intends to share. Model splicing enables secure and collaborative engineering workflows without the need to duplicate models or expose sensitive technical information. It enables efficient sharing, abstraction, and redaction of the model's functions without requiring full transparency to the entire model. AI-based recommender/generator engine 1236 enables the generalization of the model splicing process across the multitude of DE model types and DE tools in existence.

### AI-Assisted, Scalable Generation and Update of Model Splicers

As discussed in the context of AI-based recommender/generator engine 1236 in FIG. 12, an AI-assisted approach can streamline model splicer generation for newly added DE tools and/or DE model types, especially when subject matter experts (SMEs) and/or software engineers (SWEs) experienced in the newly added DE model types or DE tools are not available or cannot dedicate sufficient time to manually program a new model splicer. As disclosed herein, generative AI algorithms that perform transductive learning may be applied to assist in creating model splicers for new DE model types and DE tools, based on existing model splicers created by SMEs and SWEs. Additionally, when a new version of an existing DE tool is made available by a supplier, AI-assisted model splicer updates may be carried out to ensure compatibility with the latest available tool. Individual model splicers may therefore be tied to specific versions of a tool, with model splicer metadata indicating such versioning information.

AI-assisted model splicer generation uses machine learning (ML) and artificial intelligence (AI), especially Large Language Model (LLM)-based modules, in identifying input and output schemas for splicing a given digital model type, suggesting functions and parameters, and creating a library or pipeline of splicer function scripts and/or orchestration scripts. Such scripts can be selectively integrated into any particular model splice, to either interface with the Application Programming Interfaces (APIs) of different DE tools, interface with a platform API of the IDMP, or orchestrate the linking of DE model splices to complete specific DE tasks.

### Exemplary Process Flow

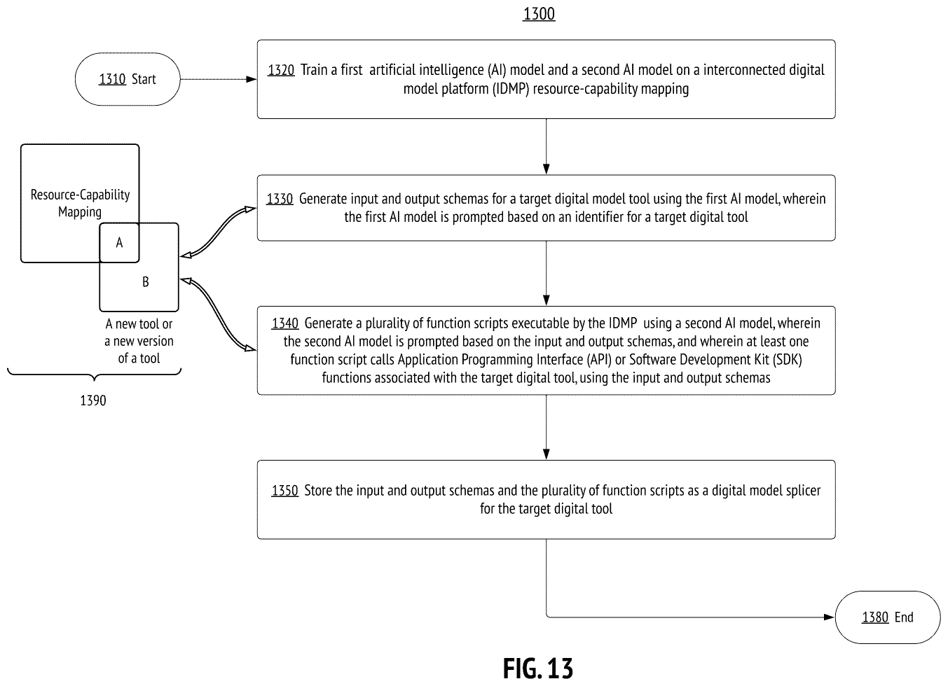

Specifically, FIG. 13 is an exemplary flowchart 1300 showing a process for AI-assisted model splicer generation, in accordance with some embodiments of the present invention. In this exemplary embodiment, a digital model splicer comprising input and output schemas and scripts executable by an IDMP is generated through one or more of the following steps.

Upon initiation at a step 1310, training of AI models is performed at a step 1320. Specifically, a first AI model and a second AI model are trained on the IDMP's resource-capability mapping. In the present disclosure, a resource-capability mapping refers to a framework for identifying, linking, or aligning resources available within the IDMP with capabilities they enable or support. Resources within the IDMP may refer to processors, computational power, storage, services, tools and functions, software modules, user access levels, and the like. The capabilities enabled by these resources may encompass data processing functions, analytics, user management, communication, and integration with other systems or services. One exemplary resource-capability mapping is the IDMP platform API, where the resource refers to third-party tools and functions integrated into and accessible via the IDMP, and where the capability refers to IDMP functions written in scripts for completing certain tasks or achieving user intents using the available resources. Resource-capability mapping also assists with zero-knowledge implementations where the capability details are available to a user while the specific digital tool resource or its functions are only mapped within a customer environment.

As discussed with reference to FIGS. 7 and 8, the IDMP platform API may be universal across at least two different tools for a common digital model type or a common digital model type category. The universality of the IDMP platform API may be explained with a simple CAD tool example. For a given CAD file format, or a given category of CAD files (e.g., component part files, 2D renderings, unstructured geometric data files), more than one CAD tool may be applicable (e.g., proprietary tools from different vendors, or open-source tools), and the IDMP platform API masks the underlying tools so that different users having access to the different CAD tools may call upon the same IDMP platform API when manipulating model splices, digital threads, and digital twins via the IDMP.

IDMP resource-capability mappings may be used to identify how tool-specific resources such as tool functions, access and control capabilities, human-machine interfaces, processes, and objects can be allocated, invoked, and utilized efficiently and effectively to achieve specific IDMP platform functions or tasks. In the present disclosure, the terms “resource-capability mapping” and “resource-capability mapping documentation” are used interchangeably. That is, such mappings may be written in code, in natural-language based texts or comments, in diagrams, or in combinations thereof.

Following is an example of IDMP resource-capability mapping written in code. Specifically, an IDMP capability in the form of a function “update_cells” may be written using different tool resources including EXCEL ver. 12.3.0, EXCEL ver. 13.3.0, and Open Excel. Another IDMP capability function “get_count” is implemented only in EXCEL ver. 12.3.0. In this particular function-tool example, tool-specific endpoints may be different (e.g., different “entrypoint” pointers), but tool-specific input/output schemas are the same. In other examples, both tool-specific endpoints and tool-specific input/output schemas may be different. In the case where the IDMP “update_cells” function has only been implemented for EXCEL ver. 12.3.0, but EXCEL ver. 13.3.0 is newly introduced and requested by a user, the system may suggest the input/output schemas of the old version for integrating the new version into the IDMP, optionally upon verifying that there are no schema changes from the old to the new version of the tool.

```
{
  “functions”: [
    {
      “name”: “update_cells”,
      “version”: “1.0.0”,
      “description”: “oihoih;”,
      “authors”: [“Malik Ghanim”],
      “function_tool_map”: [
        {
          “name”: “Excel”,
          “versions”: [“12.3.0”],
          “entrypoint”: “/somepath/tool-binary-[12.3.0]/update_cells.py”,
          “input_schema”: “/somepath/update_cells.json”,
          “output_schema”: “/somepath/update_cells.json”
        },
        {
          “name”: “Excel”,
          “versions”: [“13.3.0”],
          “entrypoint”: “/somepath/tool-binary-[13.3.0]/update_cells.py”,
          “input_schema”: “/somepath/update_cells.json”,
          “output_schema”: “/somepath/update_cells.json”
        },
        {
          “name”: “Open Excel”,
          “versions”: [“1.0.0”],
          “entrypoint”: “/somepath/update_cells.py”,
          “input_schema”: “/somepath/update_cells.json”,
          “output_schema”: “/somepath/update_cells.json”
        },
      ],
    },
    {
      “name”: “get_count”,
      “tools”: [
        {
          “name”: “Excel”,
          “versions”: [“12.3.0”]
        }
      ]
    }
  ]
}
```

In some embodiments, the first AI model and the second AI model are different AI algorithms. Training of the two AI models may be performed separately or jointly. In some embodiments, the first and second AI models may be one AI algorithm provided by the same AI engine such as ML and AI engine 220 in FIG. 2. Both non-generative AI models (also known as discriminative or analytical AI) and generative AI models are within the scope of the present invention. Non-generative AI refers to AI systems that do not primarily focus on creating new content or data but instead are designed to analyze, interpret, classify, predict, recommend, or make decisions based on existing information. Some examples of non-generative AI include classifiers, recommenders, decision trees, and the like. Some illustrative examples of generative AI models are generative adversarial networks (GANs), transformer-based Large Language Models (LLMs) such as Generative Pre-Trained (GPT) language models, less accurate but less resource intensive Small Language Models (SLMs), and the like. In this disclosure, LLMs are considered as an illustrative example of AI models for implementing AI-assisted model splicer generation, but are not intended to be limiting in scope. Similarly, while there has been a recent explosion in LLM implementations and applications including BERT, ChatGPT (GPT-4), Claude, LaMDA, and LlaMA, with either proprietary or public licenses, discussion of any specific AI models in this present disclosure is for illustrative purposes only and is not intended to limit the scope of the invention.

In some embodiments, the AI models referenced in step 1320 may be pre-trained, and the referenced training may refer to fine-tuning on customer-specific resource-capability mappings or a subset of the IDMP resource-capability mapping. Such resource-capability mappings may further comprise user inputs, example model splicers, function scripts, use cases, workflows, tasks, and other similar data or configuration applicable to model splicer generation. Fine-tuning may be further conducted on specific language and context of tool-specific API libraries. Additionally, new training data may be added in the form of user or SME feedback, such that the AI models continually improve their performance over time. This interactive approach allows for greater customization and flexibility, as the AI models can be tailored to the specific needs and requirements of the user.

Next, at a step 1330, input and output schemas are generated for a target digital model tool using the first AI model, where the first AI model is prompted based on an identifier for a target digital tool. At a subsequent step 1340, a plurality of function scripts executable by the IDMP are generated using a second AI model, where the second AI model is prompted based on the input and output schemas, and where at least one function script calls API or SDK functions associated with the target digital tool, using the input and output schemas. In some embodiments, an optional step may be performed between 1330 and 1340, to align the input and output schemas to a standardized IDMP data schema, so that at least one variable within the input and output schemas is of a standard IDMP variable type. The input and output schemas and the plurality of function scripts may be stored as a digital model splicer for the target digital tool at a step 1350, and the overall process terminates at a step 1380.

One exemplary use case that illustrates the context of AI model deployments is when a user inputs a preferred tool as the target digital tool for model splicer generation. If the preferred tool is new to the IDMP, the first AI model previously trained on an IDMP resource-capability mapping may generate an input and output schema for the new tool, utilizing knowledge of IDMP resources and capabilities, while the second AI model previously trained on the IDMP resource-capability mapping generates plurality of splice functions having the input and output schemas and calling upon tool functions. In some embodiments, the AI models or modules may be capable of analyzing documentations or libraries of the new tool to determine its capabilities or functionalities, including digital model type(s) the tool operates on, function calls, what the tool is typically used for, and/or what workflows and tasks the identified digital model type(s) are typically involved in. Such information may subsequently be used in the schema generation and the function script generation processes.

Specifically, during schema generation or function script generation, the IDMP may take into account resource-capability mappings or APIs of the new tool, especially if the new tool is open-sourced and has publicly available documentations such as API libraries. On the other hand, if the new tool is proprietary, steps 1330 and/or 1340 may be performed by an AI agent located within a secure customer environment, adhering to zero-trust implementation principles. Here an AI agent refers to a software entity or module that acts on behalf of a user or another program to perform specific tasks or operations related to an AI model. An AI agent may be designed and trained by the IDMP but deployed and fine-tuned by a customer within a secured customer environment to interface in between the IDMP, AI models, and/or proprietary tools the customer is licensed for. Similarly, a tool agent may reside within a customer environment or IDMP exclave for utilizing proprietary tools under zero-trust security.

In another example, if the preferred tool is new to the IDMP but a digital model type associated with the preferred tool has previously been incorporated into the IDMP with model type-specific model splicers implemented with another tool, the first AI model may provide input-output schemas associated with the existing model splicers as the output at step 1330, while the second AI model may generate the plurality of function scripts to implement the same model type-specific model splices with the preferred tool. A specific case for this scenario is the IDMP having model splicers built for an open-sourced tool, and the AI models suggesting, recommending, or generating the same input and output schemas as well as the same splice functions for a corresponding proprietary tool using proprietary tool functions.

In yet another example, the preferred tool may have previously been integrated into the IDMP, with existing input and output schemas on the IDMP, and existing splice functions and orchestration scripts that call upon the tool's API or SDK functions. A new version of the tool may be made available by a vendor, and the function scripts associated with the tool may be updated through the process shown in FIG. 13, thus generating a new model splicer that is tied to the newer version of the tool. For example, the first AI model may output the existing input and output schemas at step 1330, while the second AI model may output updated function scripts that call upon the newer version of the tool at step 1340. At 1350, the newer version number of the tool may be stored as metadata of the digital model splicer to indicate which version of the tool is utilized by the model splicer. When necessary, the first AI model may also update the input and output schemas at step 1330. For example, a newly released version of a CAD tool may update input variables for a given function. In a version 1.0 of the tool, a function to add a 3D model may be:

def add_model(file_path):
# logic to add model

By comparison, in a version 2.0 of the same tool, the function may have been expanded to include more parameters for better control, thus changing the schema:

def add_model(file_path, scale=1.0, position=(0, 0, 0)):
# logic to add model with scaling and positioning

In some embodiments, a human or a machine user may provide additional inputs to each of steps 1330 and 1340, to be used in prompting the first and/or the second AI model. For example, the user may include a preferred task, and the second AI model may generate splice functions for completing the task with the preferred tool, similar to AI-based recommender/generator engine 1236. In another example, the user may provide an intent instead of a well-defined task, and the second AI model may be a recommender engine to recommend one or more function scripts to accomplish the user intent. In a third example, the first AI model may be prompted further based on input and output schema examples of a second digital tool that serves as a template. This template digital tool may be analogous to the preferred digital tool, and may be associated with a template digital model type as well. Such preferred tool and corresponding template tool may be used to manipulate analogous digital model types or digital model types within the same category. For example, the preferred and template tools may operate with .stl or .dwg files respectively. In yet some embodiments, the AI models may be prompted further based on a target digital model type associated with the target digital tool, so that the generated input and output schemas and/or the function scripts are specific to the target digital model type. Furthermore, a category of the target digital model type may have previously been integrated into the IDMP and described in the resource-capability mapping, such that the generated input and output schemas overlap with existing input and output schemas for an existing digital tool within the target digital model type category.

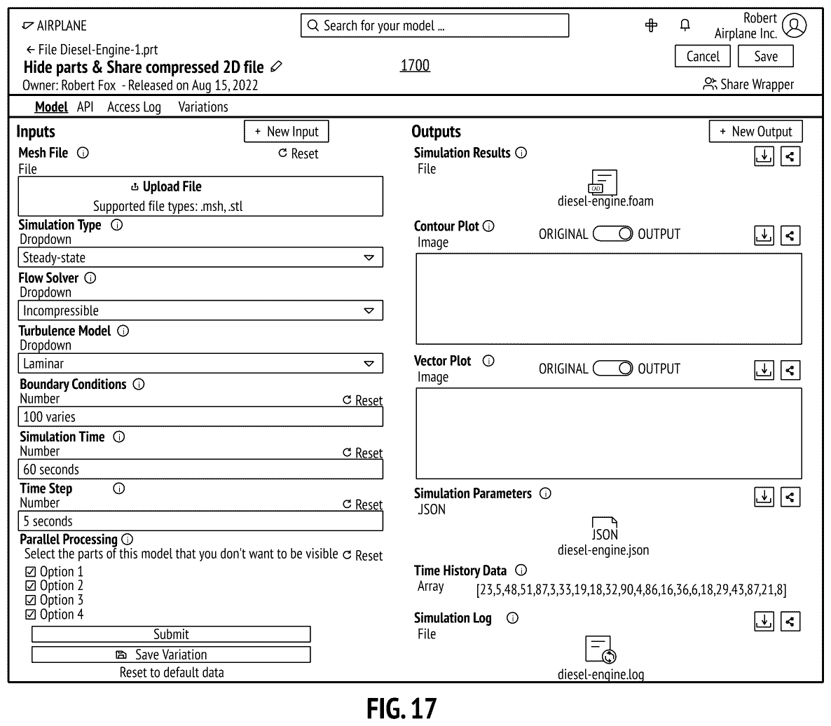

A Venn diagram 1390 connected to steps 1330 and 1340 provides one exemplary conceptual illustration of AI-assisted model splicer generation. Trained on the IDMP resource-capability mapping, the AI models as disclosed herein may be prompted to identify, recommend, or generate function scripts “A” for a new tool or a new version of a tool, matching the tool's capabilities to what's already available on the IDMP. Optionally, function scripts “B” may be generated, further based on additional information such as tool APIs and desired tasks. For example, using an LLM-based splicer generation engine 1630 shown in FIG. 16, tool API information may be extracted from API documentations of the target digital tool, and the second AI model may be prompted further based on the extracted tool API information for function script generation. In some embodiments, the first and/or the second AI models may be fine-tuned on API documentations of the target digital tool. Moreover, based on model splicer design mockups as detailed in reference to FIGS. 17 to 21, the second AI model may be further prompted based on a portion of a design mockup. In other words, given a visual representation of a desired model splicer, the system as disclosed herein may generate function scripts for extracting inputs shown in the mockup, or for deriving output digital artifacts shown in the mockup. In some embodiments, a design mockup may be generated through one or more of the following process steps: receiving a digital task involving the digital model type; uploading the input and output schemas into a design mockup tool; generating a base design mockup of the digital model splicer, with a standardized data schema; for each variable in the standardized schema, search for example text or image in a database to update the base design mockup; generating the design mockup by adding the example texts or images to the base design mockup, based on the input and output schema and the digital task; receiving user feedback on the design mockup, and finalizing the design mockup based on the user feedback.

In short, AI-assisted model splicer generation for a given DE tool creates input and output schemas for model splices of one or more DE model types or a DE tool, as well as a library or pipeline of DE tool API function scripts and cross-tool orchestration scripts that can be selectively integrated into any particular model splice. The generated model splicer can then be applied to a specific digital model file, to create a model splice by instantiating API endpoints according to the input and output schemas, and encapsulating a set of selected scripts that allow access and modification of extracted model data.

### Exemplary Implementation

FIG. 14 is a schematic 1400 showing an exemplary implementation of AI-assisted model splicer generation or update, in accordance with some embodiments of the present invention. In this illustrative embodiment, AI-assisted model splicer generation or update comprises three main stages: customer commercial assessment 1410, scope and design definition 1420, and model splicer development 1430. Note that the second AI model as referenced in the context of FIG. 13 may encompass any of the AI assistance modules 1412, 1422, 1432, and 1442 shown in FIG. 14.

During customer commercial assessment stage 1410, a digital tool may be evaluated at a step 1414 for its business value upon a potential customers' request for integration into the IDMP. In some cases, the customer's End User License Agreements (EULA) for the target DE tool may be assessed at a step 1416 using an AI-assistance sub-module 1412 to determine any potential constraints or prohibitions on user authorization and DE tool access, with assessment reports recorded for auditability. For example, AI-assistance sub-module 1412 may be a transformer-based LLM model setup for document summarization or query, and fine-tuned on legal vocabulary. In some embodiments, the EULA assessment 1416 is replaced by a legal and security review. The use of AI-assistance is especially valuable when a tool has already been integrated into the IDMP and updates (e.g., new software release) are pushed onto the IDMP.

During model splicer scope and design definition stage 1420, model or tool documentation availability may first be checked at a step 1424, and a model splicer generation process may be triggered at a step 1427 if documentations are available, to initiate an AI-assisted model splicer input/output schema generation process by a module 1510. Exemplary documentations may include, but are not limited to, product documents for the DE tool, API libraries, and IDMP resource-capability mappings.

In some embodiments, an additional condition for triggering the model splicer generation process is an external input 1429. This external input may be from a human user, or may be received from another part of the IDMP. For example, a request for a model splicer may be received from the IDMP when the model splicer is needed for building a digital thread, or is suggested for completing some specific DE tasks. In other examples, the external input may be to build a model splicer for a new DE tool, or to update the model splicer for a DE tool which may have been updated to a newer version.

In one illustrative example, external input 1429 may be a prompt “I want to do a CFD analysis” from a human user, representing a user intent to perform a specific task. A DE model type may be handled by multiple DE tools. For example, ANSYS, ABAQUS, and NASTRAN are DE tools for CFD (computational fluid dynamics) models. Customer commercial assessment may have already been conducted for one or more of such DE tools beforehand, for example for purposes other than model splicer generation, and the IDMP may converse with the user to determine if a model splicer is to be created for the one or more assessed DE tools.

In addition to AI-assisted module 1510, when all the conditions are met for model splicer generation, another AI-assistance sub-module 1422 may be triggered to review model type and/or tool-specific documentations at a step 1426. For example, AI-assistance sub-module 1422 may crawl through marketing materials for a DE tool to understand the DE tool's capabilities or what functions it can perform.

Furthermore, AI-assistance sub-module 1422 may optionally be used to assist in defining model splicers at a step 1428 for a given model type associated with the DE tool, based on input/output schemas provided by module 1510, and optionally based on any model splicer design mockup generated by a module 1520. A definition for a model splicer defines or describes capabilities of the model splicer. An exemplary definition for a model splicer is the API script specification 732 shown in FIG. 7.

During model splicer development stage 1430, the model splicer definition from stage 1420 may be converted at a step 1433 via AI-assistance sub-module 1432 into nodes with input/output parameters in the appropriate schemas. In some embodiments, this step may be combined with the previous model splicer definition step 1428, as together they provide a specification for the model splicer.

Next, a IDMP standardized schema 1439 may be used to define data that can be interchanged between DE tool scripts and the IDMP at a step 1435. An exemplary input to this process are input/output parameters and nodes that will be the API endpoints; an exemplary output of this process are input/output parameters with additional metadata aligned to the IDMP's standard schema. This may be viewed as schema alignment to IDMP standards, again simplifying the myriad formats from many different DE model types into a set of consistent data types available on the IDMP to easily edit, understand, and link models of various types.

An AI-assistance sub-module 1434 is then used to generate, at a step 1437, DE tool-specific splicer scripts that can be integrated seamlessly into the IDMP, can be selected to construct a model splice or to orchestrate interactions among multiple model splices, and to support customer specific use-cases 1440 accessible on the IDMP.

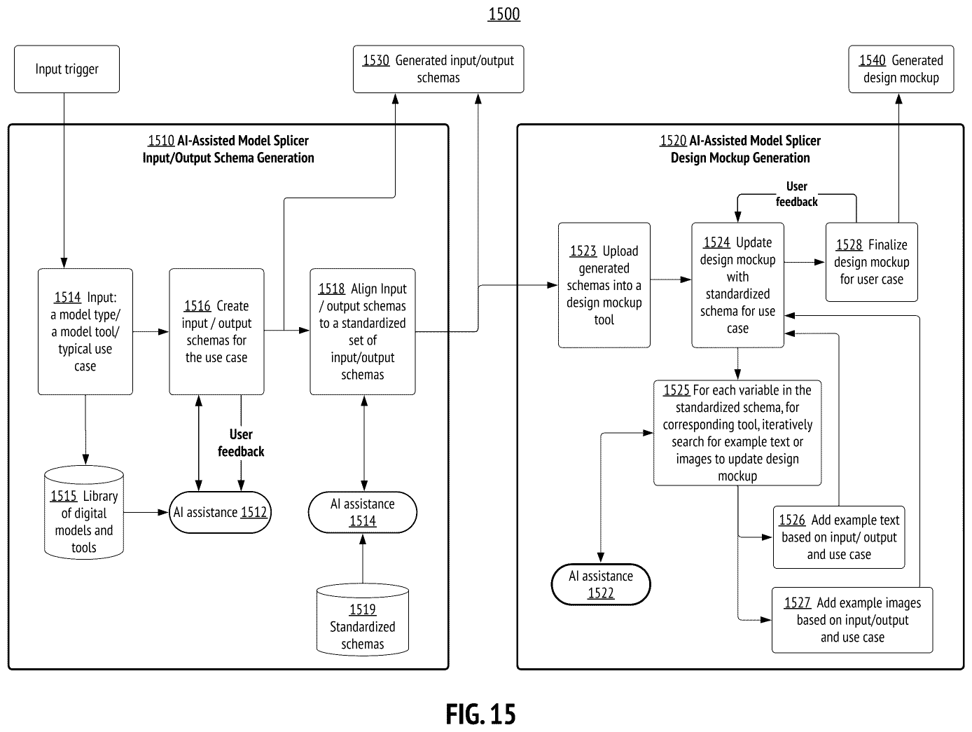

In exemplary implementations, a Zero-Knowledge implementation of AI-assisted model splicer generation (as shown in exemplary AI-assistance steps in FIG. 14 and in FIG. 15) tokenizes customer data when confirming input/output, design mockups and the functions for the specific DE tool. Tokenization is the process of exchanging sensitive data for a cryptographic identifier of that sensitive data. It is possible to use every function of the IDMP through the API alone, manually tokenizing data before submitting API requests.

A Zero-Knowledge architecture for the IDMP requires the API not to accept sensitive data. The platform's Software Development Kit (SDK) enforces this zero-knowledge constraint by tokenizing sensitive data before it is sent to the API. A zero-knowledge implementation of AI-assisted model splicing then must tokenize data in each of the three functions they rely on in the platform's standard schema or API to confirm I/O, design mockups, and the function name within the DE tool. Metadata that are part of the tokens are used to train AI models, while the sensitive data is encrypted into tokens and not used for training. The AI models predict representative input/output schema, design mockups and the function names. Additional AI models deployed as agents within the customer environment can match exact input/output schema, design mockups or function names of specific DE tools. Tokenization is the process of exchanging sensitive data for a cryptographic identifier of that sensitive data. De-tokenization is the process of exchanging that token for a copy of the sensitive data. The Zero-knowledge system as disclosed herein stores tokenized sensitive data on a customer's network rather than on the same network the systems run on.

In other implementations, the AI models may predict generic parameter names and generic function names in order to be consistent with a zero-knowledge approach.

### AI-Assisted Model Splicer Schema Generation and Mockup Creation

FIG. 15 is a schematic 1500 showing an exemplary AI-assisted model input/output schema generation module 1510 in an IDMP, and a corresponding AI-assisted model splicer design mockup generation module 1520, in accordance with some embodiments of the present invention. Again, “IDMP” refers to the universal, scalable, and adaptable interconnected digital model development platform that implements the modules and submodules as disclosed herein, including the ones shown in FIG. 15. Also note that the first AI model as referenced in the context of FIG. 13 may encompass any of the AI assistance modules 1512 and 1514 shown in FIG. 15.

In AI-assisted model input/output schema generation module 1510, generative AI algorithms as disclosed herein perform transductive learning to create input and output schemas for a new DE tool, or a new DE tool-DE model-type combination, based on existing schemas on the IDMP. Recall from the discussion with reference to FIGS. 7, that how model data may be organized in a data structure and accessed through APIs is fundamentally defined by the DE tool that created the model and is being used in splicing the model or in manipulating the model splice. A model data schema describes the organization and formatting of model data, the input/output schemas as generated by module 1510 describe the organization and formatting of input and output endpoints to model splices, while scripts generated with an AI-assistance submodule such as 1434 shown in FIG. 14, process data according to respective schemas (e.g., processing a variable according to its type and unit), to provide model access, manipulation, and linking capabilities.

More specifically, in FIG. 15, one or more of the following process steps may be carried out:
1. Input prompt: A DE model type and/or a DE tool to be used with the model type is provided at a step 1514, to prompt the creation of input/output schemas for one or more use cases at a step 1516, by a first AI assistance sub-module 1512 in module 1510 within the DE platform.
   In some embodiments, a human or a machine user may provide the input by selecting a model type/tool pair from a predefined list, such as stored in a library 1515 of digital models and tools.
   Multiple DE tools may be available for use with any given model type, with some tools proprietary and some tools open-source. For example, CAD models may work with AutoCAD, SolidWorks, CATIA, OpenFOAM, and other similar tools; Finite Element Analysis (FEA) models may work with ANSYS, Abaqus, NASTRAN, and other similar tools; a circuit model may work with SPICE, LTspice, Multisim and the like.
   In some embodiments, a user may provide an existing model splicer or model splice as the input, and the module 1510 may extract existing API endpoints as exemplary use case inputs to AI-assistance sub-module 1512.
2. Input/output schema generation: AI-assistance sub-module 1512 creates an example of input/output schemas at step 1516 for an output use case relevant to the input model type and tool, based on the input model type and/or tool, and exemplary input use cases. Input or output schemas provide templates for API endpoints within a model splice, which in some embodiments are shown as functions in a GUI. For example for modeling and simulation use cases, an input schema lists potential input data options for various modeling or simulation parameters. An output schema lists potential output data options following a modeling or simulation task.
   AI-assistance sub-module 1512 may implement any appropriate non-generative or generative AI algorithms. For example, it may be a pre-trained foundation LLM model such as GPT-4. In one example, it may be further trained on IDMP resource-capability mappings. In another example, it may have been fine-tuned on data collected from model splicing processes described with reference to FIG. 7.
   The output use case may be customized based on additional initial user input or user feedback to AI-assistant sub-module 1512.
   The resulting input/out schemas may be further fine-tuned based on user feedback to AI-assistant sub-module 1512. For example, an LLM such as GPT4 may be run in open-loop fashion initially, then external human expert feedback may be used to refine the generated input/output schemas 1530.
   In some embodiments, the input/output schemas 1530 generated in this step are provided directly as the output of module 1510.

Below is an example for AI-assisted generation of input/output schemas for the tool OpenFOAM. Specifically, the following prompt may be provided to LLM-based AI-assistance sub-module 1512 to create an example of the input/output schema for an example use case:

Exemplary input prompt:

“You are an expert in digital engineering. I am going to give you a digital engineering tool name, and you are going to give me an input and output schema for that tool, along with an example of how it could be used.

#### EXAMPLE ####
TOOL: Tool XYZ
FILE EXTENSION: .dxf
INPUTS:
{
″inputs″: [
{
″id″: 1,
″type″: ″Checkbox″,
″name″: ″Hide parts″
},
{
″id″: 2,
″type″: ″Radio Buttons″,
″name″: ″Resolution″,
″unit″: ″polygon count″
},
{
″id″: 3,
″type″: ″Number″,
″name″: ″Modify parameter″,
″unit″: ″mm″
}
]
}
OUTPUTS:
{
″outputs″: [
{
″id″: 1,
″type″: ″Image″,
″name″: ″2D Image″
},
{
″id″: 2,
″type″: ″File″,
″name″: ″3D viewer″
},
{
″id″: 3,
″type″: ″JSON″,
″name″: ″Complete set of parameters″
},
{
″id″: 4,
″type″: ″Array″,
″name″: ″List of parts″
},
{
″id″: 5,
″type″: ″Number″,
″name″: ″Parameter Value″,
″unit″: ″mm″
},
{
″id″: 6,
″type″: ″File″,
″name″: ″Download Native File″
}
]
}
#####
TOOL: OpenFOAM”

Note that only the DE tool name “OpenFOAM” is provided as an input prompt. In this setup, AI-assistance sub-module 1512 may provide input/output schemas that are associated with multiple DE model types or file extensions that work with the tool OpenFOAM. The user may prompt with specific model type and tool pair names as well.

An exemplary output provided by AI-assistance sub-module 1512 is as follows:

“FILE EXTENSION: .foam, .dict
INPUTS:
{
″inputs″: [
{
″id″: 1,
″type″: ″File″,
″name″: ″Mesh file″,
″file_extension″: ″.msh, .stl″
},
{
″id″: 2,
″type″: ″Dropdown″,
″name″: ″Simulation type″,
″options″: [″Steady-state″, ″Transient″]
},
{
″id″: 3,
″type″: ″Dropdown″,
″name″: ″Flow solver″,
″options″: [″Incompressible″, ″Compressible″, ″Multiphase″]
},
{
″id″: 4,
″type″: ″Dropdown″,
″name″: ″Turbulence model″,
″options″: [″Laminar″, ″RANS″, ″LES″, ″DNS″]
},
{
″id″: 5,
″type″: ″Number″,
″name″: ″Boundary conditions″,
″unit″: ″varies″
},
{
″id″: 6,
″type″: ″Number″,
″name″: ″Simulation time″,
″unit″: ″seconds″
},
{
″id″: 7,
″type″: ″Number″,
″name″: ″Time step″,
″unit″: ″seconds″
},
{
″id″: 8,
″type″: ″Checkbox″,
″name″: ″Parallel processing″
}
]
}
OUTPUTS:
{
″outputs″: [
{
″id″: 1,
″type″: ″File″,
″name″: ″Simulation results″,
″file_extension″: ″.foam, .vtk, .csv″
},
{
″id″: 2,
″type″: ″Image″,
″name″: ″Contour plot″
},
{
″id″: 3,
″type″: ″Image″,
″name″: ″Vector plot″
},
{
″id″: 4,
″type″: ″JSON″,
″name″: ″Simulation parameters″
},
{
″id″: 5,
″type″: ″Array″,
″name″: ″Time history data″
},
{
″id″: 6,
″type″: ″File″,
″name″: ″Simulation log″,
″file_extension″: ″.log″
}
]
}

### Example Use Case

An aerospace engineer is tasked with analyzing the airflow around a new aircraft design to determine its aerodynamic performance. The engineer imports the aircraft geometry as an STL file into OpenFOAM and sets the simulation type as “Steady-state.” They choose the “Incompressible” flow solver and select an appropriate turbulence model based on the expected Reynolds number. The engineer specifies boundary conditions for the simulation, sets the desired simulation time, and sets the time step for the solver. To speed up the simulation, they enable parallel processing. After running the simulation, the engineer can analyze the simulation results, including contour and vector plots, time history data, and the simulation log to understand the aircraft's aerodynamic characteristics and identify any areas for improvement.”
3. Schema Alignment: the generated input/output schema 1530 may be aligned, or fitted to a standardized or standard set of input/output schema or “input/output building blocks”.
   A standardized schema refers to a standard set of types of variables. For example, web app input and output types or building blocks in standard HTML. An non-exhaustive list of web app input and output types is provided at the end of this subsection.
   Schema alignment is the process of simplifying the myriad formats from many different DE model types into a set of consistent data types such that it is easy to edit, understand, and link to other models.
   For example, for an input schema related to a GUI, corresponding standard types may be “text box”, “radio button” etc. For an output schema related to image outputs, corresponding standard types may be “URL” to an image.
   Alignment refers to having one of more variable types within the input or output schema that are part of a small set of standard types.
   In some embodiments, schema alignment 1518 is performed via an AI-assistance sub-module 1514, using standardized schemas 1519 retrieved from an internal database. In some embodiments, the AI-assistance sub-module 1514 is implemented as a ML classifier with feedback, or a generator with a transformer model.
   In various embodiments, both AI-assistance sub-modules 1512 and 1514 may be trained on data the IDMP has collected over a variety of DE tools, model type files, and of the standardized schema, which may be used to set the system context for an LLM like GPT 4.
   In some embodiments, the aligned input/output schemas generated in this step are provided as the output 1530 of module 1510.

For further illustration, below is an non-exhaustive list of standard web app input and output types:
Exemplary simple input types include, but are not limited to: text, number, dropdown (select), checkbox, radio button, textarea, file upload, date input, time input, range input (slide), color input, email input, password input, URL input, and Search input.

Exemplary advanced input types include, but are not limited to: autocomplete (typeahead), tag input, rich text editor, data range picker, time range picker, geolocation input, file dropzone, multiple file upload, star rating input, and slider with multiple handles.

Exemplary simple output types include, but are not limited to: plain text, numeric value, date (in predefined format), time, image, link (anchor), list, table, button, and tooltip.

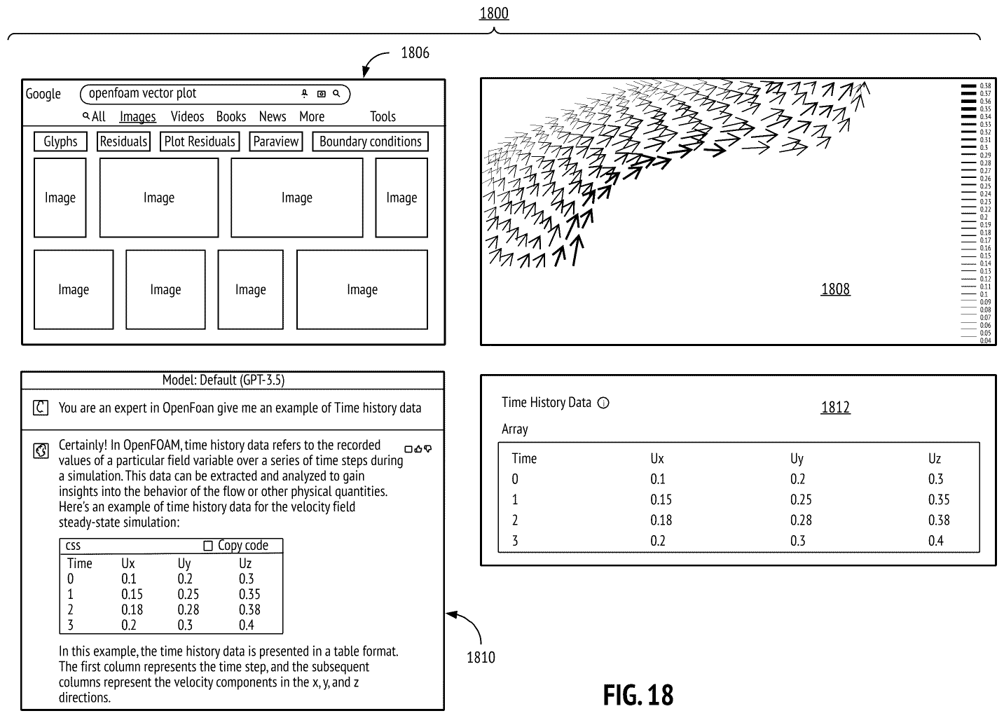

Exemplary advanced output types include, but are not limited to: interactive chart or graph, data grid (advanced table), accordion, carousel (slide), modal (dialog), progress bar, tabs, map, timeline, and treeview.
4. Design mockup: while the generated input/output schemas 1530 may be sent to a model splicer design definition module 1428 discussed with reference to FIG. 14, the generated input/output schemas may also be used to generate a visual model splicer mockup. In the embodiment of the AI-assisted model splicer design mockup generation module 1520 shown in FIG. 15, the input/output schemas may first be uploaded at a step 1523 into a design mockup tool such as FIGMA to form the basis of a visual mockup without examples, and each variable in the generated input and output schemas may be iterated or looped through steps 1524, 1525, 1526, and 1527 to update the base design mockup. That is, the IDMP may iteratively search for example text or images/graphics to update the base design mockup, without or without user input, and optionally via an AI-assistance module 1522.
   Each search may be performed using a traditional or chatbot-based search engine
   For example, a traditional web search engine may be used to search for images related to the input DE tool and the variable under consideration. For instance, the phrase “OpenFOAM vector plot” may be used as a search key to look for vector plots (see FIG. 18). One or more example images found may be added to the design mockup based on the use case.
   Similarly, ChatGPT may be prompted to find text examples, to be copied into the designed mockup.
   Once all variables in the input and output schema have corresponding image and/or text examples, the mockup may be reviewed, updated based on user feedback, and finalized in the design mockup tool at a step 1528 into a full design mockup 1540.

### AI-Assisted Function Script Generation

FIG. 16 shows an exemplary open-source LLM implementation 1600 of AI-assisted function script generation in a model splicer generation engine, in accordance with some embodiments of the present invention. Specifically, this illustrative embodiment may be an implementation of AI-assistance submodule 1434 using LlamaAcademy, an open-source LLM that combines crawling, data generation using GPT3.5 and GPT4, and fine-tuning Vicuna-13B on synthetic data, to fine-tune on API documentation and generate API scripts using META's Large Language Model Meta AI (LLaMa), MICROSOFT's Low-Rank Adaptation of LLMs (LoRA), and the open-source LangChain.

In the illustrative implementation shown in FIG. 16, the system utilizes LLMs to generate model splicers for a generalized variety of model types and tools, effectively bridging the gap between various DE tools. For a desired DE tool, its respective API documentation webpages may be collated using advanced techniques such as autoGPT. The system then may scrape all text and API calls from these documentation webpages and related forums using web scraping tools such as Elinks and Selenium. The extracted text is converted into embeddings using a tokenizer and an embeddings API or similar technology. These API texts and their corresponding embedding vectors are stored in a vector database, which is further enhanced by summarizing each API text using a fast Language Model (e.g., GPT-3.5) and adding these summaries additionally in the database.

To facilitate seamless interaction with developers or users, the system may convert user questions about API usage into embeddings and identifies the closest embeddings in the vector database using techniques such as cosine similarity. The API summary and text of the closest embeddings may then be converted back into regular text, which serves as input for an advanced LLM (e.g., GPT-4) to construct a script for a wrapper. The generated script may be tested on the actual software (e.g., OpenFOAM) for compilation, and if unsuccessful, the advanced LLM is requested to fix the script until it compiles successfully. The successfully compiled code and the original request are added to the vector database, and the process iterates (e.g., for approximately 10,000 requests) to generate a diverse sample of API usage. This iterative approach may be repeated for each tool of interest, ultimately creating a comprehensive knowledge base for various DE tools. Optionally, additional human or alternative checkers may be employed to ensure code functionality, and fine-tuned LLMs may be developed for each specific tool, enhancing the system's overall performance.

Individual steps listed in FIG. 16 are as follows:
Step 1: List desired DE tools
Step 2: Locate API documentation webpages for these tools (e.g., using autoGPT)
Step 3: Scrape text and API calls from the API documentation webpages and forums (using web scraping tools such as Elinks and Selenium)
Step 4: Convert the scraped text into embeddings (using tokenizer and embeddings API or similar)
Step 5: Store the API text and corresponding embeddings vectors in a vector database
Step 6: Summarize each API text using a fast Language Model (e.g., GPT-3.5)
Step 7: Add the summaries as another column in the vector database (API Text: Text Embeddings, API Summary)
Step 8: Vectorize the Language Model summarizations using tokenizer and embeddings API Step 9: Add the summary embeddings as another column in the vector database (API Text: Text Embeddings, API Summary: Summary Embeddings)
Step 10: When a developer/user/LLM asks a question about how to use the API, convert the question into an embedding
Step 11: Find the closest embeddings in the vector database (e.g., cosine similarity) Step 12: Convert the API summary and API text of the closest embeddings back into regular text
Step 13: Use the retrieved data as input and ask an advanced LLM (e.g., GPT-4) to construct a script for a model splicer or wrapper
Step 14: Test the generated script on the actual software (e.g., OpenFOAM) to see if it compiles
Step 15: If the script doesn't compile, request the advanced LLM to fix it
Step 16: Repeat steps 14-15 until the script compiles successfully
Step 17: Add the successfully compiled code and the original request to the vector database
Step 18: Ask an LLM to make a slight modification to the original request
Step 19: Restart at step 10 and iterate for ˜10,000 requests to get a diverse sample of API usage
Step 20: Once 10,000 requests have been completed, move on to the next tool in step 1.

In some embodiments, an additional human or alternative checker can ensure the code not only compiles but also implements the desired functionality according to the original request. In alternative embodiments, instead of solely using embeddings in a vector database, information from steps 10 and 17 may be used to fine-tune smaller, custom LLMs for each tool, creating a fine-tuned LLM for each specific tool.

In various embodiments, the aforementioned steps may be implemented by different components shown in FIG. 3. For example, steps 1-2 may refer to both agents in the exclave 316 (e.g., DE platform agent, DE tool agent), as well the DE platform API in the IDEP Enclave 302. Model splicer generation may be performed on the enclave (e.g., creating splice functions linked with universal IDEP API), and in other examples, in the exclave (e.g., where the tool API vector store is additionally located in customer data buckets). The various LLM examples shown within the splicer generation engine in FIG. 16 may be implemented as one or more language agents that are created with open-source models and deployed in the exclave. While public models such as GPT4 and OpenAI models work for the intended purposes, local instances (e.g. Mistral, Llama3) may be used instead to maintain data security.

### Model Splicer Design Mockup Examples

FIGS. 17-21 show exemplary model splicer design mockups generated by AI-assisted module 1520 in FIG. 15. Such mockups may be generated for illustrative use cases, based on expert input internal to the IDMP, or based on user input preferences externally. In particular, FIG. 17 shows a screen capture illustrating an exemplary AI-assisted process for creating a OPENFOAM model splicer design mockup, in accordance with some embodiments of the present invention. Specifically, FIG. 17 is a base mockup 1700 for a “Hide parts & Share compressed 2D file” model splicer when generated input/output schemas are first uploaded to an interface design tool such as FIGMA.

In this example shown in FIG. 17, under a “Model” tab, typical input model data fields (e.g., file upload, simulation type, flow solver, etc.) and output digital artifacts (e.g., simulation results, contour plot, etc.) that can be generated from OPENFOAM are listed.

While not shown explicitly in FIG. 17, an “API” tab may list the input and output schemas. Following is a set of example input and output schemas.

```
Inputs:
{
  “3d_model_file”: “.stp”,
  “tessellation_quality”: 0.5,
  “boolean_operation”: [“Union”, “Difference”, “Intersection”],
  “export_format”: “STP”
}
Output Schema:
{
  “id”: 1,
  “type”: “File”,
  “name”: “3D model File”,
  “file_extension”: “.stp”
},
{
  “id”: 2,
  “type”: “Number”,
  “name”: “Tessellation Quality”,
  “unit”: “Level of detail”
},
{
  “id”: 3,
  “type”: “Checkbox”,
  “name”: “Boolean Operation”,
},
{
  “id”: 4,
  “type”: “Radio Button”,
  “name”: “Export Format”,
}
```

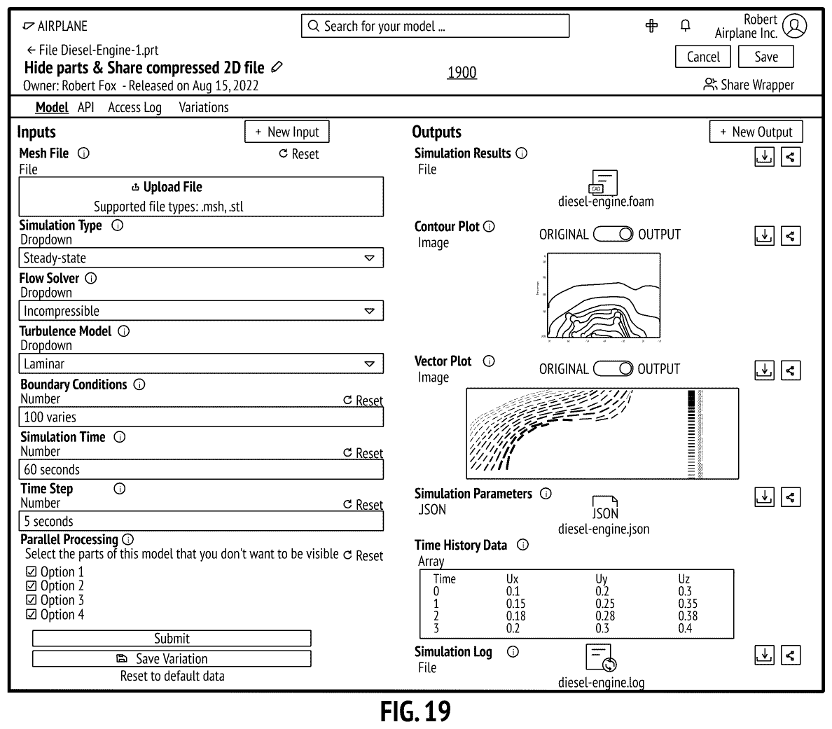

FIG. 18 shows screen captures 1800 illustrating an exemplary AI-assisted process for obtaining exemplary digital artifacts via process steps 1524, 1525, 1525 and 1527, in accordance with some embodiments of the present invention. Specifically, a diagram 1806 shows an example of an online image search for an “OpenFOAM Vector Plot” (e.g. using GOOGLE PHOTOS). A user may select an appropriate image 1808 from all the search results and copy it into the base mockup 1700. A diagram 1810 shows an example of a text search using ChatGPT, with the prompt “You are an expert in OpenFOAM, give me an example of Time history data”. A Time History Data table 1812 thus generated may be inserted into the base mockup 1700 as well. The same lookup processes may be performed for all variables in the input and output schemas shown in base mockup 1700, and a fully populated mockup 1900 such as shown FIG. 19 may be generated as a result. FIG. 19 is a full model splicer design mockup derived from FIGS. 17 and 18, in accordance with some embodiments of the present invention.

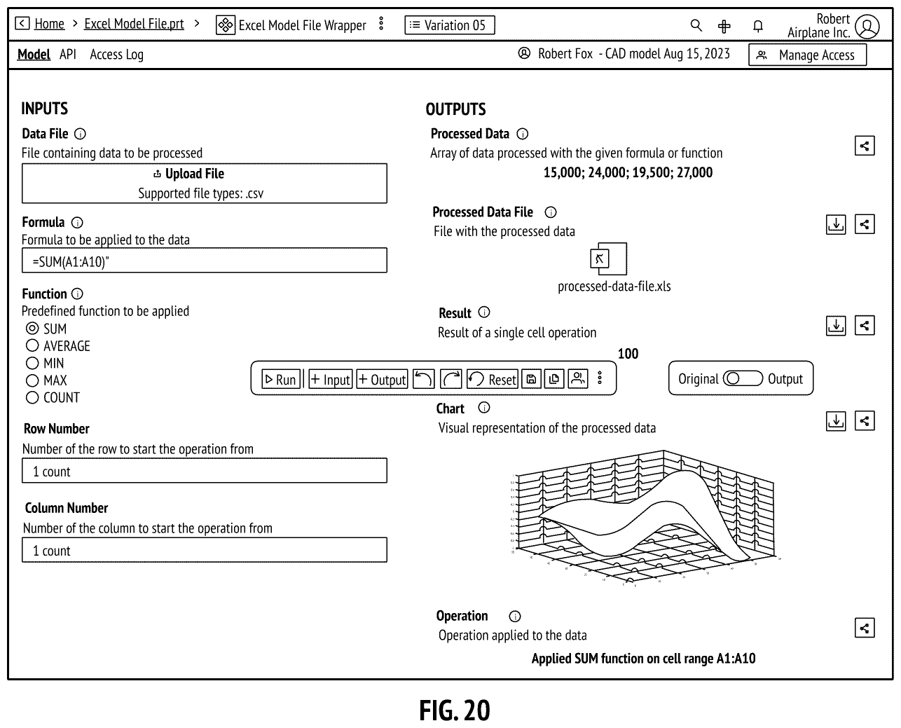

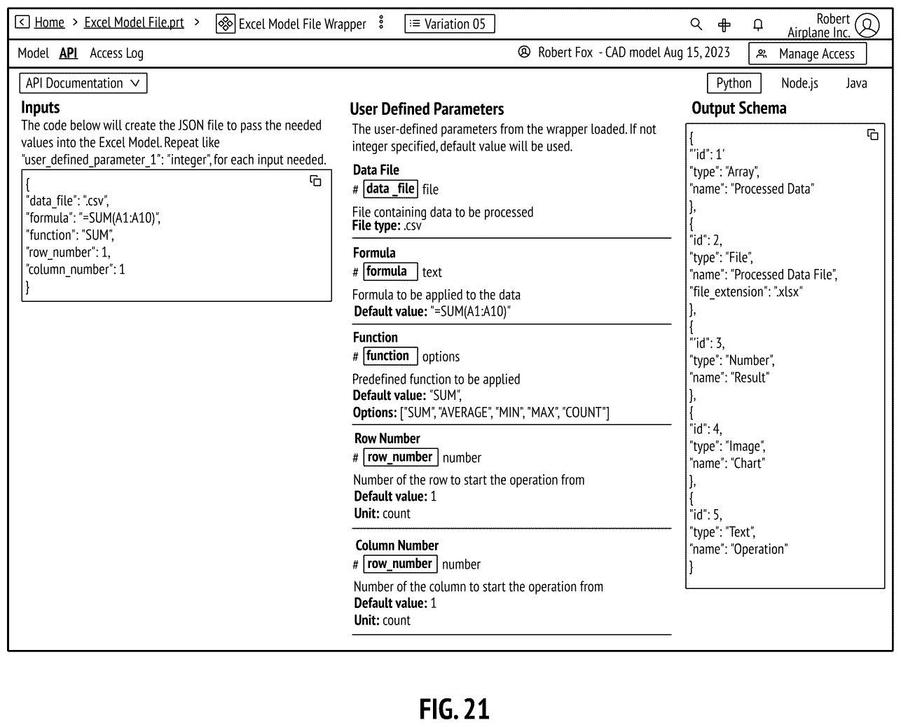

As another example, FIG. 20 shows an illustrative EXCEL model splicer design mockup, and FIG. 21 shows a corresponding API tab, both in accordance with some embodiments of the present invention. EXCEL is a widely used DE tool or digital tool that is applicable to many different DE model types, including but not limited to simulation data model, financial data model, and the like. Across such different model types, input and output schemas and splice functions may be common or universal. For example, in FIG. 20, regardless of the input model type, data fields such as file upload, formula, function, and row and column numbers may be commonly used and thus generated by the system and used to create the design mockup. Similarly, typical output digital artifacts such as processed data arrays, processed data files, charts, and applied function outputs are listed in FIG. 20. Under the API tab, FIG. 21 shows inputs, user defined parameters, and output schemas used for this mockup.

While now shown explicitly, many other illustrative model splicer design mockups for various DE model types and/or DE tools can be created. For example, mockups can be created for OpenFOAM, 3DX, and Creo for CAD models, Matlab Simulink for engineering scripts, OpenCascade for CFD, Ansys for FEA, Autodesk Eagle for Electronics systems model, PLM tools for Integrated master plan models, and ERP tools for Supply chain models, etc. For a CAD model, the generated input/output schemas may differ depending on the tool used.

AI-Assisted Script Generation Via LLM Models with Fine-Tuning

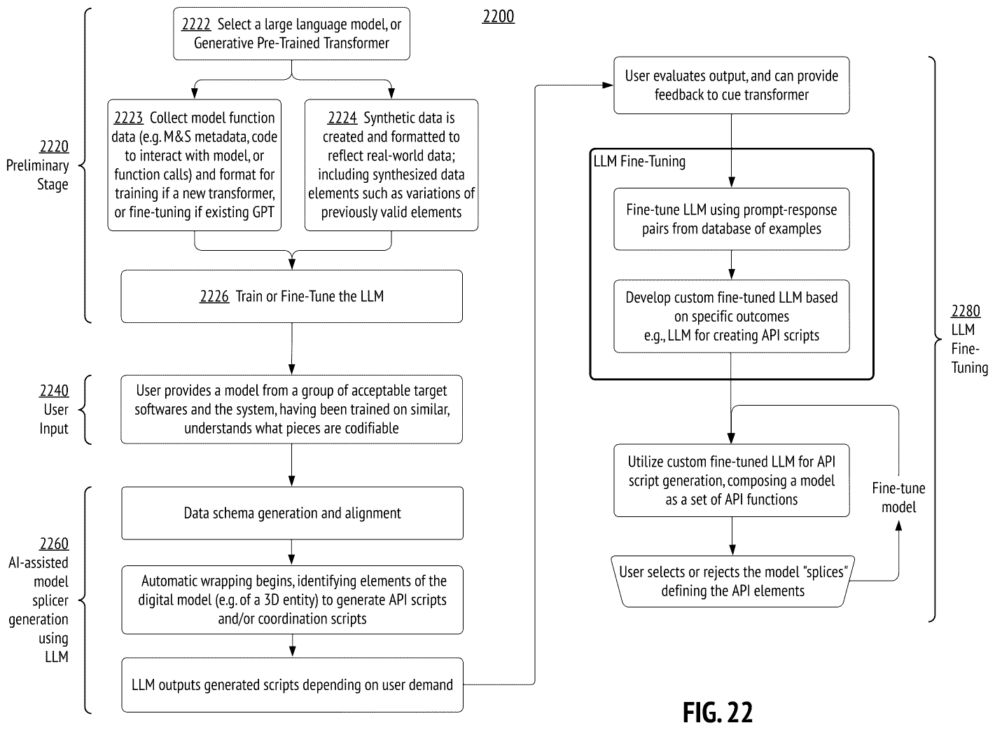

While FIGS. 12 and 14 provide generalized end-to-end process flow for model splicer creation, from customer request to generated model splicers on the IDMP, FIG. 22 shows an exemplary process for model splicer generation via Large Language Models (LLMs) directly, with prompt-response fine-tuning, in accordance with some embodiments of the present invention.

In particular, the process in FIG. 22 may be applied to exemplary implementations of the model splicer development stage 1430 discussed in FIG. 14, specifically of the implementation of AI-assistance sub-module 1434 shown in FIG. 14 for API function wrapping and script generation.

More specifically, process 2200 illustrated in FIG. 22 comprises four stages: a preliminary AI model selection and training stage 2220, an user input stage 2240, an AI-assisted API model splicer generation stage 2260, and an LLM fine-tuning stage 2280.

During the preliminary AI model selection and training stage 2220, a LLM or a generative pre-trained (GPT) transformer (e.g., GPT-3 da vinci) may first be selected at a step 2222. Pre-training of such AI models is usually performed on large swarms of publicly available data, but not tailored specifically for DE function script generation. Various embodiments of the present invention thus train or fine-tune the selected AI model. Training data are collected and formatted at a step 2223, and stored in a training data database, for training a selected new transformer or for fine-tuning an existing GPT at a step 2226. In the following description of FIG. 22, an LLM is used as an illustrative but non-limiting example of an AI model for script generation.

Exemplary training data may include, but are not limited to, IDMP resource-capability mappings, IDMP documentations, DE model function data such as modeling and simulation metadata, code to interact with a DE model, tool APIs or function calls. Note as the LLM is prompted to generate scripts, prompt-and-response pairs may be collected and aggregated from valid and user-verified tool function calls and API function scripts recorded during past model manipulation or model splicing processes. For example, consider a CAD model for an object (e.g., a shape) in SolidWorks, CATIA, or OpenCASCADE. A user or SME may have attempted to create the object, which has tessellations or facets defined by triangles, using API function scripts. That is, the user referenced specific API elements of a tool in particular sequences or orders to create the desired object. Such user actions may have been captured previously and stored in the training data database, as an object and corresponding tool and code that generated it. Alternatively, the DE tool may have functionalities to export the object to code.

In some embodiments, training data augmentation 2224 may be used to artificially increase the training dataset by creating synthetic data from existing, verified data, and to reduce model overfitting. For example, synthetic data such as variations of previously valid data elements may be created and formatted to reflect real-world, user-generated data. For function script generation, an abstract syntax tree may be used to inform what elements of the API may be varied, and a rule-based approach may be used to generate specific variations. Such variations may be checked by leveraging validation and verification capabilities within a compiler. That is, a script variation can be queued at the compiler to check for syntax, and if it compiles, it is considered valid and can be added as synthetic training data; if not, alternate perturbations of the abstract syntax tree may be pursued.

Below is an illustrative example. Assume the following AI model prompt and response are used to generate synthetic variations:

```
Prompt: “Create a cube with equal dimensions of 10 inches”
  Response:
    #include <BRepPrimAPI_MakeBox.hxx>
    #include <TopoDS_Shape.hxx>
    int main( )
    {
    // Create a cube with a length, width, and height of 10 inches
    BRepPrimAPI_MakeBox box(10*25.4, 10*25.4, 10*25.4); // convert inch to mm
    TopoDS_Shape shape = box.Shape( );
    return 0;
    }
```

An exemplary synthetic data creation process comprises the following steps:
1. Take the above response and perform basic Abstract Syntax Tree (AST) decomposition
2. Assess the function call and its parameters as the primary API element for variation
3. Vary the parameters within the bounds of rules and constraints
4. From the AST, recompose a function similar to the original in structure but altered to effect the model differently
5. Validate the new function by analyzing the output of compilation
6. Verify and persist new function call in training data

After initial AI model training/fine-tuning 2226, a customer or user may provide or select a DE model or tool from a group of acceptable target software, in an user input stage 2240. As the AI model from the previous stage has been trained on similar DE models or tools, it understands what pieces of the input DE model or tool is codifiable.

Next, AI-assisted model splicer generation 2260 begins, where input/output schemas are created, and elements of the DE model (e.g., of a 3D entity) are identified to generate API scripts. Based on user demand, the AI model (e.g., LLM) may also output specific API scripts as part of the model splicer generation process.

As soon as API scripts are generated by the LLM, the user or other SMEs may evaluate, verify, and provide feedback to the LLM, in a LLM fine-tuning stage 2280 shown in FIG. 22. That is, as humans use the AI-assisted system, their input (e.g., selection or rejection of a generated data schema or API script) contributes additional model, tool, and API script data for AI-assistance modules shown in FIGS. 14-16. The system is therefore better informed, and such incremental training data on the particular DE model type and DE tool can contribute to fine-tuning the AI-assisted script generation for the particular script generation task on hand.

An illustrative architecture for fine-tuning the LLM in FIG. 22 is discussed below. Based on the use of platform data, this architecture may be reused on separate fine-tuning datasets to train and create a library of fine-tuned LLMs, each customized to specific AI-assistance use cases (e.g., documentation, model sharing), or targeted to a different DE software or tool.

In various embodiments, during LLM training and/or fine-tuning,
1. Training data may include IDMP resource-capability mappings, scripts and functions for models, as well as model transaction history.
2. Synthetic data creation may follow a rule-based approach for permutations on existing data, using an abstract syntax tree for variants, where a compiler is used to verify success.
3. Prompt-response pairs for fine-tuning the LLM may be increased through permutations following an abstract syntax tree.
4. System architecture may be reused to train and create a library of fine-tuned LLMs, each customized to a specific AI-assistance use case (e.g., documentation, model sharing).

Furthermore, training data examples may include any of the following:
1. API documentation, such as API reference guides, user guides, and tutorials.
2. Technical articles and blog posts, specifically discussing digital engineering APIs.
3. Code snippets and sample projects that demonstrate how to use the API in various programming languages.
4. Online forums (e.g., Stack Overflow) and other Q&A threads.
   a. The training dataset would include stack overflow and other Q&A threads that discuss digital engineering APIs.
5. Publicly available APIs, such as API endpoint descriptions, request/response examples, and other information that can be gathered from publicly available APIs.

In some embodiments, synthetic data generation may rely on:
1. Abstract syntax tree—customized for specific digital engineering applications.
2. Selectively run permutations on training data.
3. Test for compile, then recommend adding to synthetic data.
4. Expert feedback.

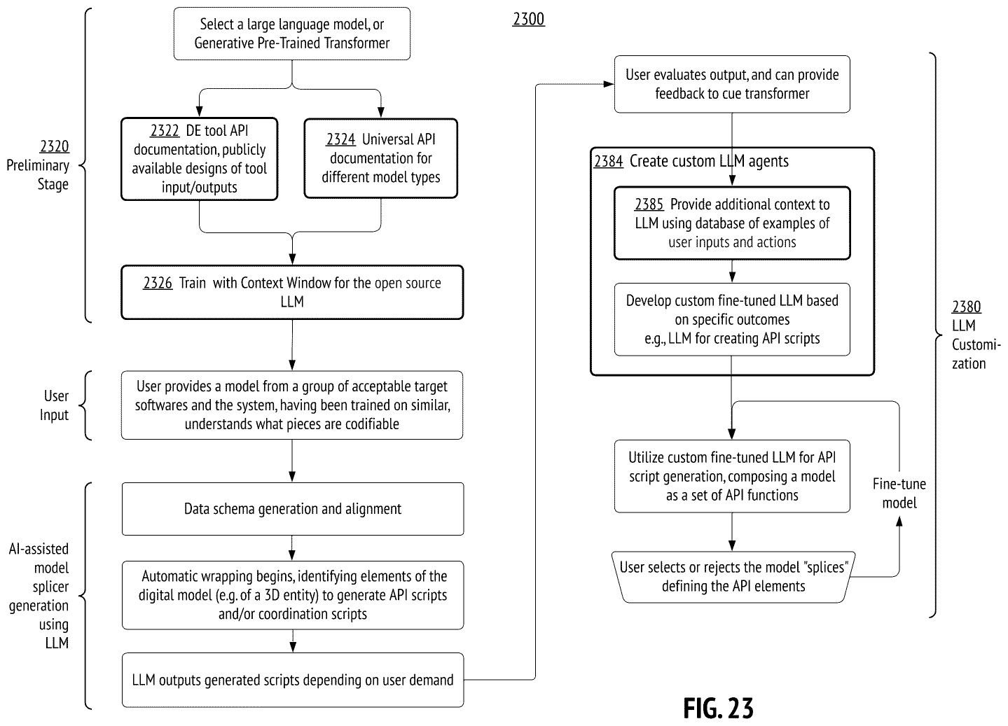

FIG. 23 shows another exemplary process 2300 for model splicer generation via a Large Language Model (LLM) with LLM customization, in accordance with some embodiments of the present invention. This illustrative example is a variant of the one shown in FIG. 22. During the preliminary training stage 2320, DE tool API documentation and publicly available designs of tool input/outputs 2322 and universal API documentation (e.g., similar to the IDEP platform API described earlier) for different model types 2324 may be used as a context window in a training step 2326 to train a pre-selected, possibly open-sourced LLM. After this LLM is used to generate function scripts, further LLM customization 2380 may be completed by providing additional context to the LLM at a step 2385 using databases of examples of user input and actions. Thus, custom LLM agents 2384 may be created for specific use cases, specific digital workflows, or specific IDMP customers.

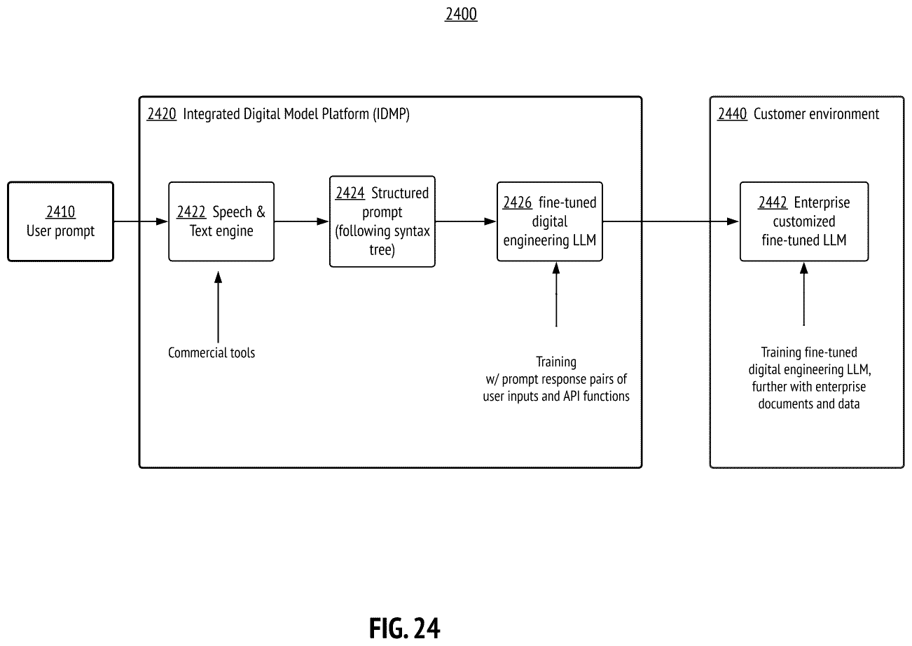

FIG. 24 shows an exemplary architecture 2400 for fine-tuning an LLM using DE data, in accordance with some embodiments of the present invention. This illustrative architecture includes an IDMP 2420 and a customer environment 2440, where an enterprise-customized LLM 2442 may be further fine-tuned with enterprise documents and data proprietary to the customer. In some embodiments the IDMP 2420 is part of IDMP enclave 302 and the customer environment 2440 is part of the customer environment 310.

In this setup, a user inputs information at a step 2410 into IDMP 2420. Such information may be of various forms. In some embodiments, there are broadly two types of inputs: objects and details. Objects may include all types of files, and details may include attributes about those files. Interactions with the platform and uploaded objects may also be considered user input. The interactions are facilitated via a UI that may be audio and/or visual in nature. Examples of files include code, step files, binaries, and archives. Examples of details include name of files, labels of contents within files, and documentation. Examples of user interactions include all the functions supported for CAD/CAM, zoom in, and hide parts. In some embodiments, a chat-like interface that also takes audio inputs to perform some actions may be included.

The information enters a speech and text engine 2422, which may include commercial tools, where it is processed. The processed information may be converted to structured prompts 2424 (e.g., following a syntax tree) for fine-tuning a DE LLM 2426, which may be trained and optionally fine-tuned with prompt response pairs of user inputs and API functions for DE tools. The results may then be used outside of the IDMP 2420 and move to the customer environment 2440, where an enterprise customized LLM 2442 may be further fine-tuned with enterprise documents and data.

Again, this exemplary architecture may be implemented by multiple agents on the IDEP enclave and exclave shown in FIG. 3.

Within the IDEP enclave, the following may be implemented:
Any speech and text engines as agents using an automatic speech recognition (ASR) web service such as OPENAI's Whisper model, or open-source alternatives like NVIDIA's NeMo, or SpeechBrain.
Structured prompting may include a LLM agent to revise the prompting with a context window of syntax tree, or an ML model that is a recommender engine.
IDMP API may be used to customize the LLM. For example, an open source LLM agent can be customized with IDMP API and public documentation as context window

Within the IDEP enclave, the following may be implemented:
The LLM may be made enterprise-specific. For example, one or more open-source LLM agents may be customized with context windows such as DE tool-specific context or enterprise documentation-specific context.

### Machine Learning (ML) and Neural Networks

Machine learning (ML) algorithms are characterized by the ability to improve their performance at a task over time without being explicitly programmed with the rules to perform that task (i.e., learn). An ML model is the output generated when a ML algorithm is trained on data. As described herein, embodiments of the present invention use one or more AI and ML algorithms to perform model splicer generation and update. Various exemplary ML algorithms are within the scope of the present invention. The following description describes illustrative ML techniques for implementing various embodiments of the present invention.

### Neural Networks

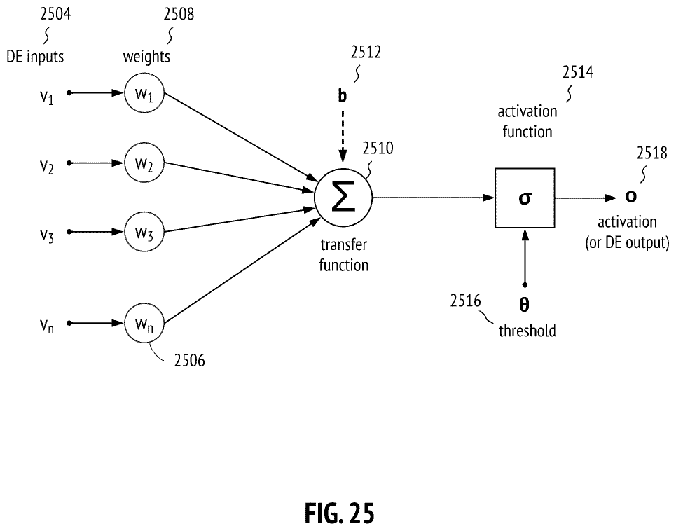

A neural network is a computational model comprising interconnected units called “neurons” that work together to process information. It is a type of ML algorithm that is particularly effective for recognizing patterns and making predictions based on complex data. Neural networks are widely used in various applications such as image and speech recognition and natural language processing, due to their ability to learn from large amounts of data and improve their performance over time. FIG. 25 describes neural network operation fundamentals, according to exemplary embodiments of the present invention.

FIG. 25 shows a single-layered neural network, also known as a single-layer perceptron. The operation of a single-layered neural network involves the following steps:
1. Input: Receiving a DE input vector v 2504 with elements vⱼ, with j∈[1, n] representing the j^{th} DE input, and where each element of the vector corresponds to an element 2506 in the input layer. For an exemplary neural network model (e.g., to implement a recommender/generator engine) trained to determine whether an existing splice function is to be recommended based on user input, the DE input vector v 2504 may take the form of a user prompt. A DE input can be a user prompt, a DE document, a DE model, DE program code, system data from the IDEP, and/or any useful form of data in digital engineering.
2. Transfer Function: Multiplying each element of the DE input vector by a corresponding weight wⱼ 2508. These weighted inputs are then summed together as the transfer function, yielding the net input to the activation function

$${\sum }_{j = 1}^{n} {v}_{j} \cdot {w}_{j} 2510.$$

Each neuron in a neural network may have a bias value 2512, which is added to the weighted sum of the inputs to that neuron. Both the weights and bias values are learned during the training process. The purpose of the bias is to provide every neuron with a trainable constant value that can help the model fit the data better. With biases, the net input to the activation function

$${\sum }_{j = 1}^{n} \{ {v}_{j} \cdot {w}_{j} \} + b .$$

In the exemplary neural network model described above (e.g., to implement a recommender engine), the value of the transfer function 2510 may represent the probability that an existing splice function will be recommended.
3. Activation Function: Passing the net input through an activation function 2514. The activation function σ determines the activation value o 2518, which is the output of the neuron. It is typically a non-linear function such as a sigmoid or ReLU (Rectified Linear Unit) function. The threshold θ 2516 of the activation function is a value that determines whether a neuron is activated or not. In some activation functions, such as the step function, the threshold is a specific value. If the net input is above the threshold, the neuron outputs a constant value, and if it's below the threshold, it outputs a zero value. In other activation functions, such as the sigmoid or ReLU (Rectified Linear Unit) functions, the threshold is not a specific value but rather a point of transition in the function's curve.
   In the exemplary neural network model described above (e.g., to implement a recommender engine), the activation function σ 2514 may be a ReLU that is activated at a threshold θ 2516 representing the minimum probability for an existing splice function to be recommended. Hence, the activation function 2514 will yield a positive recommendation when the recommendation likelihood exceeds the threshold θ 2516.
4. Output: The activation value o 2518 is the output of the activation function. This value is what gets passed on to the next layer in the network or becomes the final DE output in the case of the last layer. In the exemplary neural network model described above (e.g., to implement a recommender engine), the activation value o 2518 is a DE output that is a boolean or binary parameter taking a positive value when an existing splice function is to be recommended and a negative value otherwise. A DE output can be a DE document, a DE model, DE program code, or any useful form of data in digital engineering.

In the exemplary neural network discussions of FIG. 25, examples are provided with respect to a particular recommender engine implementation using neural networks. Analogous approaches can be used to implement the generator engine and any other NN-based components of the systems and subsystems described herein.

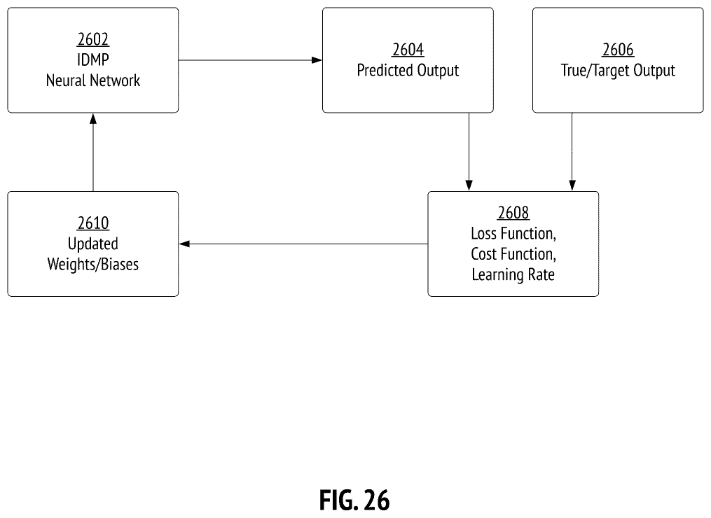

FIG. 26 shows an overview of an IDMP neural network training process, according to exemplary embodiments of the present invention.

The training of the IDMP neural network involves repeatedly updating the weights and biases 2610 of the network to minimize the difference between the predicted output 2604 and the true or target output 2606, where the predicted output 2604 is the result produced by the network when a set of inputs from a dataset is passed through it. The predicted output 2604 of an IDMP neural network 2602 corresponds to the DE output 2518 of the final layer of the neural network. The true or target output 2606 is the true desired result. The difference between the predicted output and the true output is calculated using a loss function 2608, which quantifies the error made by the network in its predictions.

The loss function is a part of the cost function 2608, which is a measure of how well the network is performing over the whole dataset. The goal of training is to minimize the cost function 2608. This is achieved by iteratively adjusting the weights and biases 2610 of the network in the direction that leads to the steepest descent in the cost function. The size of these adjustments is determined by the learning rate 2608, a hyperparameter that controls how much the weights and biases change in each iteration. A smaller learning rate means smaller changes and a slower convergence towards the minimum of the cost function, while a larger learning rate means larger changes and a faster convergence, but with the risk of overshooting the minimum.

For an IDMP neural network model 2602 based on the exemplary neural network model (e.g., to implement a recommender engine) discussed above in the context of FIG. 25, and trained to determine whether an existing splice function is to be recommended based on user instructions:
the weights and biases 2610 are the IDMP neural network's hyperparameters that get updated at each iteration of the training process, as discussed in the context of FIG. 25,
the predicted output 2604 is the binary prediction on whether the existing splice function is to be recommended based on a sample user prompt, (or a normalized score ranking prioritizing the order of existing splice functions to be displayed to the user),
the true/target output 2606 is the correct decision (i.e., sample ground truth output) on whether to recommend the existing splice function based on the sample user prompt,
the loss function 2608 is the difference between the evaluation and the true output (e.g., a binary error indicating whether the IDMP neural network's decision was correct),
the cost function 2608 is the average of all errors over a training dataset including sample user prompts and corresponding binary recommendations on the splice function, and
the learning rate 2608 is the rate at which the cost function 2608 in consecutive training epochs approaches a pre-specified tolerable cost function.

Neural network training combines the processes of forward propagation and backpropagation. Forward propagation is the process where the input data is passed through the network from the input layer to the output layer. During forward propagation, the weights and biases of the network are used to calculate the output for a given input. Backpropagation, on the other hand, is the process used to update the weights and biases 2610 of the network based on the error (e.g., cost function) 2608 of the output. After forward propagation through the IDMP neural network 2602, the output 2604 of the network is compared with true output 2606, and the error 2608 is calculated. This error is then propagated back through the network, starting from the output layer and moving towards the input layer. The weights and biases 2610 are adjusted in a way that minimizes this error. This process is repeated for multiple iterations or epochs until the network is able to make accurate predictions.

The neural network training method described above, in which the network is trained on a labeled dataset (e.g., sample pairs of input user prompts and corresponding output recommendations), where the true outputs are known, is called supervised learning. In unsupervised learning, the network is trained on an unlabeled dataset, and the goal is to discover hidden patterns or structures in the data. The network is not provided with the true outputs, and the training is based on the intrinsic properties of the data. Furthermore, reinforcement learning is a type of learning where an agent learns to make decisions from the rewards or punishments it receives based on its actions. Although reinforcement learning does not typically rely on a pre-existing dataset, some forms of reinforcement learning can use a database of past actions, states, and rewards during the learning process. Any neural network training method that uses a labeled dataset is within the scope of the methods and systems described herein, as is clear from the overview below.

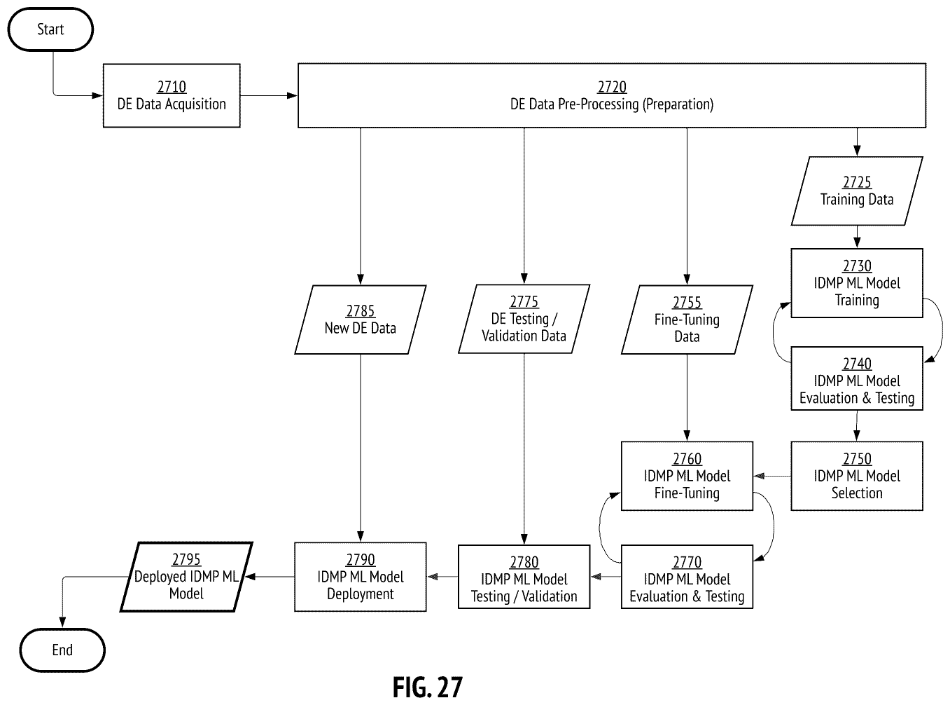

FIG. 27 provides additional details on the training process or an IDMP machine learning model, according to exemplary embodiments of the present invention.

### Transformer Model Architecture

The transformer architecture is a neural network design that was introduced in the paper “Attention is All You Need” by Vaswani et al. published in June 2017 (available at arxiv (dot) org), and incorporated herein by reference as if fully set forth herein. Large Language Models (LLMs) heavily rely on the transformer architecture.

The architecture (see FIG. 1 in Vaswani et al.) is based on the concept of “attention”, allowing the model to focus on different parts of the input sequence when producing an output. Transformers consist of an encoder and a decoder. The encoder processes the input data and the decoder generates the output. Each of these components is made up of multiple layers of self-attention and point-wise, fully connected layers.

The layers of self-attention in the transformer model allow it to weigh the relevance of different parts of the input sequence when generating an output, thereby enabling it to capture long-range dependencies in the data. On the other hand, the fully connected layers are used for transforming the output of the self-attention layers, adding complexity and depth to the model's learning capability.

The transformer model is known for its ability to handle long sequences of data, making it particularly effective for tasks such as machine translation and text summarization. In the transformer architecture, positional encoding is used to give the model information about the relative positions of the words in the input sequence. Since the model itself does not have any inherent sense of order or sequence, positional encoding is a way to inject some order information into the otherwise order-agnostic attention mechanism.

### The Embeddings Vector Space

In the context of neural networks, tokenization refers to the process of converting the input and output spaces, such as natural language text or programming code, into discrete units or “tokens”. This process allows the network to effectively process and understand the data, as it transforms complex structures into manageable, individual elements that the model can learn from and generate.

In the training of neural networks, embeddings serve as a form of distributed word representation that converts discrete categorical variables (i.e., tokens) into a continuous vector space (i.e., embedding vectors). This conversion process captures the semantic properties of tokens, enabling tokens with similar meanings to have similar embeddings. These embeddings provide a dense representation of tokens and their semantic relationships. Embeddings are typically represented as vectors, but may also be represented as matrices or tensors.

The input of a transformer typically requires conversion from an input space (e.g., the natural language token space) to an embeddings space. This process, referred to as “encoding”, transforms discrete inputs (tokens) into continuous vector representations (embeddings). This conversion is a prerequisite for the transformer model to process the input data and understand the semantic relationships between tokens (e.g., words). Similarly, the output of a transformer typically requires conversion from the embeddings space to an output space (e.g., natural language tokens, programming code tokens, etc.), in a process referred to as “decoding”. Therefore, the training of a neural network and its evaluation (i.e., its use upon deployment) both occur within the embeddings space.

In this document, the processes of tokenization, encoding, decoding, and de-tokenization may be assumed. In other words, the processes described below occur in the “embeddings space”. Hence, while the tokenization and encoding of training data and input prompts may not be represented or discussed explicitly, they may nevertheless be implied. Similarly, the decoding and de-tokenization of neural network outputs may also be implied.

### Training and Fine-Tuning Machine Learning (ML) Modules

FIG. 27 is an illustrative flow diagram showing the different phases and datasets involved in training an IDMP ML model, according to exemplary embodiments of the present invention.

The training process starts at step 2710 with DE data acquisition, retrieval, assimilation, or generation. At step 2720, acquired DE data are pre-processed, or prepared. At step 2730, the IDMP ML model is trained using training data 2725. At step 2740, the IDMP ML model is evaluated, validated, and tested, and further refinements to the IDMP ML model are fed back into step 2730 for additional training. Once its performance is acceptable, at step 2750, optimal IDMP ML parameters are selected.

Training data 2725 is a dataset containing multiple instances of system inputs (e.g., user inputs, user prompts, database documents, resource-capability mappings, platform API and/or tool APIs, etc.) and correct outcomes (e.g., input and output schemas, splice functions, etc.). It trains the IDMP ML model to optimize the performance for a specific target task, such as the prediction of a specific target output data field within a specific target document. In FIG. 27, training data 2725 may also include subsets for validating and testing the IDMP ML model, as part of the training iterations 2730 and 2740. For an NN-based ML model, the quality of the output may depend on (a) NN architecture design and hyperparameter configurations, (b) NN coefficient or parameter optimization, and (c) quality of the training data set. These components may be refined and optimized using various methods. For example, training data 2725 may be expanded via a document database augmentation process.

In some embodiments, an additional fine-tuning 2760 phase including iterative fine-tuning 2760 and evaluation, validation, and testing 2770 steps, is carried out using fine-tuning data 2755. Fine-tuning in machine learning is a process that involves taking a selected 2750 pre-trained model and further adjusting or “tuning” its parameters to better suit a specific task or fine-tuning dataset 2755. This technique is particularly useful when dealing with deep learning models that have been trained on large, general training datasets 2725 and are intended to be applied to more specialized tasks or smaller datasets. The objective is to leverage the knowledge the model has already acquired during its initial training (often referred to as transfer learning) and refine it so that the model performs better on a more specific task at hand.

The fine-tuning process typically starts with a model that has already been trained on a large benchmark training dataset 2725, such as ImageNet (available at image-net (dot) org) for image recognition tasks. The model's existing weights, which have been learned from the original training, serve as the starting point. During fine-tuning, the model is trained further on a new fine-tuning dataset 2755, which may contain different classes or types of data than the original training set. This additional training phase allows the model to adjust its weights to better capture the characteristics of the new fine-tuning dataset 2755, thereby improving its performance on the specific task it is being fine-tuned for.

In some embodiments, additional test and validation 2780 phases are carried out using DE test and validation data 2775. Testing and validation of a ML model both refer to the process of evaluating the model's performance on a separate dataset 2775 that was not used during training, to ensure that it generalizes well to new unseen data. Validation of a ML model helps to prevent overfitting by ensuring that the model's performance generalizes beyond the training data.

While the validation phase is considered part of ML model development and may lead to further rounds of fine-tuning, the testing phase is the final evaluation of the model's performance after the model has been trained and validated. The testing phase provides an unbiased assessment of the final model's performance that reflects how well the model is expected to perform on unseen data, and is usually carried out after the model has been finalized to ensure the evaluation is unbiased.

Once the IDMP ML model is trained 2730, selected 2750, and optionally fine-tuned 2760 and validated/tested 2780, the process ends with the deployment 2790 of the IDMP ML model. Deployed IDMP ML models 2795 usually receive new DE data 2785 that was pre-processed 2780.

In machine learning, data pre-processing 2720 is tailored to the phase of model development. During model training 2730, pre-processing involves cleaning, normalizing, and transforming raw data into a format suitable for learning patterns. For fine-tuning 2760, pre-processing adapts the data to align with the distribution of the specific targeted task, ensuring the pre-trained model can effectively transfer its knowledge. Validation 2780 pre-processing mirrors that of training to accurately assess model generalization without leakage of information from the training set. Finally, in deployment 2790, pre-processing ensures real-world data matches the trained model's expectations, often involving dynamic adjustments to maintain consistency with the training and validation stages.

### Machine Learning Algorithms

Various exemplary ML algorithms are within the scope of the present invention. Such machine learning algorithms include, but are not limited to, random forest, nearest neighbor, decision trees, support vector machines (SVM), Adaboost, gradient boosting, Bayesian networks, evolutionary algorithms, various neural networks (including deep learning networks (DLN), convolutional neural networks (CNN), and recurrent neural networks (RNN)), etc.

ML modules based on transformers and Large Language Models (LLMs) are particularly well suited for the tasks described herein. The online article “Understanding Large Language Models—A Transformative Reading List”, by S. Raschka (posted Feb. 7, 2023, available at sebastianraschka(dot)com), describes various LLM architectures that are within the scope of the methods and systems described herein, and is hereby incorporated by reference in its entirety herein as if fully set forth herein.

The input to each of the listed ML modules is a feature vector comprising the input data described above for each ML module. The output of the ML module is a feature vector comprising the corresponding output data described above for each ML module.

Prior to deployment, each of the ML modules listed above may be trained on one or more respective sample input datasets and on one or more corresponding sample output datasets. The input and output training datasets may be generated from a database containing a history of input instances (e.g., user inputs, user prompts, resource-capability mappings, platform APi and/or tool APIs, etc.) and output instances (e.g., data fields, input schemas and output schemas, splice functions, etc.), or may be generated synthetically by subject matter experts.

### Exemplary System Architecture

An exemplary embodiment of the present disclosure may include one or more servers (management computing entities), one or more networks, and one or more clients (user computing entities). Each of these components, entities, devices, and systems (similar terms used herein interchangeably) may be cloud-based, and in direct or indirect communication with, for example, one another over the same or different wired or wireless networks. All of these devices, including servers, clients, and other computing entities or nodes may be run internally by a customer (in various architecture configurations including private cloud), internally by the provider of the IDMP (in various architecture configurations including private cloud), and/or on the public cloud.

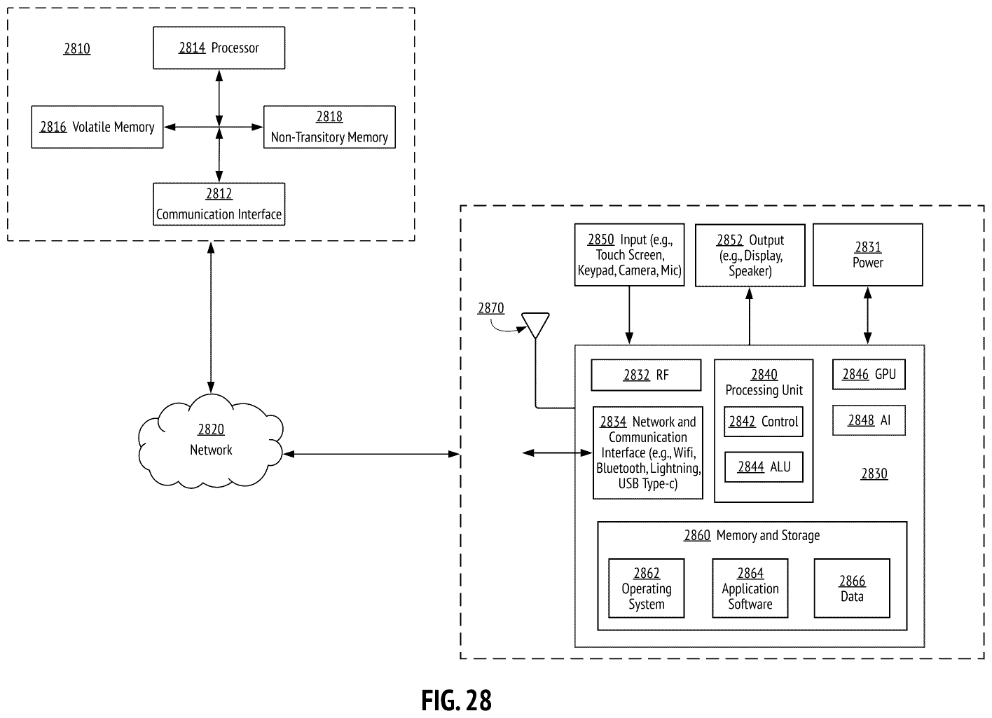

FIG. 28 provides illustrative schematics of a server (management computing entity) 2810 connected via a network 2820 to a client (user computing entity) 2830 used for model splicer generation and update within an IDMP, according to some embodiments of the present invention. While FIG. 28 illustrates the various system entities as separate, standalone entities, the various embodiments are not limited to this particular architecture. Additionally, the terms “client device”, “client computing entity”, “edge device”, and “edge computing system” are equivalent and are used interchangeably herein.

### Exemplary Management Computing Entity

An illustrative schematic is provided in FIG. 28 for a server or management computing entity 2810. In general, the terms computing entity, computer, entity, device, system, and/or similar words used herein interchangeably may refer to, for example, one or more cloud servers, computers, computing entities, desktop computers, mobile phones, tablets, phablets, notebooks, laptops, distributed systems, gaming consoles, watches, glasses, iBeacons, proximity beacons, key fobs, radio frequency identification (RFID) tags, earpieces, scanners, televisions, dongles, cameras, wristbands, wearable items/devices, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, crawling, displaying, storing, determining, creating/generating, monitoring, evaluating, and/or comparing (similar terms used herein interchangeably). In one embodiment, these functions, operations, and/or processes can be performed on data, content, and/or information (similar terms used herein interchangeably), as they are used in a digital engineering process.

In one embodiment, management computing entity 2810 may be equipped with one or more communication interfaces 2812 for communicating with various computing entities, such as by exchanging data, content, and/or information (similar terms used herein interchangeably) that can be transmitted, received, operated on, processed, displayed, stored, and/or the like. For instance, management computing entity 2810 may communicate with one or more client computing devices such as 2830 and/or a variety of other computing entities. Network or communications interface 2812 may support various wired data transmission protocols including, but not limited to, Fiber Distributed Data Interface (FDDI), Digital Subscriber Line (DSL), Ethernet, Asynchronous Transfer Mode (ATM), frame relay, and data over cable service interface specification (DOCSIS). In addition, management computing entity 2810 may be capable of wireless communication with external networks, employing any of a range of standards and protocols, including but not limited to, general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High-Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

As shown in FIG. 28, in one embodiment, management computing entity 2810 may include or be in communication with one or more processors 2814 (also referred to as processors and/or processing circuitry, processing elements, and/or similar terms used herein interchangeably) that communicate with other elements within management computing entity 2810, for example, via a bus. As will be understood, processor 2814 may be embodied in a number of different ways. For example, processor 2814 may be embodied as one or more complex programmable logic devices (CPLDs), microprocessors, multi-core processors, co-processing entities, application-specific instruction-set processors (ASIPs), graphical processing units (GPUs), microcontrollers, and/or controllers. The term circuitry may refer to an entire hardware embodiment or a combination of hardware and computer program products. Thus, processor 2814 may be embodied as integrated circuits (ICs), application-specific integrated circuits (ASICs), field-programmable gate arrays (FPGAs), programmable logic arrays (PLAs), hardware accelerators, other circuitry, and/or the like. As will therefore be understood, processor 2814 may be configured for a particular use or configured to execute instructions stored in volatile or non-volatile (or non-transitory) media 2816 and 2818, or otherwise accessible to processor 2814. As such, whether configured by hardware or computer program products, or by a combination thereof, processor 2814 may be capable of performing steps or operations according to embodiments of the present disclosure when configured accordingly.

In one embodiment, management computing entity 2810 may further include or be in communication with non-transitory memory 2818 (also referred to as non-volatile media, non-volatile storage, non-transitory storage, physical storage media, memory, memory storage, and/or memory circuitry—similar terms used herein interchangeably). In one embodiment, the non-transitory memory or storage may include one or more non-transitory memory or storage media, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. As will be recognized, the non-volatile (or non-transitory) storage or memory media may store cloud storage buckets, databases, database instances, database management systems, data, applications, programs, program modules, scripts, source code, object code, byte code, compiled code, interpreted code, machine code, executable instructions, and/or the like. The term database, database instance, and/or database management system (similar terms used herein interchangeably) may refer to a collection of records or data that is stored in a computer-readable storage medium using one or more database models, such as a hierarchical database model, network model, relational model, entity-relationship model, object model, document model, semantic model, graph model, and/or the like.

In one embodiment, management computing entity 2810 may further include or be in communication with volatile memory 2816 (also referred to as volatile storage, memory, memory storage, memory and/or circuitry-similar terms used herein interchangeably). In one embodiment, the volatile storage or memory may also include one or more volatile storage or memory media, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, processor 2814. Thus, the cloud storage buckets, databases, database instances, database management systems, data, applications, programs, program modules, scripts, source code, object code, byte code, compiled code, interpreted code, machine code, executable instructions, and/or the like may be used to control certain aspects of the operation of management computing entity 2810 with the assistance of processor 2814 and an operating system.

Although not shown, management computing entity 2810 may include or be in communication with one or more input elements, such as a keyboard input, a mouse input, a touch screen/display input, motion input, movement input, audio input, pointing device input, joystick input, keypad input, and/or the like. Management computing entity 2810 may also include or be in communication with one or more output elements, also not shown, such as audio output, visual output, screen/display output, motion output, movement output, spatial computing output (e.g., virtual reality or augmented reality), and/or the like.

As will be appreciated, one or more of the components of management computing entity 2810 may be located remotely from other management computing entity components, such as in a distributed system. Furthermore, one or more of the components may be combined and additional components performing functions described herein may be included in management computing entity 2810. Thus, management computing entity 2810 can be adapted to accommodate a variety of needs and circumstances. As will be recognized, these architectures and descriptions are provided for exemplary purposes only and are not limited to the various embodiments.

### Exemplary User Computing Entity

A user may be a human individual, a company, an organization, an entity, a department within an organization, a representative of an organization and/or person, an artificial user such as algorithms, artificial intelligence, or other software that interfaces, and/or the like. FIG. 28 further provides an illustrative schematic representation of a client user computing entity 2830 that may be used in conjunction with embodiments of the present disclosure. In various embodiments, computing device 2830 may be a general-purpose computing device with dedicated modules for performing digital engineering-related tasks. It may alternatively be implemented in the cloud, with logically and/or physically distributed architectures.

As shown in FIG. 28, user computing entity 2830 may include a power source 2831, an antenna 2870, a radio transceiver 2832, a network and communication interface 2834, and a processor unit 2840 that provides signals to and receives signals from the network and communication interface. The signals provided to and received may include signaling information in accordance with air interface standards of applicable wireless systems. In this regard, user computing entity 2830 may be capable of operating with one or more air interface standards, communication protocols, modulation types, and access types. More particularly, user computing entity 2830 may operate in accordance with any of a number of wireless communication standards and protocols, such as those described above with regard to management computing entity 2810. Similarly, user computing entity 2830 may operate in accordance with multiple wired communication standards and protocols, such as those described above with regard to management computing entity 2810.

Via these communication standards and protocols, user computing entity 2830 may communicate with various other entities using concepts such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). User computing entity 2830 may also download changes, add-ons, and updates, for instance, to its firmware, software (e.g., including executable instructions, applications, program modules), and operating system.

In some implementations, processing unit 2840 may be embodied in several different ways. For example, processing unit 2840 may be embodied as one or more complex programmable logic devices (CPLDs), microprocessors, multi-core processors, co-processing entities, application-specific instruction-set processors (ASIPs), graphical processing units (GPUs), microcontrollers, and/or controllers. Further, processing unit 2840 may be embodied as one or more other processing devices or circuitry. The term circuitry may refer to an entirely hardware embodiment or a combination of hardware and computer program products. Thus, processing unit 2840 may be embodied as integrated circuits, application specific integrated circuits (ASICs), field programmable gate arrays (FPGAs), programmable logic arrays (PLAs), hardware accelerators, other circuitry, and/or the like. As will therefore be understood, processing unit 2840 may be configured for a particular use or configured to execute instructions stored in volatile or non-volatile media or otherwise accessible to the processing unit. As such, whether configured by hardware or computer program products, or by a combination thereof, processing unit 2840 may be capable of performing steps or operations according to embodiments of the present invention when configured accordingly.

In some embodiments, processing unit 2840 may comprise a control unit 2842 and a dedicated arithmetic logic unit (ALU) 2844 to perform arithmetic and logic operations. In some embodiments, user computing entity 2830 may comprise a graphics processing unit (GPU) 2846 for specialized parallel processing tasks, and/or an artificial intelligence (AI) module or accelerator 2848, also specialized for applications including artificial neural networks and machine learning. In some embodiments, processing unit 2840 may be coupled with GPU 2846 and/or AI accelerator 2848 to distribute and coordinate digital engineering related tasks.

In some embodiments, computing entity 2830 may include a user interface, comprising an input interface 2850 and an output interface 2852, each coupled to processing unit 2840. User input interface 2850 may comprise any of a number of devices or interfaces allowing computing entity 2830 to receive data, such as a keypad (hard or soft), a touch display, a mic/speaker for voice/speech/conversation, a camera for motion or posture interfaces, and appropriate sensors for spatial computing interfaces. User output interface 2852 may comprise any of a number of devices or interfaces allowing computing entity 2830 to provide information to a user, such as through the touch display, or a speaker for audio outputs. In some embodiments, output interface 2852 may connect computing entity 2830 to an external loudspeaker or projector, for audio and/or visual output. In some embodiments, user interfaces 2850 and 2852 integrate multimodal data in an interface that caters to human users. Some examples of human interfaces include a dashboard-style interface, a workflow-based interface, conversational interfaces, and spatial-computing interfaces. As shown in FIG. 5, computing entity 2830 may also support bot/algorithmic interfaces such as code interfaces, text-based API interfaces, and the like.

User computing entity 2830 can also include volatile and/or non-volatile storage or memory 2860, which can be embedded and/or may be removable. For example, the non-volatile or non-transitory memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile (or non-transitory) storage or memory 2860 may store an operating system 2862, application software 2864, data 2866, databases, database instances, database management systems, data, applications, programs, program modules, scripts, source code, object code, byte code, compiled code, interpreted code, machine code, executable instructions, and/or the like to implement functions of user computing entity 2830. As indicated, this may include a user application that is resident on the entity or accessible through a browser or other user interface for communicating with management computing entity 2810 and/or various other computing entities.

In some embodiments, user computing entity 2830 may include one or more components or functionalities that are the same or similar to those of management computing entity 2810, as described in greater detail above. As will be recognized, these architectures and descriptions are provided for exemplary purposes only and are not limited to the various embodiments.

In some embodiments, computing entities 2810 and/or 2830 may communicate to external devices like other computing devices and/or access points to receive information such as software or firmware, or to send information from the memory of the computing entity to external systems or devices such as servers, computers, smartphones, and the like.

In some embodiments, two or more computing entities such as 2810 and/or 2830 may establish connections using a network such as 2820 utilizing any of the networking protocols listed previously. In some embodiments, the computing entities may use network interfaces such as 2812 and 2834 to communicate with each other, such as by communicating data, content, information, and/or similar terms used herein interchangeably that can be transmitted, received, operated on, processed, displayed, stored, and/or the like.

### Additional Hardware & Software Implementation Details

Although an example processing system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The terms “processor”, “computer,” “data processing apparatus”, and the like encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing, and grid computing infrastructures.

A computer program (also known as a program, software, software application, script, code, program code, and the like) can be written in any form of programming language, including compiled or interpreted languages, declarative or procedural languages, and it can be deployed in any form, including as a standalone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto optical disks, or optical disks. However, a computer need not have such devices. Devices suitable for storing computer program instructions and information/data include all forms of non-volatile memory, media, and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a backend component, e.g., as an information/data server, or that includes a middleware component, e.g., an application server, or that includes a frontend component, e.g., a client computer having a graphical user interface or a web browser through which a user can interact with an implementation of the subject matter described herein, or any combination of one or more such back end, middleware, or front end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship with each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

In some embodiments of the present invention, the entire system can be implemented and offered to the end-users and operators over the Internet, in a so-called cloud implementation. No local installation of software or hardware would be needed, and the end-users and operators would be allowed access to the systems of the present invention directly over the Internet, using either a web browser or similar software on a client, which client could be a desktop, laptop, mobile device, and so on. This eliminates any need for custom software installation on the client side and increases the flexibility of delivery of the service (software-as-a-service), and increases user satisfaction and ease of use. Various business models, revenue models, and delivery mechanisms for the present invention are envisioned, and are all to be considered within the scope of the present invention.

In general, the method executed to implement the embodiments of the invention, may be implemented as part of an operating system or a specific application, component, program, object, module, or sequence of instructions referred to as “program code,” “computer program(s)”, “computer code(s),” and the like. The computer programs typically comprise one or more instructions set at various times in various memory and storage devices in a computer, and that, when read and executed by one or more processors in a computer, cause the computer to perform operations necessary to execute elements involving the various aspects of the invention. Moreover, while the invention has been described in the context of fully functioning computers and computer systems, those skilled in the art will appreciate that the various embodiments of the invention are capable of being distributed as a program product in a variety of forms, and that the invention applies equally regardless of the particular type of machine or computer-readable media used to actually affect the distribution. Examples of computer-readable media include but are not limited to recordable type media such as volatile and non-volatile (or non-transitory) memory devices, floppy and other removable disks, hard disk drives, optical disks, which include Compact Disk Read-Only Memory (CD ROMS), Digital Versatile Disks (DVDs), etc., as well as digital and analog communication media.

### CONCLUSIONS

One of ordinary skill in the art knows that the use cases, structures, schematics, flow diagrams, and steps may be performed in any order or sub-combination, while the inventive concept of the present invention remains without departing from the broader scope of the invention. Every embodiment may be unique, and step(s) of method(s) may be either shortened or lengthened, overlapped with other activities, postponed, delayed, and/or continued after a time gap, such that every active user and running application program is accommodated by the server(s) to practice the methods of the present invention.

For simplicity of explanation, the embodiments of the methods of this disclosure are depicted and described as a series of acts or steps. However, acts or steps in accordance with this disclosure can occur in various orders and/or concurrently, and with other acts or steps not presented and described herein. Furthermore, not all illustrated acts or steps may be required to implement the methods in accordance with the disclosed subject matter. In addition, those skilled in the art will understand and appreciate that the methods could alternatively be represented as a series of interrelated states via a state diagram or events or their equivalent.

As used herein, the singular forms “a,” “an,” and “the” include plural references unless the context clearly indicates otherwise. Thus, for example, reference to “a cable” includes a single cable as well as a bundle of two or more different cables, and the like.

The terms “comprise,” “comprising,” “includes,” “including,” “have,” “having,” and the like, used in the specification and claims are meant to be open-ended and not restrictive, meaning “including but not limited to.”

In the foregoing description, numerous specific details are set forth, such as specific structures, dimensions, processes parameters, etc., to provide a thorough understanding of the present invention. The particular features, structures, materials, or characteristics may be combined in any suitable manner in one or more embodiments. The words “example”, “exemplary”, “illustrative” and the like, are used herein to mean serving as an example, instance, or illustration. Any aspect or design described herein as “example” or its equivalents is not necessarily to be construed as preferred or advantageous over other aspects or designs. Rather, use of the words “example” or equivalents is intended to present concepts in a concrete fashion.

As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A, X includes B, or X includes both A and B, then “X includes A or B” is satisfied under any of the foregoing instances.

Reference throughout this specification to “an embodiment,” “certain embodiments,” or “one embodiment” means that a particular feature, structure, or characteristic described in connection with the embodiment is included in at least one embodiment. Thus, the appearances of the phrase “an embodiment,” “certain embodiments,” or “one embodiment” throughout this specification are not necessarily all referring to the same embodiment.

As used herein, the term “about” in connection with a measured quantity, refers to the normal variations in that measured quantity, as expected by one of ordinary skill in the art in making the measurement and exercising a level of care commensurate with the objective of measurement and the precision of the measuring equipment. For example, in some exemplary embodiments, the term “about” may include the recited number±10%, such that “about 10” would include from 9 to 11. In other exemplary embodiments, the term “about” may include the recited number±X %, where X is considered the normal variation in said measurement by one of ordinary skill in the art.

Features which are described in the context of separate embodiments may also be provided in combination in a single embodiment. Conversely, various features which are, for brevity, described in the context of a single embodiment, may also be provided separately or in any suitable sub-combination. The applicant hereby gives notice that new claims may be formulated to such features and/or combinations of such features during the prosecution of the present application or of any further application derived therefrom. Features of the transitory physical storage medium described may be incorporated into/used in a corresponding method, digital documentation system and/or system, and vice versa.

Although the present invention has been described with reference to specific exemplary embodiments, it will be evident that the various modifications and changes can be made to these embodiments without departing from the broader scope of the invention. Accordingly, the specification and drawings are to be regarded in an illustrative sense rather than in a restrictive sense. It will also be apparent to the skilled artisan that the embodiments described above are specific examples of a single broader invention which may have greater scope than any of the singular descriptions taught. There may be many alterations made in the descriptions without departing from the scope of the present invention, as defined by the claims.

What is claimed is:

1. A non-transitory physical storage medium storing program code, the program code executable by a hardware processor to cause the hardware processor to execute a computer-implemented process for artificial intelligence (AI)-assisted generation of a digital model splicer on a digital platform, comprising program code to:
generate, using a first AI model, input and output schemas for a target digital tool, wherein the input schema comprises identification and type of input data into functions of the target digital tool, and wherein the output schema comprises identification and type of output data from functions of the target digital tool;
train a second AI model on a platform resource-capability mapping of the digital platform to generate scripts executable on the digital platform,
wherein the platform resource-capability mapping provides a correspondence between given resources on the digital platform and corresponding capabilities of the given resources, wherein the given resources comprise one or more third-party tool functions supported by the digital platform, and
wherein the corresponding capabilities comprise one or more platform functions executable on the digital platform, and that call upon the third-party tool functions supported by the digital platform;
generate, using the second AI model, one or more function scripts executable by the digital platform, wherein the second AI model is prompted based on the input and output schemas, and wherein the one or more function scripts call Application Programming Interface (API) or Software Development Kit (SDK) functions associated with the target digital tool using the input and output schemas; and
store the input and output schemas and the one or more function scripts as the digital model splicer for the target digital tool.

2. The non-transitory physical storage medium of claim 1, further comprising program code to align the input and output schemas to a standardized platform data schema, wherein at least one variable within the input and output schemas is of a standard platform variable type.

3. The non-transitory physical storage medium of claim 1, wherein the first AI model is prompted further based on input and output schema examples for a template digital tool associated with a template digital model type.

4. The non-transitory physical storage medium of claim 1, wherein the digital platform has a platform API referencing the one or more function scripts as implementations of one or more platform functions associated with the target digital tool, wherein the platform API is universal for a given platform function implemented using at least two different digital tools for a common digital model type category, and wherein the platform resource-capability mapping comprises the platform API.

5. The non-transitory physical storage medium of claim 1, further comprising program code to:
receive a user intent input, wherein the second AI model is a recommender engine, wherein the second AI model is prompted further based on the user intent input, and wherein the one or more function scripts accomplish the user intent input.

6. The non-transitory physical storage medium of claim 1, wherein the first AI model is prompted further based on a target digital model type associated with the target digital tool, and wherein the one or more function scripts are stored as the digital model splicer implemented using the target digital tool for the target digital model type.

7. The non-transitory physical storage medium of claim 6, wherein a category of the target digital model type is previously integrated into the digital platform and described in the resource-capability mapping, and wherein the input and output schemas overlap with existing input and output schemas for an existing digital tool with the target digital model type category.

8. The non-transitory physical storage medium of claim 1, further comprising program code to:
extract tool API information from API documentations of the target digital tool, wherein the second AI model is prompted further based on the tool API information.

9. The non-transitory physical storage medium of claim 1, further comprising program code to:
fine-tune the first AI model and the second AI model on API documentations of the target digital tool.

10. The non-transitory physical storage medium of claim 1, further comprising program code to:
generate a design mockup for the digital model splicer, wherein the second AI model is prompted further based on a portion of the design mockup.

11. The non-transitory physical storage medium of claim 10, wherein the program code to generate the design mockup comprises program code to:
receive a digital task;
upload the input and output schemas into a design mockup tool;
generate, using the design mockup tool, a base design mockup of the digital model splicer, with a standardized data schema;
for each variable in the standardized schema, search for example text or image in a database to update the base design mockup;
generate the design mockup by adding the example texts or images to the base design mockup, based on the input and output schema and the digital task;
receive user feedback on the design mockup; and
finalize the design mockup based on the user feedback.

12. The non-transitory physical storage medium of claim 1, wherein the first AI model or the second AI model is a generative AI model.

13. The non-transitory physical storage medium of claim 1, wherein the first AI model or the second AI model is a transformer-based Large Language Model (LLM) or a Small Language Model (SLM).

14. The non-transitory physical storage medium of claim 1, wherein the second AI model is pre-trained on existing function scripts from the digital platform.

15. The non-transitory physical storage medium of claim 1, wherein the first AI model or the second AI model is prompted further based on human user input.

16. The non-transitory physical storage medium of claim 1, wherein the first AI model or the second AI model is prompted further based on a digital task.

17. The non-transitory physical storage medium of claim 1, wherein at least one function script calls API functions associated with a digital tool different from the target digital tool.

18. A computer-implemented method executable by a hardware processor for generating a digital model splicer on a digital platform, comprising:
generating, using a first artificial intelligence (AI) model, input and output schemas for a target digital tool, wherein the input schema comprises identification and type of input data into functions of the target digital tool, and wherein the output schema comprises identification and type of output data from functions of the target digital tool;
training a second AI model on a platform resource-capability mapping of the digital platform to generate scripts executable on the digital platform,
wherein the platform resource-capability mapping provides a correspondence between given resources on the digital platform and corresponding capabilities of the given resources,
wherein the given resources comprise one or more third-party tool functions supported by the digital platform, and
wherein the corresponding capabilities comprise one or more platform functions executable on the digital platform, and that call upon the third-party tool functions supported by the digital platform;
generating, using the second AI model, one or more function scripts executable by the digital platform, wherein the second AI model is prompted based on the input and output schemas, and wherein the one or more function scripts call Application Programming Interface (API) or Software Development Kit (SDK) functions associated with the target digital tool using the input and output schemas; and
storing the input and output schemas and the one or more function scripts as the digital model splicer for the target digital tool.

19. The method of claim 18, further comprising:
aligning the input and output schemas to a standardized platform data schema, wherein at least one variable within the input and output schemas is of a standard platform variable type.

20. A system for generating a digital model splicer on a digital platform, comprising:
at least one hardware processor; and
at least one non-transitory physical storage medium storing program code, the program code executable by a hardware processor to cause the hardware processor to execute a computer-implemented process for artificial intelligence (AI)-assisted generation of the digital model splicer on the digital platform, comprising program code to:
generate, using a first AI model, input and output schemas for a target digital tool, wherein the input schema comprises identification and type of input data into functions of the target digital tool, and wherein the output schema comprises identification and type of output data from functions of the target digital tool;
train a second AI model on a platform resource-capability mapping of the digital platform to generate scripts executable on the digital platform,
wherein the platform resource-capability mapping provides a correspondence between given resources on the digital platform and corresponding capabilities of the given resources,
wherein the given resources comprise one or more third-party tool functions supported by the digital platform, and
wherein the corresponding capabilities comprise one or more platform functions executable on the digital platform, and that call upon the third-party tool functions supported by the digital platform;
generate, using the second AI model, one or more function scripts executable by the digital platform, wherein the second AI model is prompted based on the input and output schemas, and wherein the one or more function scripts Application Programming Interface (API) or Software Development Kit (SDK) functions associated with the target digital tool using the input and output schemas; and
store the input and output schemas and the one or more function scripts as the digital model splicer for the target digital tool.
